(19) United States
(12) Patent Application Publication
(10) Pub. No.: US 2025/0377593 A1
(43) Pub. Date: Dec. 11, 2025

(54) RESIST PATTERN FORMING PROCESS

(71) Applicant: Shin-Etsu Chemical Co., Ltd., Tokyo (JP)

(72) Inventors: Shun Kikuchi, Joetsu-shi (JP); Kousuke Ohyama, Joetsu-shi (JP); Satoshi Kusama, Joetsu-shi (JP); Masaki Ohashi, Joetsu-shi (JP)

(73) Assignee: Shin-Etsu Chemical Co., Ltd., Tokyo (JP)

(21) Appl. No.: 19/225,114

(22) Filed: Jun. 2, 2025

(30) Foreign Application Priority Data
Jun. 10, 2024 (JP) 2024-093768

(51) Int. Cl. G03F 7/038; G03F 7/00; G03F 7/039; G03F 7/36; G03F 7/38

(52) U.S. Cl. CPC G03F 7/0388; G03F 7/0382; G03F 7/0392; G03F 7/36; G03F 7/38; G03F 7/70033

(57) ABSTRACT

A resist pattern forming process is provided that includes a step in which a non-chemically amplified resist composition excellent in sensitivity and maximum resolution is used and the exposed resist film is developed by dry etching to form a positive or negative resist pattern when processed by photolithography using high-energy radiation. A resist pattern forming process comprising the steps of: (i) applying a resist composition containing: a hypervalent iodine compound having the formula (1), (2), or (3); a carboxy group-containing compound; and a solvent onto a substrate or onto an underlayer film laminated on a substrate to form a resist film, (ii) exposing the resist film to high-energy radiation, (iii) heating the exposed resist film, and (iv) developing the heated resist film by dry etching to form a resist pattern.

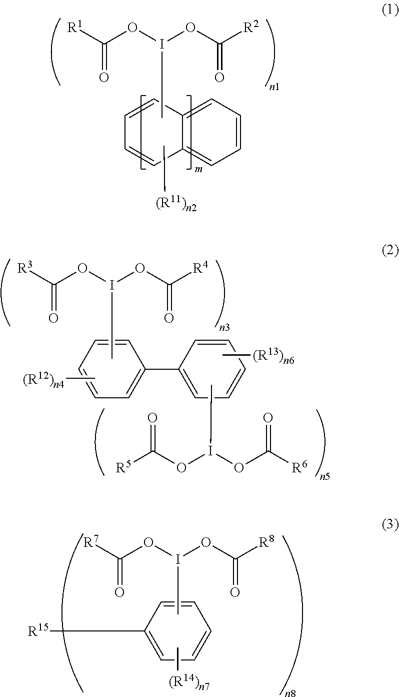

### CROSS-REFERENCE TO RELATED APPLICATIONS

This non-provisional application claims priority under 35 U.S.C. § 119(a) on Patent Application No. 2024-093768 filed in Japan on Jun. 10, 2024, the entire contents of which are hereby incorporated by reference.

### TECHNICAL FIELD

This invention relates to a resist pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

Currently, the resist development step in semiconductor manufacturing is mainly performed by a wet process (wet development) using an alkaline aqueous solution or an organic solvent as a developer. However, with the miniaturization of the resist pattern, the wet process development has been largely influenced by swelling of patterns and the surface tension of liquids.

On the other hand, there is a method of performing development by a dry process (dry development) using an etching method with plasma. The dry process development is not influenced by swelling of patterns and the surface tension of liquids. Therefore, the resist development step in dry process has been studied for a long time.

Patent Document 1 reports that a chemically amplified positive resist composition employing a specific resin component can be used to form a high-resolution positive pattern, where a resist film is formed, exposed, and subjected to post-exposure bake (PEB) as in a conventional wet process until before the development step, and only the development step is performed by a dry process.

In chemically amplified resist compositions, as the feature size is reduced, image blurs due to acid diffusion become a problem (see Non-Patent Document 1). To insure resolution for fine patterns with a feature size of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having polymerizable olefin. With respect to the patterning of a resist film to a feature size of 16 nm et seq., it is believed impossible in the light of acid diffusion to form such a pattern from a chemically amplified resist composition. It would be desirable to have a non-chemically amplified resist composition.

A typical non-chemically amplified resist material is polymethyl methacrylate (PMMA). It is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 2 discloses a chemically amplified resist composition containing highly EUV-absorbing iodine atoms. However, as mentioned above, the chemically amplified resist composition cannot reach the resolution desired in the EUV lithography where the pattern feature size becomes smaller than ever. In particular, the line-and-space pattern has remarkably increased pattern collapse and disconnection as the pattern size is reduced. Therefore, reducing them leads to improvement in maximum resolution.

Patent Document 3 discloses a negative resist composition comprising a tin compound, and discloses that dry process development can be achieved by using the resist composition. Based on tin element having high EUV absorption, this resist composition is improved in stochastics. In addition, since dry process is used, there is no influence from swelling of patterns and the surface tension of liquids, and high sensitivity and high resolution can be realized. Such so-called metal resist compositions, however, suffer from many problems including poor shelf stability and defectiveness due to post-etching residues. Further, the metal resist compositions are of negative tone wherein the exposed region becomes a metal oxide which is insoluble in the developer. In their application to the patterning of contact holes, an additional reversal step is necessary, leaving an economical concern.

### CITATION LIST

Patent Document 1: JP-A 2023-157346
Patent Document 2: JP-A 2018-5224
Patent Document 3: JP-A 2022-538040
Non-Patent Document 1: SPIE Vol. 5039 p1 (2003)
Non-Patent Document 2: SPIE Vol. 6520 p65203L-1 (2007)

### SUMMARY OF THE INVENTION

The present invention has been made in view of the above circumstances, and an object of the invention is to provide a resist pattern forming process including a step in which a non-chemically amplified resist composition excellent in sensitivity and maximum resolution is used and the exposed resist film is developed by dry etching to form a positive or negative resist pattern when processed by photolithography using high-energy radiation, typically EB and EUV lithography.

As a result of intensive studies to achieve the above object, the inventors have found that a resist composition based on a predetermined hypervalent iodine compound and a carboxy group-containing compound has a very high sensitivity, forms a resist film having a satisfactory resolution, can form a positive or negative resist pattern with a good pattern shape by dry etching development of the resist composition, and is thus quite useful in precise micropatterning. Thereby, the present invention has been achieved.

That is, the present invention provides the following resist pattern forming process.

1. A resist pattern forming process comprising the steps of:
(i) applying a resist composition containing: a hypervalent iodine compound having the formula (1), (2), or (3); a carboxy group-containing compound; and a solvent onto a substrate or onto an underlayer film laminated on a substrate to form a resist film,
(ii) exposing the resist film to high-energy radiation,
(iii) heating the exposed resist film, and
(iv) developing the heated resist film by dry etching to form a resist pattern:

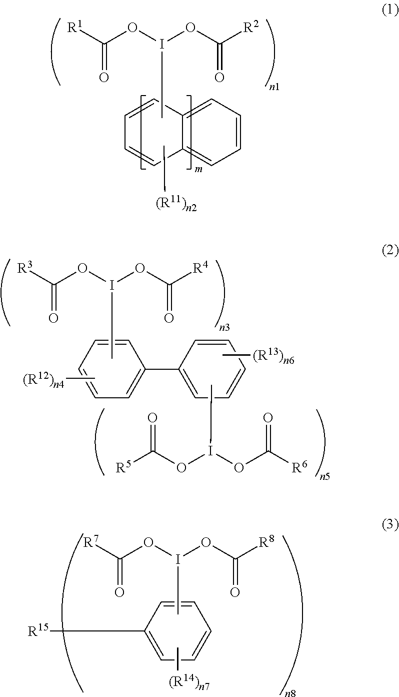

wherein
m is 0, 1, or 2; when m is 0, n1 is 2 or 3, n2 is 0, 1, 2, 3, or 4, and 2≤n1+n2≤6; when m is 1, n1 is 1, 2, or 3, n2 is 0, 1, 2, 3, 4, 5, 6, or 7, and 1≤n1+n2≤8; when m is 2, n1 is 1, 2, or 3, n2 is 0, 1, 2, 3, 4, 5, 6, 7, 8, or 9, and 1≤n1+n2≤10;
n3 is 1 or 2, n4 is 0, 1, 2, 3, or 4, provided that 1≤n3+n4≤5; n5 is 1 or 2, n6 is 0, 1, 2, 3, or 4, provided that 1≤n5+n6≤5; and n7 is 0, 1, 2, 3, or 4, and n8 is 1, 2, 3, or 4;
R¹ to R⁸ are each independently a halogen atom or a C₁-C₁₀ hydrocarbyl group which may contain a heteroatom, R¹ and R², R³ and R⁴, R⁵ and R⁶, or R⁷ and R⁸ may bond together to form a ring with the carbon atoms to which they are attached and the intervenient atoms;
R¹¹ to R¹⁴ are each independently a halogen atom or a C₁-C₄₀ hydrocarbyl group which may contain a heteroatom; when n2 is 2 or more, each R¹¹ may be the same or different from each other, and a plurality of R¹¹s may bond to each other to form a ring with the carbon atoms of the aromatic ring to which they are attached; when n4 is 2 or more, each R¹² may be the same or different from each other, and a plurality of R¹²s may bond to each other to form a ring with the carbon atoms of the aromatic ring to which they are attached; when n6 is 2 or more, each R¹³ may be the same or different from each other, and a plurality of R¹³s may bond to each other to form a ring with the carbon atoms of the aromatic ring to which they are attached; when n7 is 2 or more, each R¹⁴ may be the same or different from each other, and a plurality of R¹⁴s may bond to each other to form a ring with the carbon atoms of the aromatic ring to which they are attached;
R¹⁵ is a C₁-C₄₀ (n8)-valent hydrocarbon group or a C₂-C₄₀ (n8)-valent heterocyclic group; when n8 is 2, R¹⁵ may be an ether bond, a carbonyl group, an azo group, a thioether bond, a carbonate bond, a carbamate bond, a sulfinyl group, a sulfonyl group, or a thioketone bond; some or all of the hydrogen atoms of the (n8)-valent hydrocarbon group or the (n8)-valent heterocyclic group may be substituted with a heteroatom-containing moiety, some of —CH₂— of the (n8)-valent hydrocarbon group may be substituted with a heteroatom-containing moiety, and R¹⁴ and R¹⁵ may bond together to form a ring with the carbon atoms to which they are attached and the intervenient atoms.

2. The resist pattern forming process of 1 wherein the carboxy group-containing compound is a polymer having a repeat unit having the formula (4) or a compound having the formula (5):

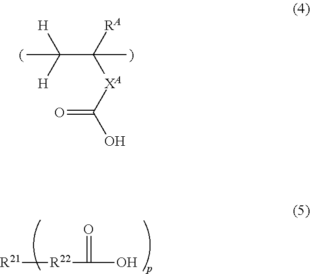

wherein R^{A} is a hydrogen atom, a halogen atom, a methyl group, or a trifluoromethyl group, X^{A} is a single bond, a phenylene group, a naphthylene group, or *—C(═O)—O—X^{A1}— wherein X^{A1} is a C₁-C₁₀ saturated hydrocarbylene group, a phenylene group, or a naphthylene group, the saturated hydrocarbylene group may contain a hydroxy group, an ether bond, an ester bond, or a lactone ring, and * designates a valence bond to a carbon atom in a main chain;
p is 1, 2, 3, or 4,
R²¹ is a C₁-C₄₀ p-valent hydrocarbon group or a C₂-C₄₀ p-valent heterocyclic group, when p is 2, R²¹ may be an ether bond, a carbonyl group, an azo group, a thioether bond, a carbonate bond, a carbamate bond, a sulfinyl group, or a sulfonyl group, and some or all of the hydrogen atoms in the p-valent hydrocarbon group or the p-valent heterocyclic group may be substituted by a heteroatom-containing moiety, and some constituent —CH₂— in the p-valent hydrocarbon group may be replaced by a heteroatom-containing moiety,
R²² is a single bond or a C₁-C₁₀ hydrocarbylene group, and some or all of the hydrogen atoms in the hydrocarbylene group may be substituted by a heteroatom-containing moiety, and some constituent —CH₂— in the hydrocarbylene group may be replaced by a heteroatom-containing moiety, and when p is 2, 3, or 4, each R²² may be the same or different from each other.

3. The resist pattern forming process of 1 or 2 wherein the high-energy radiation is i-ray, KrF excimer laser beam, ArF excimer laser beam, EB, or EUV.

4. The resist pattern forming process of any one of 1 to 3 wherein, in the step (iv), the dry etching is performed by using a gas containing at least one selected from the group consisting of oxygen and tetrafluoromethane.

### Advantageous Effects of the Invention

The inventive resist pattern forming process exhibits both high sensitivity and resolution when processing by i-ray, KrF and ArF excimer laser beam, and EB and EUV lithography and developing by dry etching, and is quite useful in micropatterning.

### DETAILED DESCRIPTION OF THE INVENTION

### [Resist Composition]

The resist composition used in the inventive resist pattern forming process contains a predetermined hypervalent iodine compound; a carboxy group-containing compound; and a solvent.

### [Hypervalent Iodine Compound]

The hypervalent iodine compound is a three-coordinate hypervalent iodine compound having the formula (1), (2), or (3).

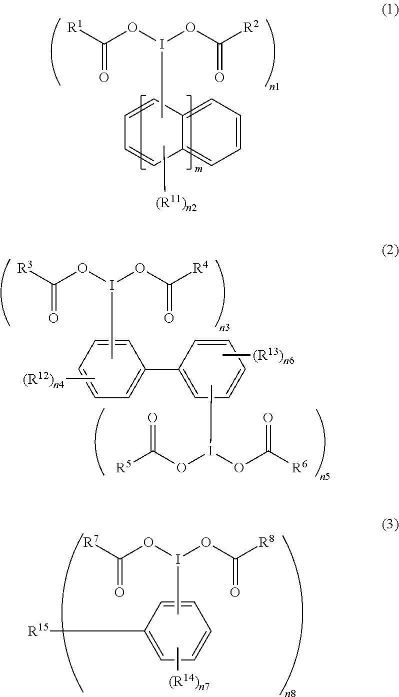

In the formulae (1) to (3), m is 0, 1, or 2; when m is 0, n1 is 2 or 3, n2 is 0, 1, 2, 3, or 4, and 2≤n1+n2≤6; when m is 1, n1 is 1, 2, or 3, n2 is 0, 1, 2, 3, 4, 5, 6, or 7, and 1≤n1+n2≤8; when m is 2, n1 is 1, 2, or 3, n2 is 0, 1, 2, 3, 4, 5, 6, 7, 8, or 9, and 1≤n1+n2≤ 10;
n3 is 1 or 2, n4 is 0, 1, 2, 3, or 4, provided that 1≤n3+n4≤5; n5 is 1 or 2, n6 is 0, 1, 2, 3, or 4, provided that 1≤n5+n6≤5; and n7 is 0, 1, 2, 3, or 4, and n8 is 1, 2, 3, or 4.

In the formulae (1) to (3), R¹ to R⁸ are each independently a halogen atom or a C₁-C₁₀ hydrocarbyl group which may contain a heteroatom, R¹ and R², R³ and R⁴, R⁵ and R⁶, or R⁷ and R⁸ may bond together to form a ring with the carbon atoms to which they are attached and the intervenient atoms.

Suitable halogen atoms of R¹ to R⁸ include fluorine, chlorine, bromine and iodine. The C₁-C₁₀ hydrocarbyl group of R¹ to R⁸ may be saturated or unsaturated and straight, branched or cyclic. Examples thereof include C₁-C₁₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl, alkenyl groups such as vinyl and allyl, C₆-C₁₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ to R⁸ are preferably C₁-C₄ hydrocarbyl groups.

In the formulae (1) to (3), R¹¹ to R¹⁴ are each independently a halogen atom or a C₁-C₄₀ hydrocarbyl group which may contain a heteroatom; when n2 is 2 or more, each R¹¹ may be the same or different from each other, and a plurality of R¹¹s may bond to each other to form a ring with the carbon atoms of the aromatic ring to which they are attached; when n4 is 2 or more, each R¹² may be the same or different from each other, and a plurality of R¹²s may bond to each other to form a ring with the carbon atoms of the aromatic ring to which they are attached; when n6 is 2 or more, each R¹³ may be the same or different from each other, and a plurality of R¹³s may bond to each other to form a ring with the carbon atoms of the aromatic ring to which they are attached; when n7 is 2 or more, each R¹⁴ may be the same or different from each other, and a plurality of R¹⁴s may bond to each other to form a ring with the carbon atoms of the aromatic ring to which they are attached.

Suitable halogen atoms of R¹¹ to R¹⁴ include fluorine, chlorine, bromine and iodine. The C₁-C₄₀ hydrocarbyl group of R¹¹ to R¹⁴ may be saturated or unsaturated and straight, branched or cyclic. Examples thereof include C₁-C₄₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, and adamantylmethyl, and C₆-C₄₀ aryl groups such as phenyl, naphthyl, and anthracenyl. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—).

In the formula (3), R¹⁵ is a C₁-C₄₀ (n8)-valent hydrocarbon group or a C₂-C₄₀ (n8)-valent heterocyclic group; when n8 is 2, R¹⁵ may be an ether bond, a carbonyl group, an azo group, a thioether bond, a carbonate bond, a carbamate bond, a sulfinyl group, a sulfonyl group, or a thioketone bond; some or all of the hydrogen atoms of the (n8)-valent hydrocarbon group or the (n8)-valent heterocyclic group may be substituted with a heteroatom-containing moiety, some of —CH₂— of the (n8)-valent hydrocarbon group may be substituted with a heteroatom-containing moiety, and R¹⁴ and R¹⁵ may bond together to form a ring with the carbon atoms to which they are attached and the intervenient atoms.

The (n8)-valent hydrocarbon group of R¹⁵ may be saturated or unsaturated and straight, branched or cyclic. The (n8)-valent hydrocarbon group is obtained by removing (n8) number of hydrogen atoms from a hydrocarbon. Suitable hydrocarbons include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Exemplary C₁-C₄₀ alkanes include methane, ethane, propane, butane, pentane, hexane, heptane, octane, nonane, decane, and structural isomers thereof.

Exemplary C₂-C₄₀ alkenes include ethylene, propylene, butene, pentene, hexene, heptene, octene, nonene, decene, and structural isomers thereof.

Exemplary C₂-C₄₀ alkynes include acetylene, propyne, butyne, pentyne, hexyne, heptyne, octyne, nonyne, decyne, and structural isomers thereof.

Exemplary C₃-C₄₀ cyclic saturated hydrocarbons include cyclopropane, cyclobutane, cyclohexane, cycloheptane, cyclooctane, adamantane, and norbornane.

Exemplary C₃-C₄₀ cyclic unsaturated hydrocarbons include cyclopropene, cyclobutene, cyclopentene, cyclohexene, cycloheptene, cyclooctene, and norbornene.

Exemplary C₆-C₄₀ aromatic hydrocarbons include benzene, naphthalene, and biphenyl.

The (n8)-valent heterocyclic group of R¹⁵ is obtained by removing (n8) number of hydrogen atoms from a heterocyclic compound. Suitable heterocyclic compounds include furane, pyridine, pyrazole, and thiazolidine.

In the (n8)-valent hydrocarbon group and (n8)-valent heterocyclic group, some or all of the hydrogen atoms may be substituted by a moiety containing a heteroatom such as oxygen, sulfur, nitrogen or halogen, so that the group may contain hydroxy, cyano, fluorine, chlorine, bromine, or iodine. In the (n8)-valent hydrocarbon group, some constituent —CH₂— may be replaced by a moiety containing a heteroatom such as oxygen, sulfur or nitrogen, so that the group may contain carbonyl, ether bond, thioether bond, ester bond, sulfonic ester bond, carbonate bond, carbamate bond, lactone ring, sultone ring, or carboxylic anhydride (—C(═O)—O—C(═O)—).

Examples of the hypervalent iodine compound having formula (1) are shown below, but not limited thereto.

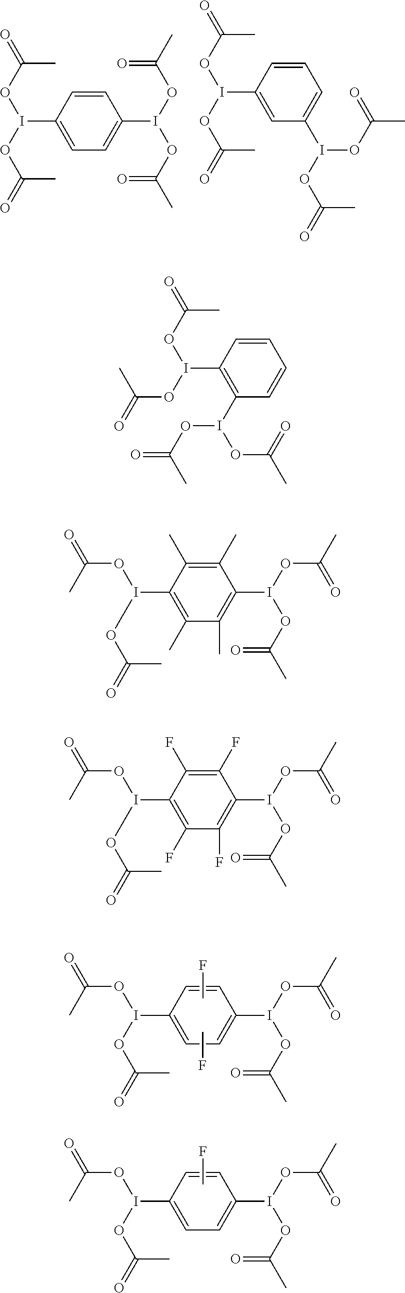

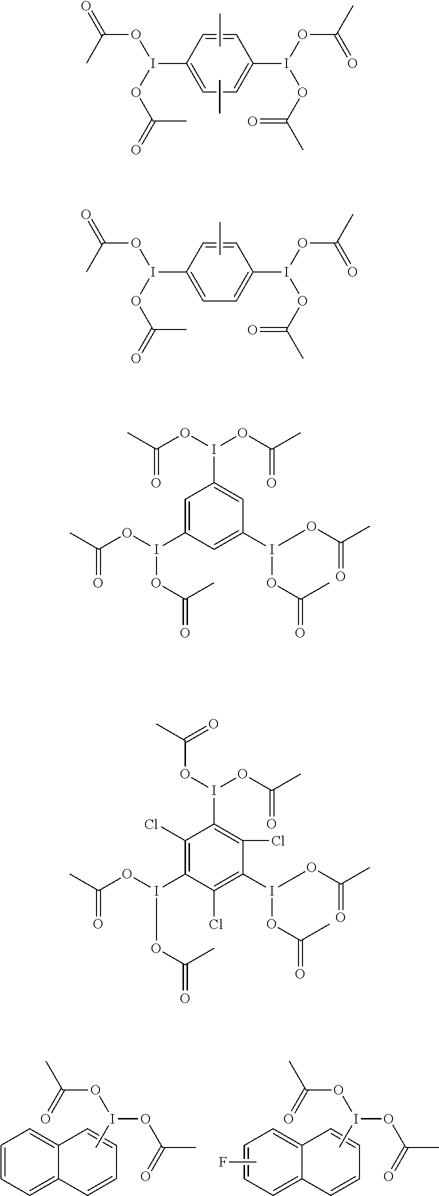

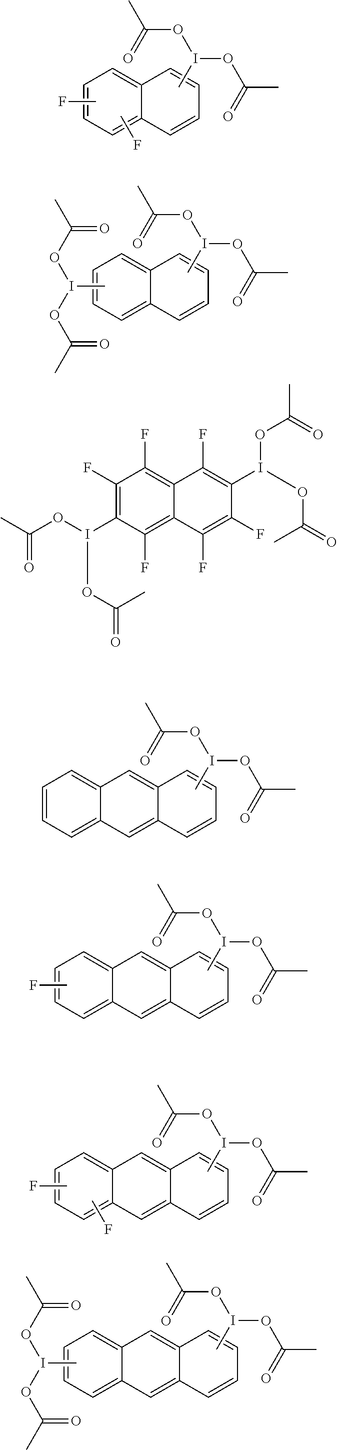

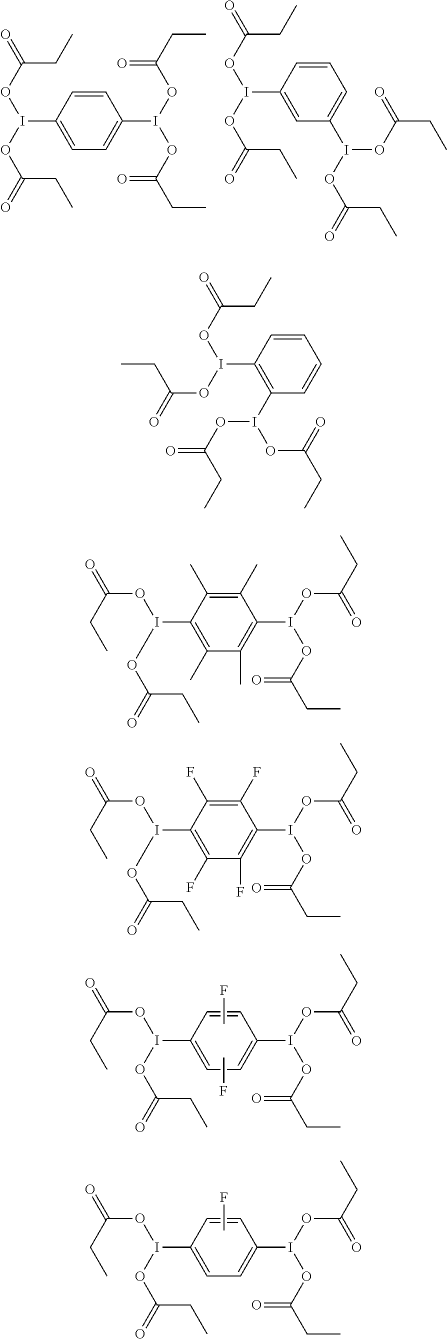

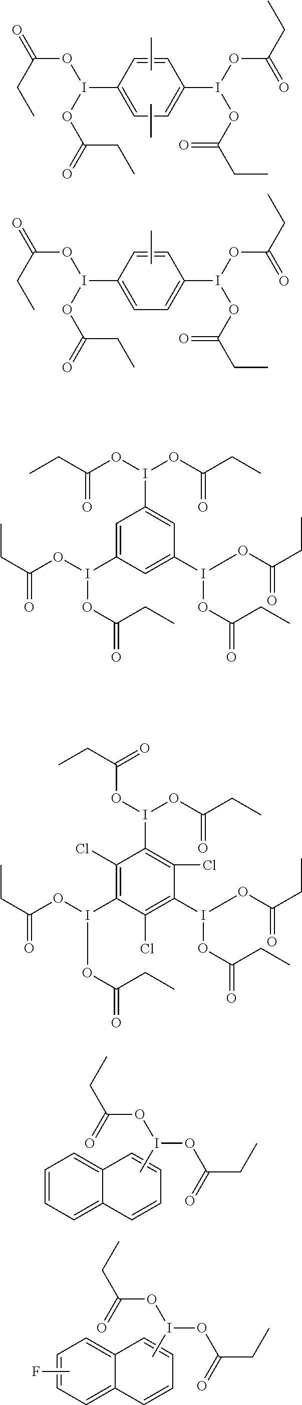

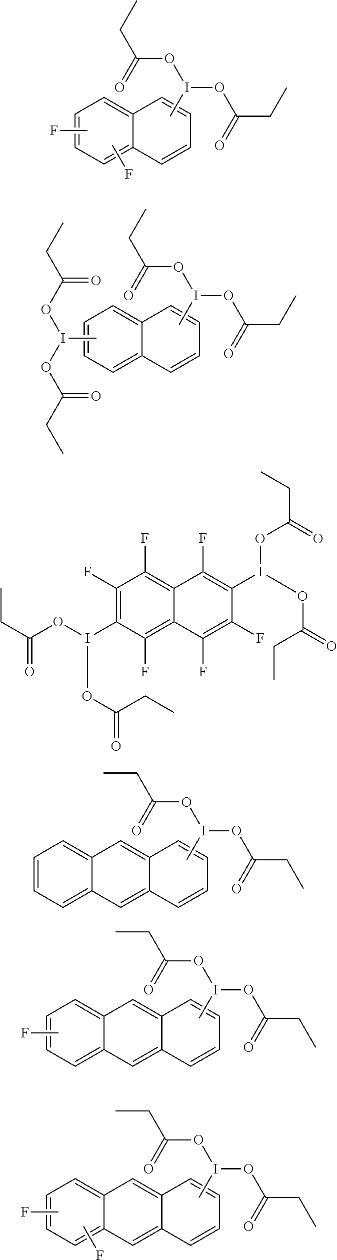

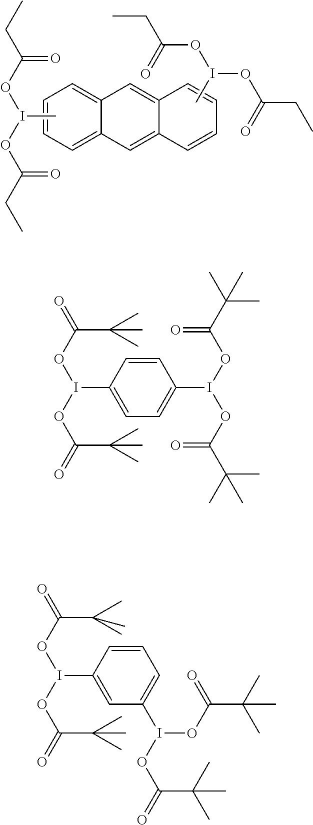

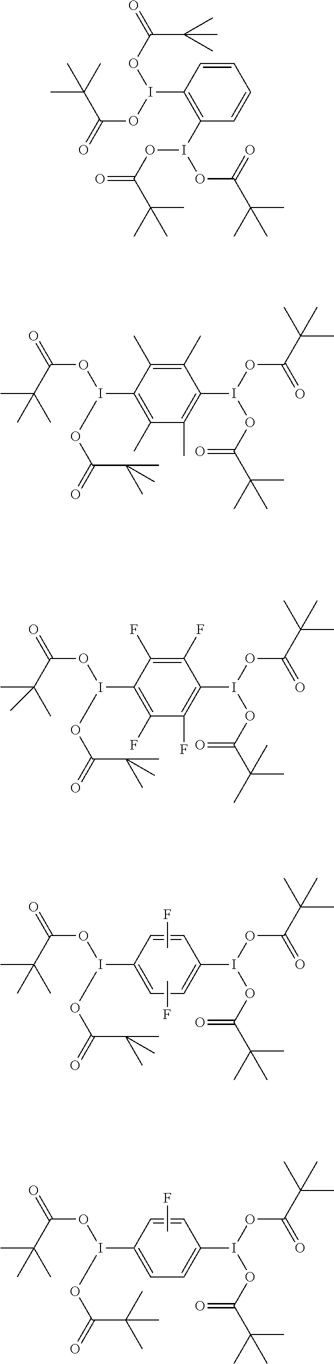

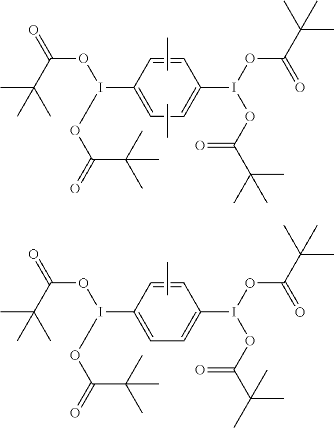

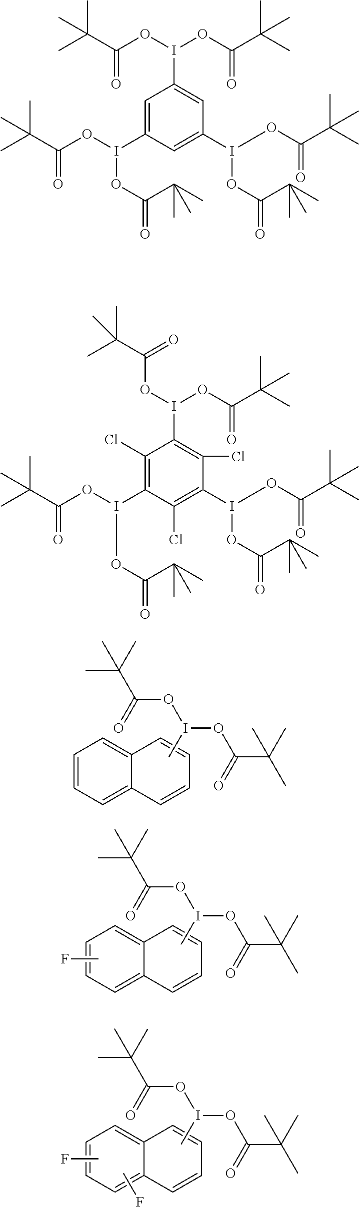

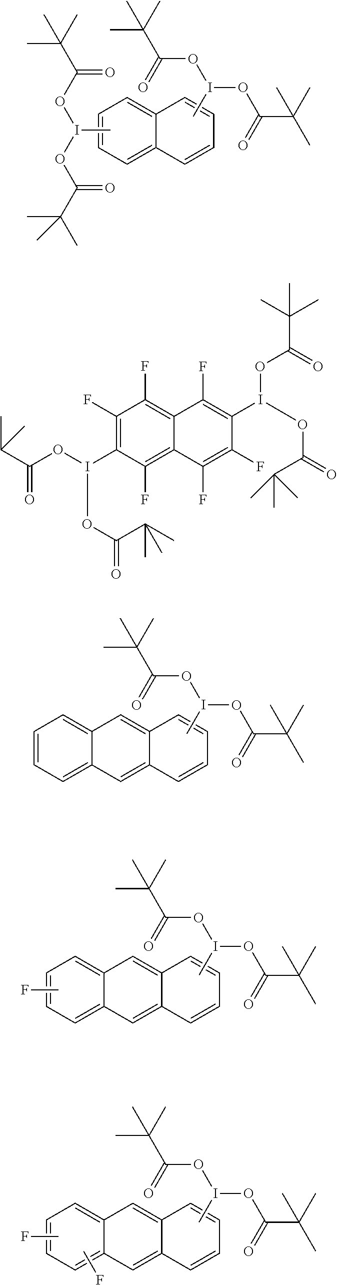

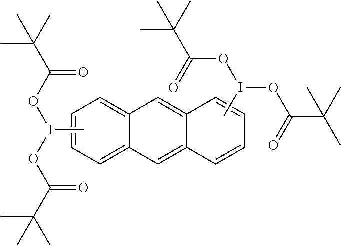

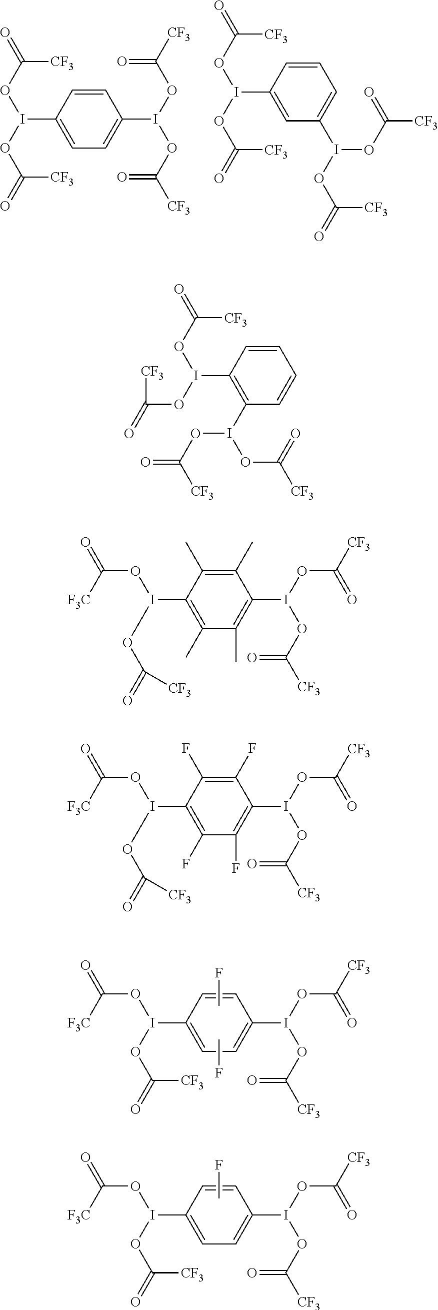

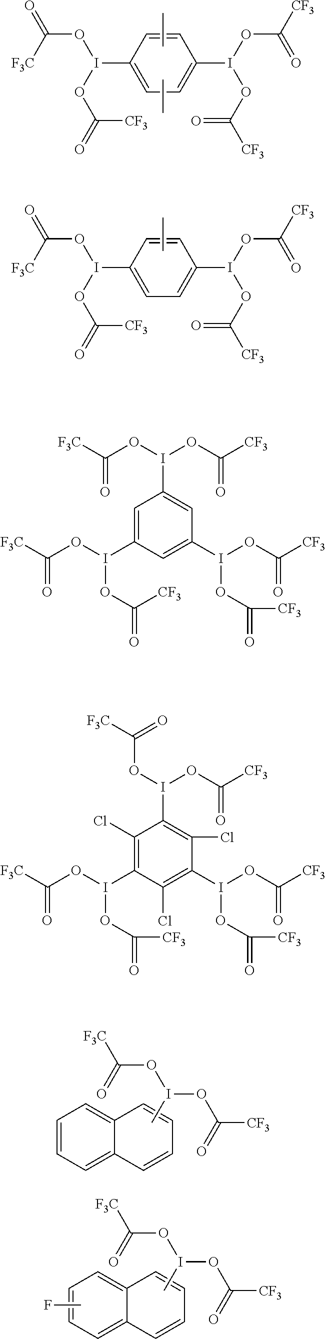

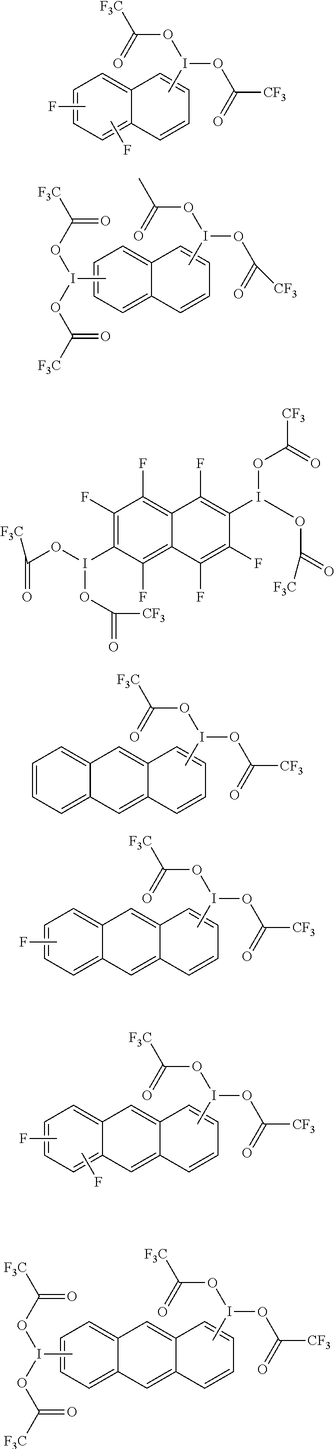

Examples of the hypervalent iodine compound having formula (2) are shown below, but not limited thereto.

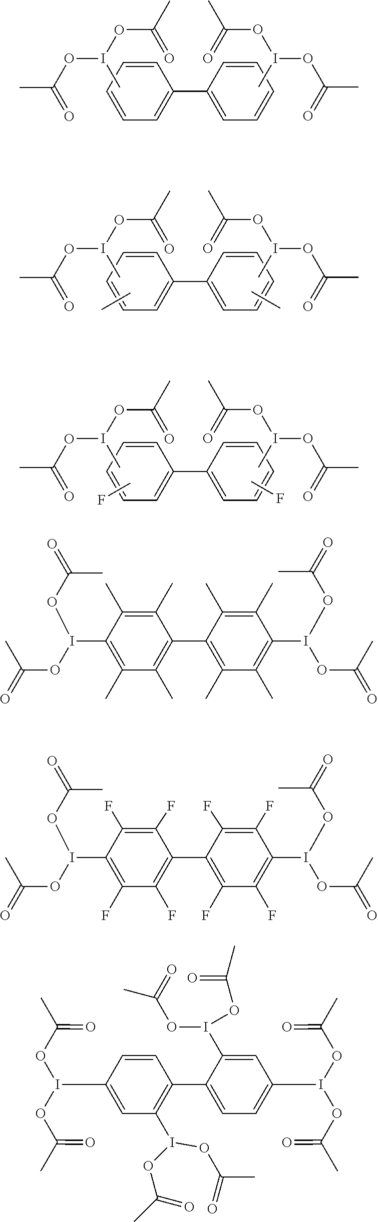

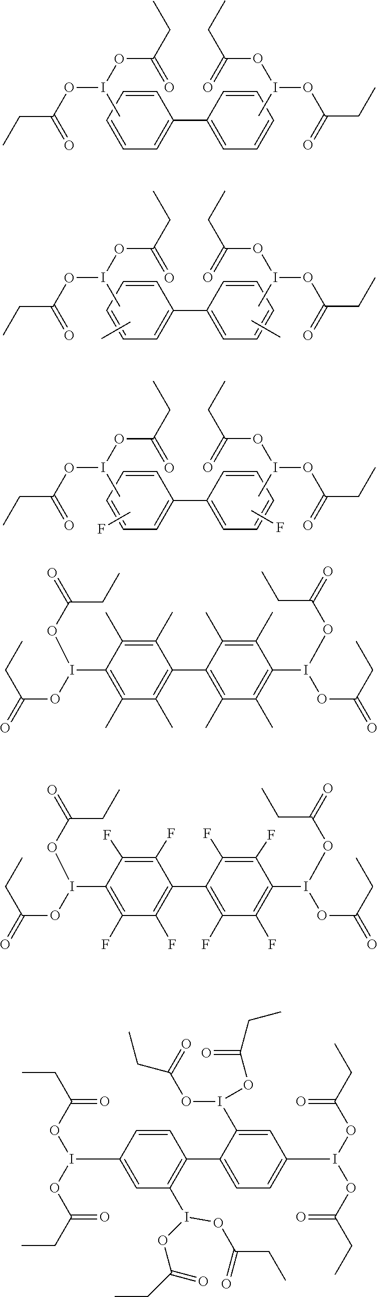

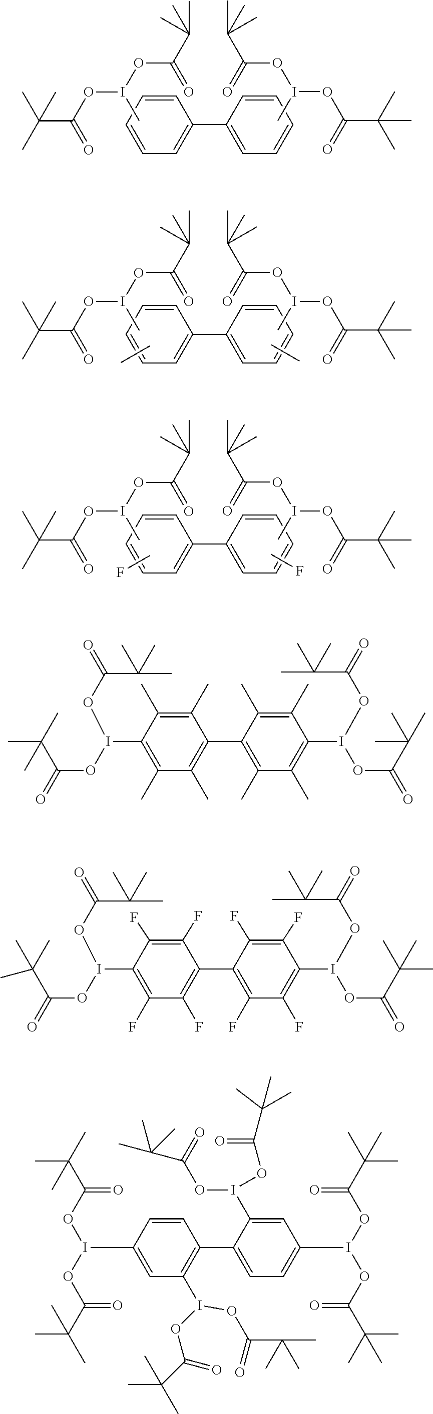

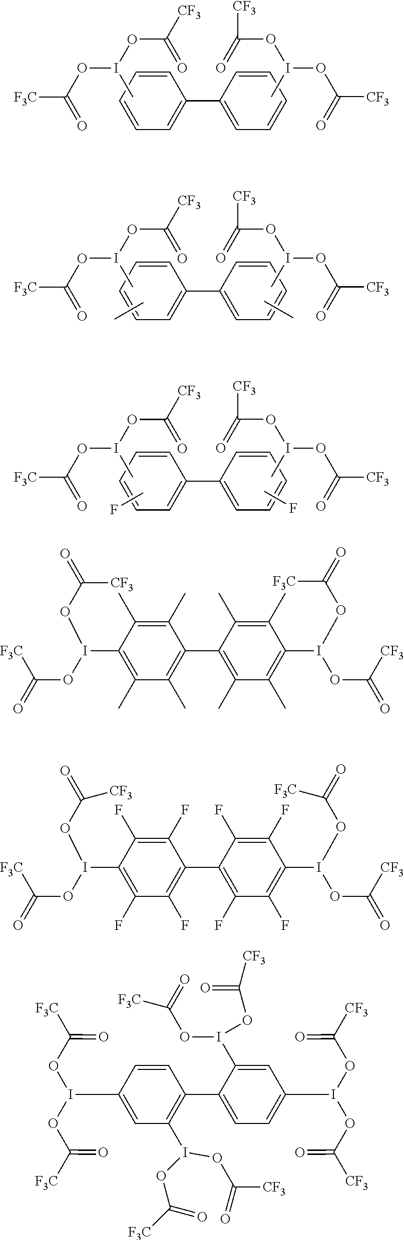

Examples of the hypervalent iodine compound having formula (3) are shown below, but not limited thereto.

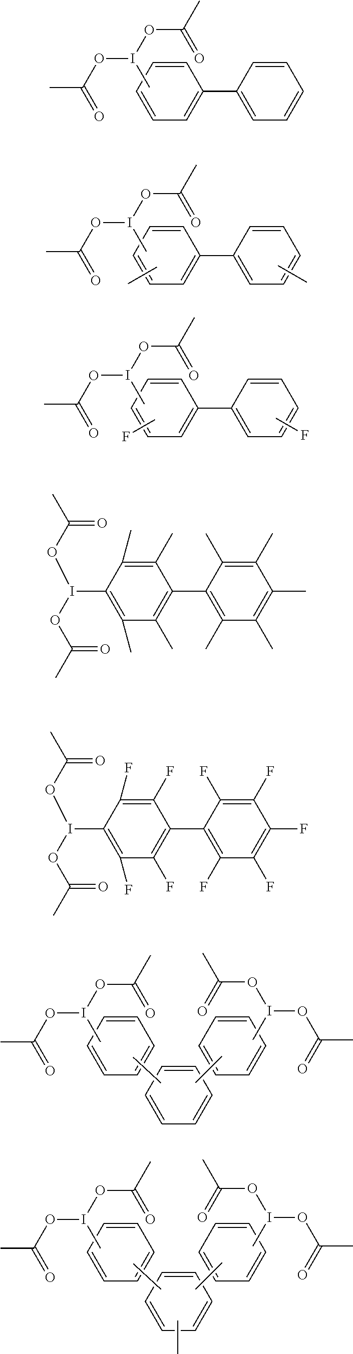

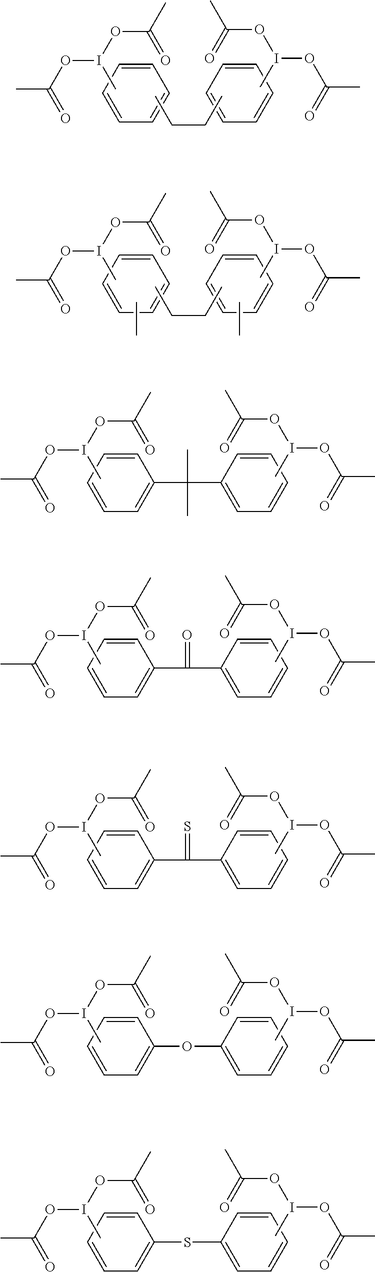

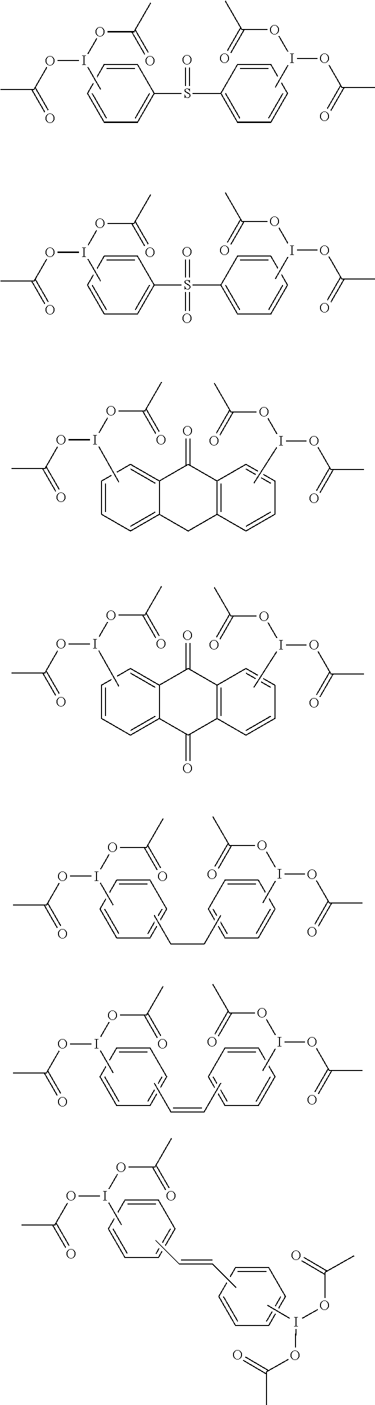

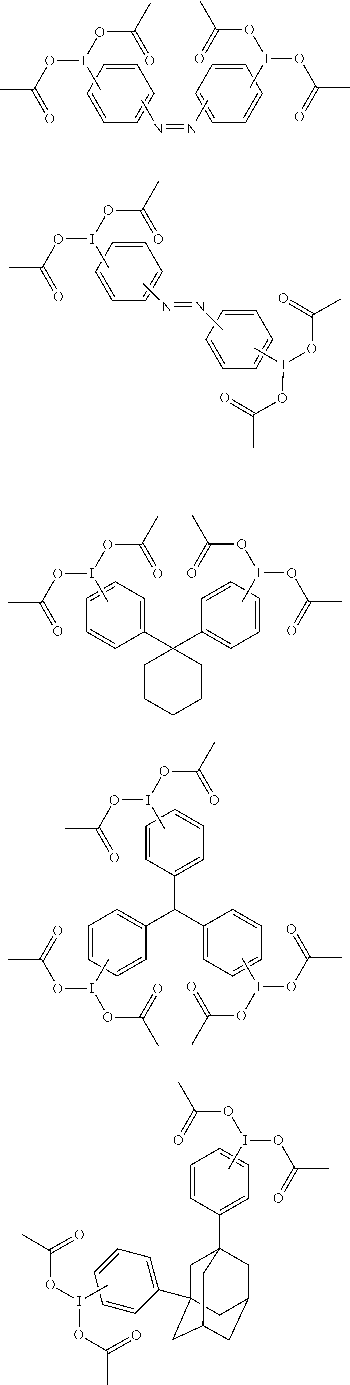

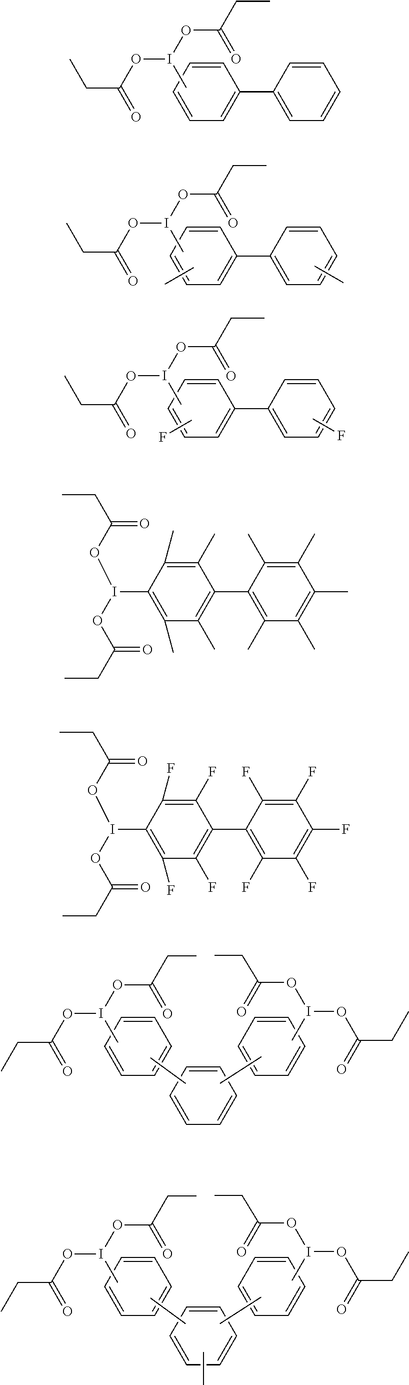

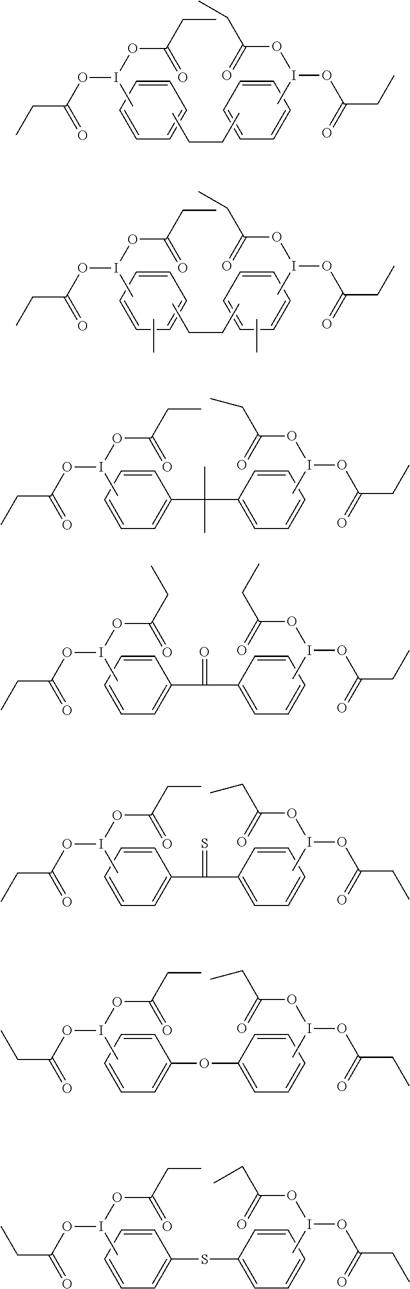

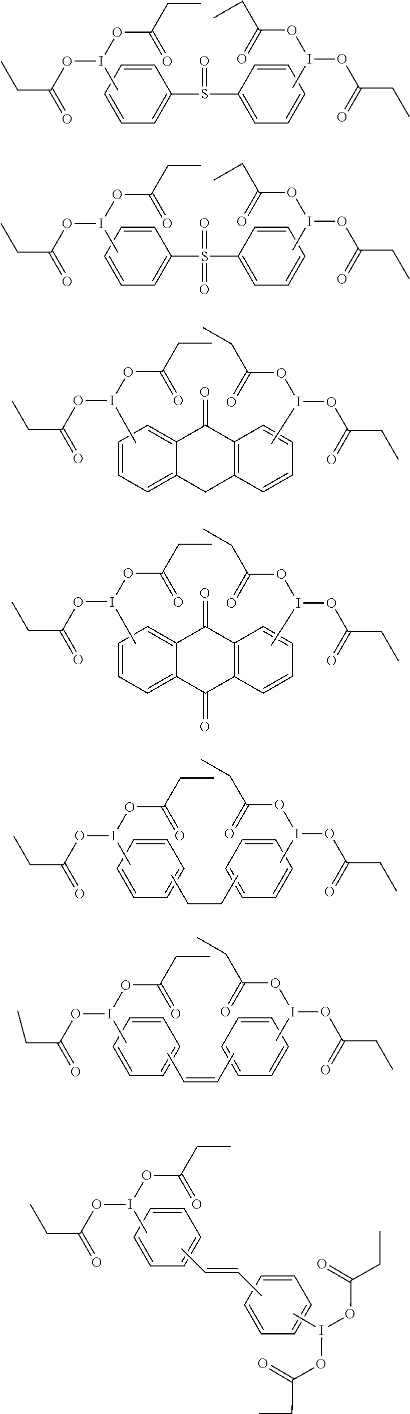

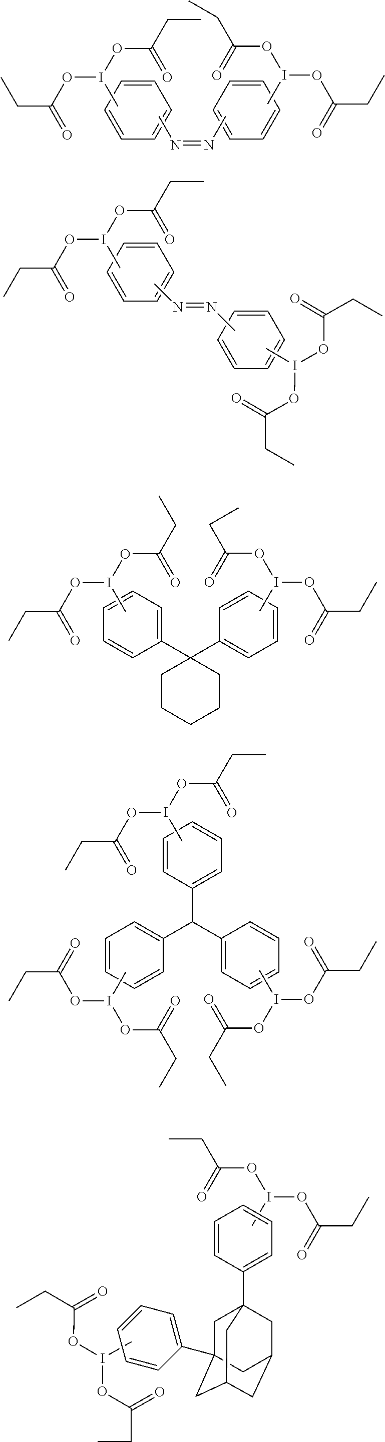

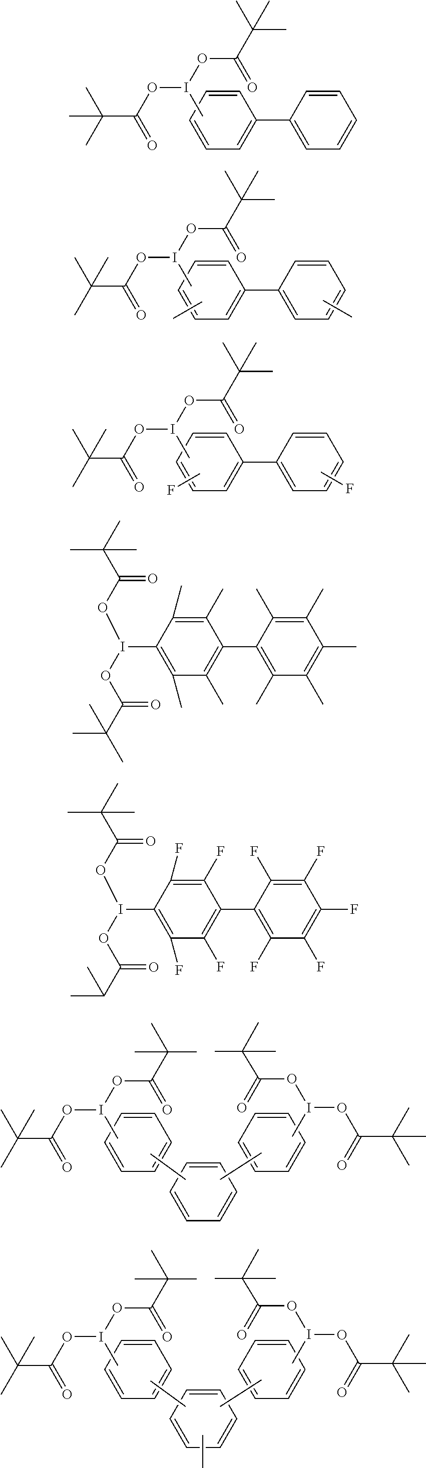

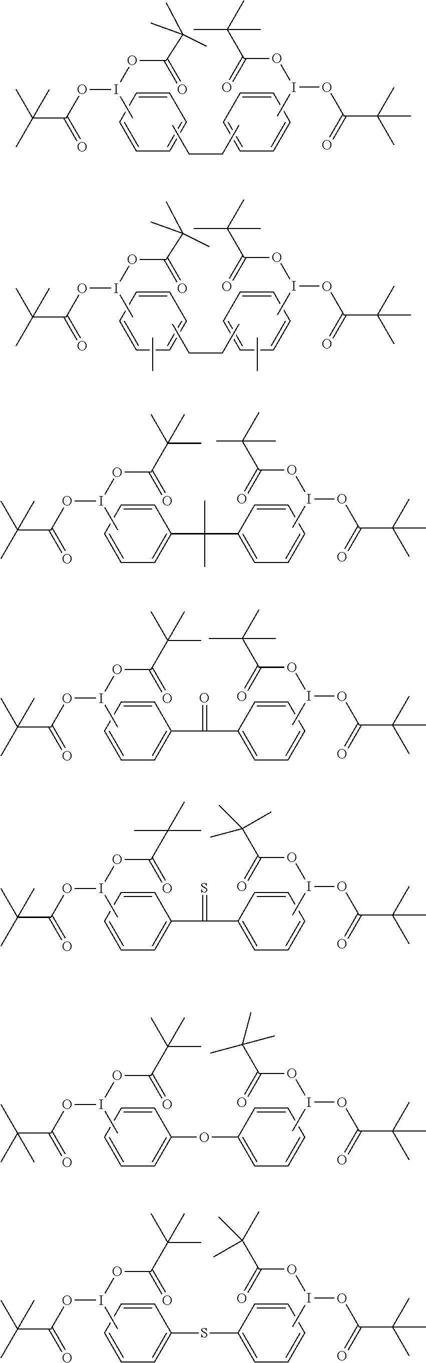

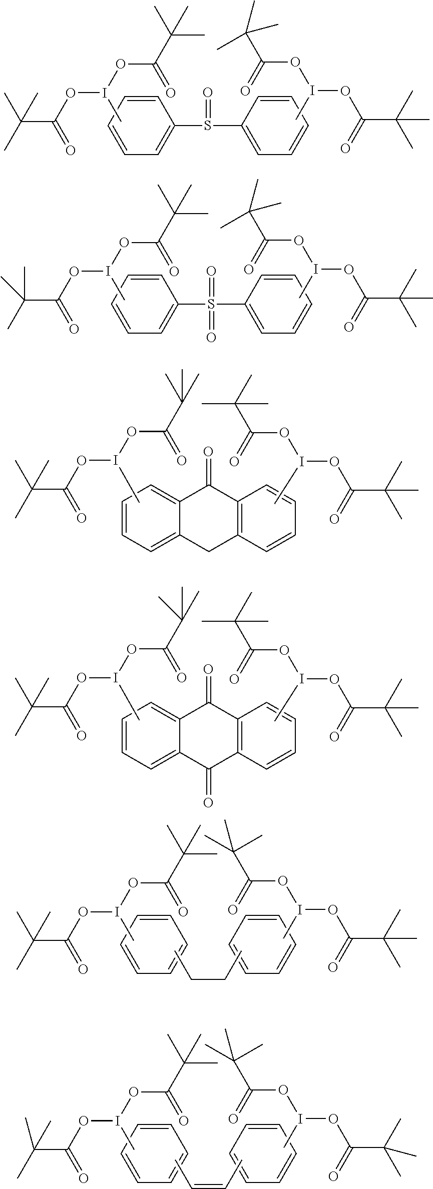

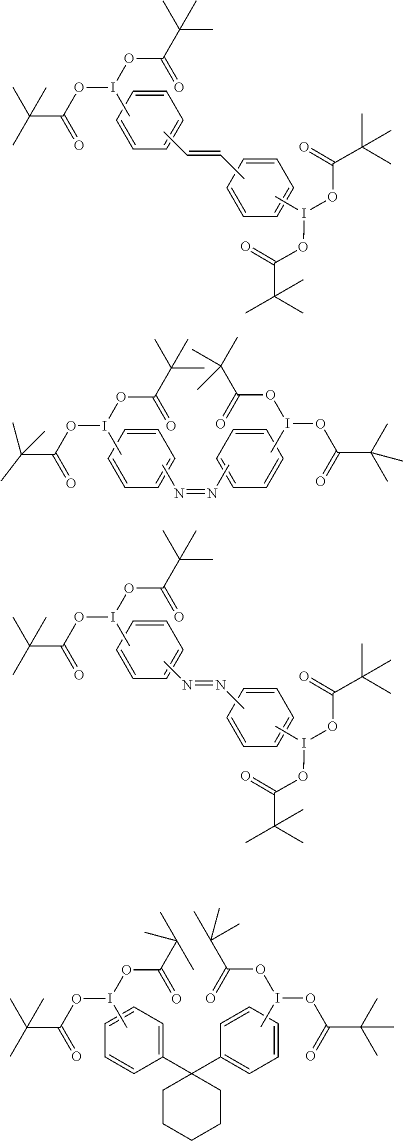

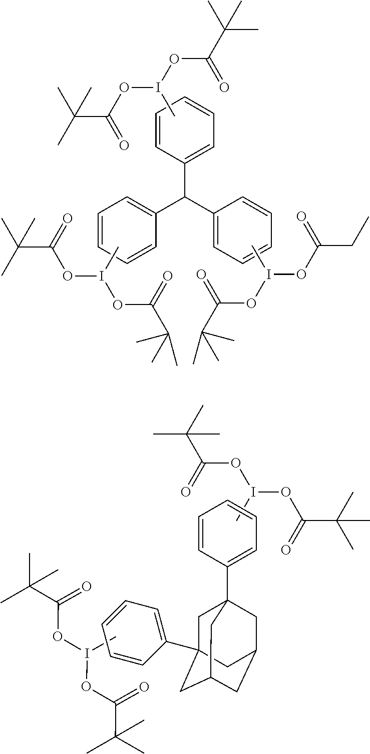

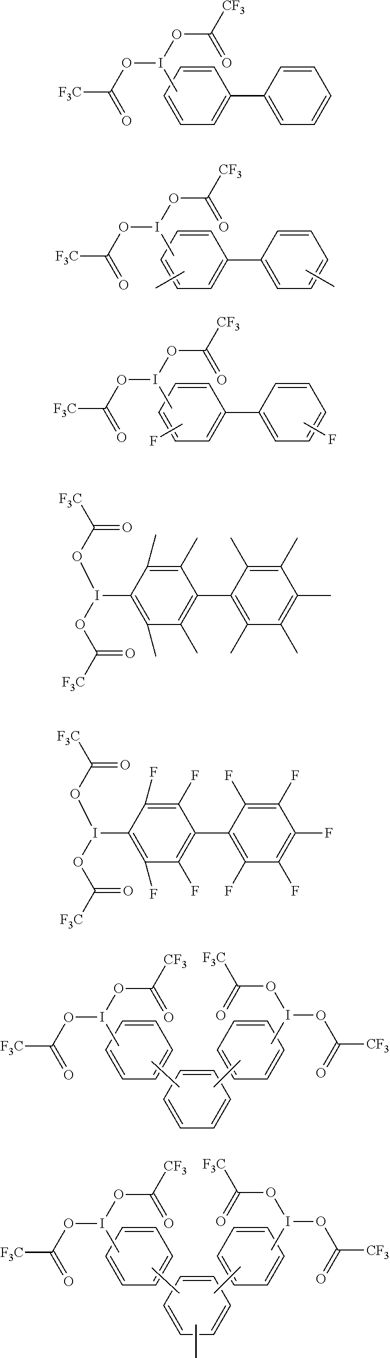

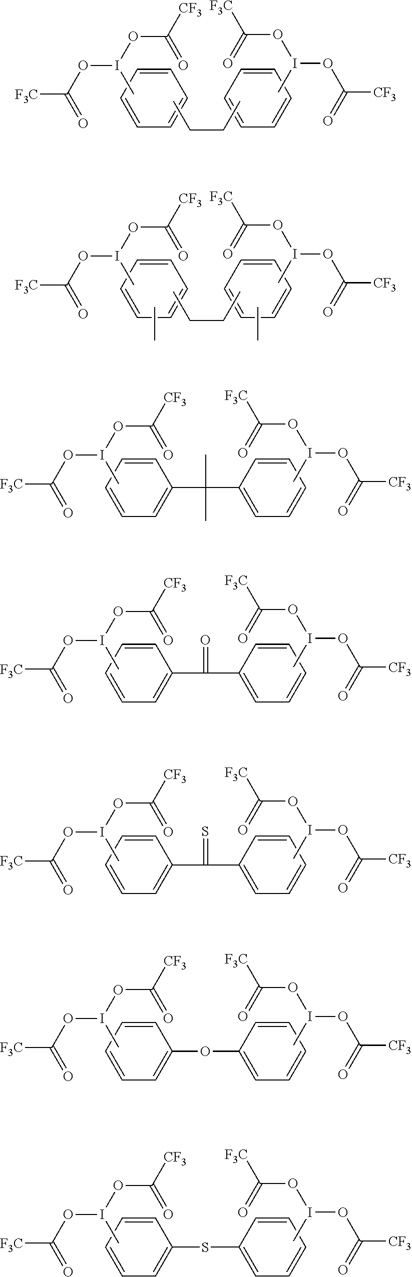

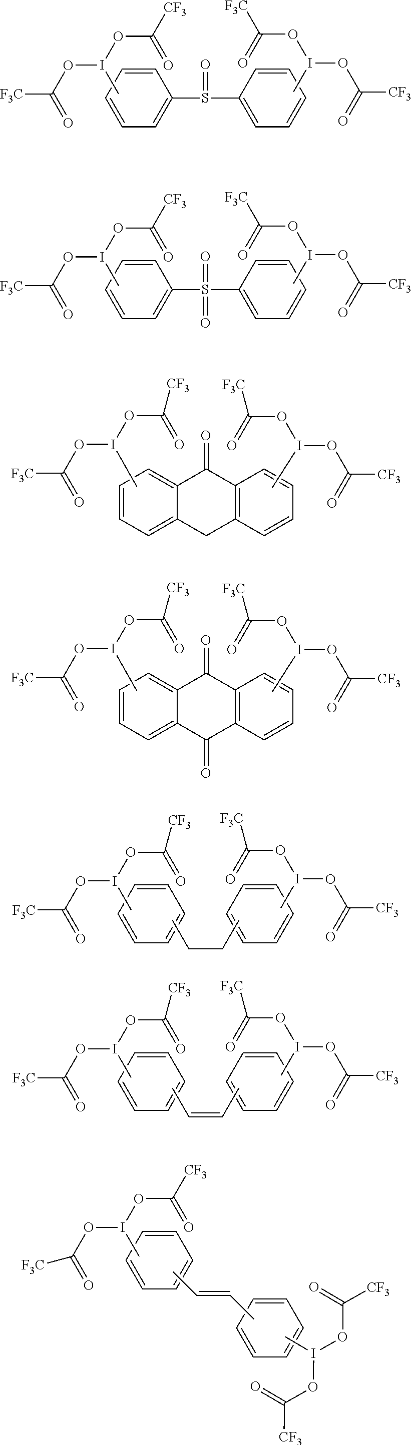

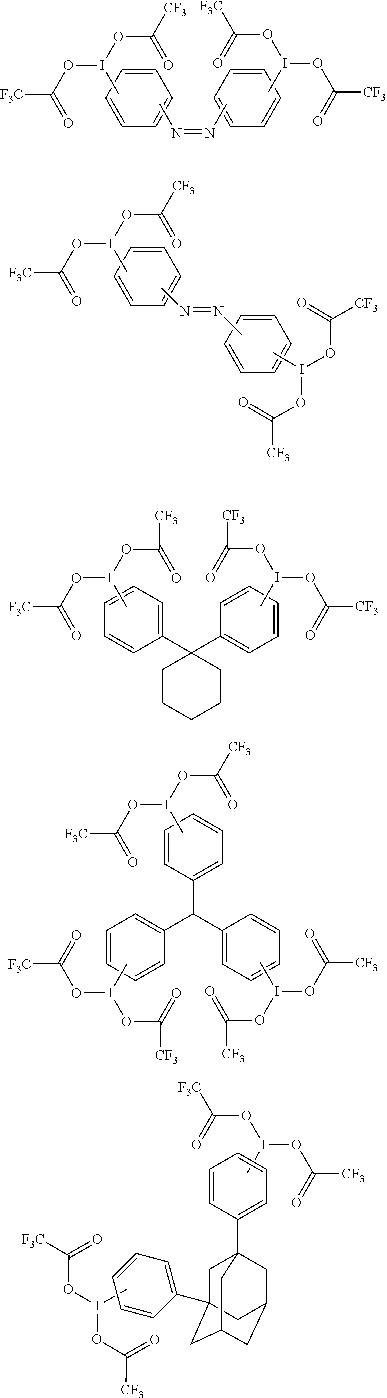

### [Carboxy Group-Containing Compound]

The carboxy group-containing compound is preferably a polymer having a repeat unit having the formula (4) or a compound having the formula (5).

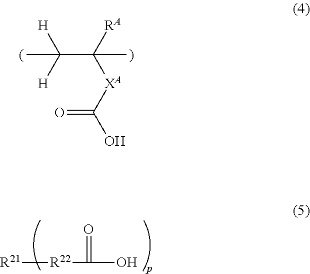

In the formula (4), R^{A} is a hydrogen atom, a halogen atom, a methyl group, or a trifluoromethyl group, X^{A} is a single bond, a phenylene group, a naphthylene group, or *—C(═O)—O—X^{A1}— wherein X^{A1} is a C₁-C₁₀ saturated hydrocarbylene group, a phenylene group, or a naphthylene group, the saturated hydrocarbylene group may contain a hydroxy group, an ether bond, an ester bond, or a lactone ring,
and * designates a valence bond to a carbon atom in a main chain.

In the formula (5), p is 1, 2, 3, or 4.

In the formula (5), R²¹ is a C₁-C₄₀ p-valent hydrocarbon group or a C₂-C₄₀ p-valent heterocyclic group, when p is 2, R²¹ may be an ether bond, a carbonyl group, an azo group, a thioether bond, a carbonate bond, a carbamate bond, a sulfinyl group, or a sulfonyl group, and some or all of the hydrogen atoms in the p-valent hydrocarbon group or the p-valent heterocyclic group may be substituted by a heteroatom-containing moiety, and some constituent —CH₂— in the p-valent hydrocarbon group may be replaced by a heteroatom-containing moiety.

In the formula (5), R²² is a single bond or a C₁-C₁₀ hydrocarbylene group, and some or all of the hydrogen atoms in the hydrocarbylene group may be substituted by a heteroatom-containing moiety, and some constituent —CH₂— in the hydrocarbylene group may be replaced by a heteroatom-containing moiety, and when p is 2, 3, or 4, each R²² may be the same or different from each other.

The p-valent hydrocarbon group of R²¹ may be saturated or unsaturated and straight, branched or cyclic. The p-valent hydrocarbon group is obtained by removing p number of hydrogen atoms from a hydrocarbon. Suitable hydrocarbons include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Exemplary C₁-C₄₀ alkanes include methane, ethane, propane, butane, pentane, hexane, heptane, octane, nonane, decane, and structural isomers thereof.

Exemplary C₂-C₄₀ alkenes include ethylene, propylene, butene, pentene, hexene, heptene, octene, nonene, decene, and structural isomers thereof.

Exemplary C₂-C₄₀ alkynes include acetylene, propyne, butyne, pentyne, hexyne, heptyne, octyne, nonyne, decyne, and structural isomers thereof.

Exemplary C₃-C₄₀ cyclic saturated hydrocarbons include cyclopropane, cyclobutane, cyclohexane, cycloheptane, cyclooctane, adamantane, and norbornane.

Exemplary C₃-C₄₀ cyclic unsaturated hydrocarbons include cyclopropene, cyclobutene, cyclopentene, cyclohexene, cycloheptene, cyclooctene, and norbornene.

Exemplary C₆-C₄₀ aromatic hydrocarbons include benzene, naphthalene, and biphenyl.

The p-valent heterocyclic group of R²¹ is obtained by removing p number of hydrogen atoms from a heterocyclic compound. Suitable heterocyclic compounds include furane, pyridine, pyrazole, and thiazolidine.

In the p-valent hydrocarbon group and p-valent heterocyclic group, some or all of the hydrogen atoms may be substituted by a moiety containing a heteroatom such as oxygen, sulfur, nitrogen or halogen, so that the group may contain hydroxy, cyano, fluorine, chlorine, bromine, or iodine. In the p-valent hydrocarbon group, some constituent —CH₂— may be replaced by a moiety containing a heteroatom such as oxygen, sulfur or nitrogen, so that the group may contain carbonyl, ether bond, thioether bond, ester bond, sulfonic ester bond, carbonate bond, carbamate bond, lactone ring, sultone ring, or carboxylic anhydride (—C(═O)—O—C(═O)—).

The hydrocarbylene group of R²² may be saturated or unsaturated and straight, branched or cyclic. Examples thereof include C₁-C₂₀ alkanediyl groups such as methanediyl, ethane-1,1-diyl, ethane-1,2-diyl, propane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, and dodecane-1,12-diyl, C₃-C₂₀ cyclic saturated hydrocarbylene groups such as cyclopentanediyl, cyclohexanediyl, norbornanediyl, and adamantanediyl, C₂-C₂₀ unsaturated aliphatic hydrocarbylene groups such as vinylene and propene-1,3-diyl, C₆-C₂₀ arylene groups such as phenylene and naphthylene, and combinations thereof. In the hydrocarbylene group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain hydroxy, cyano, fluorine, chlorine, bromine, iodine, carbonyl, ether bond, thioether bond, ester bond, sulfonic ester bond, carbonate bond, carbamate bond, lactone ring, sultone ring, or carboxylic anhydride.

Of the carboxylic acids, those compounds of formula (5) wherein p is 2, 3, or 4 are preferred because when mixed with the hypervalent iodine compound, they form a high molecular weight, robust resist film having etching resistance and developer resistance.

Examples of the carboxy group-containing repeat unit having formula (4) are shown below, but not limited thereto. In the following formula, R^{A} is the same as described above.

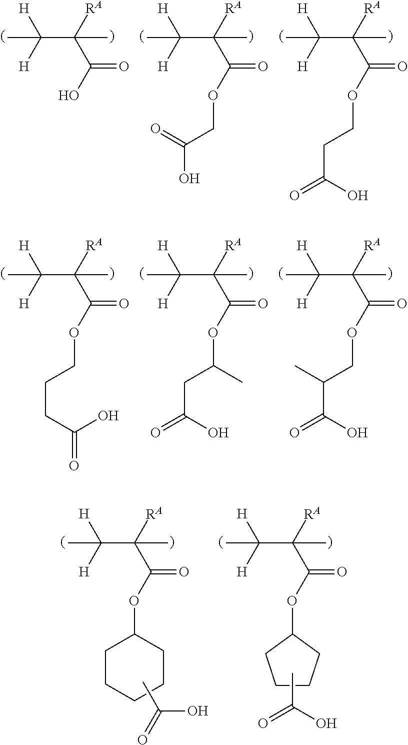

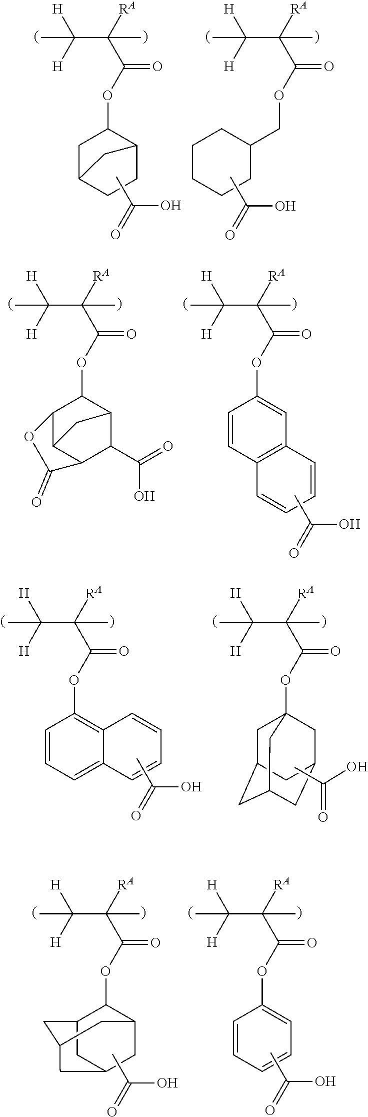

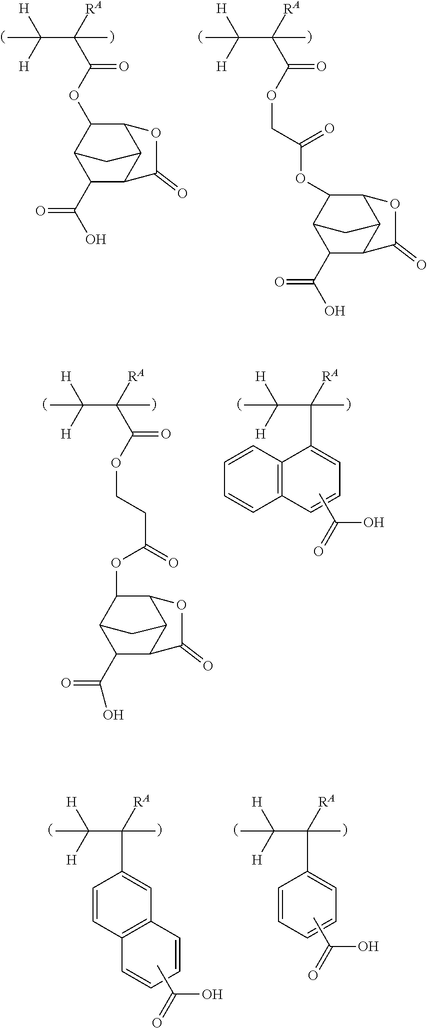

Examples of the carboxylic acid having formula (5) are shown below, but not limited thereto.

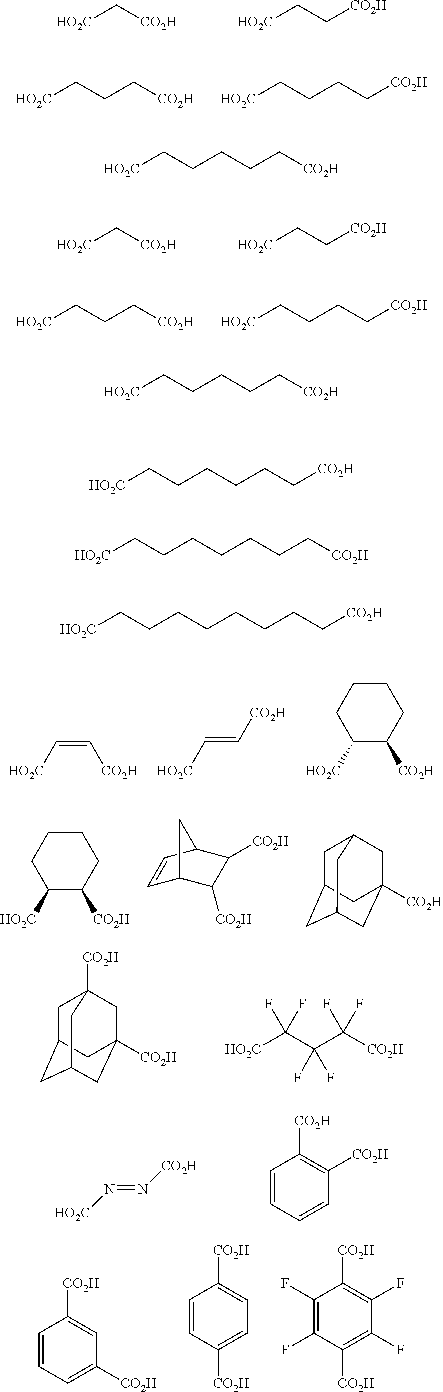

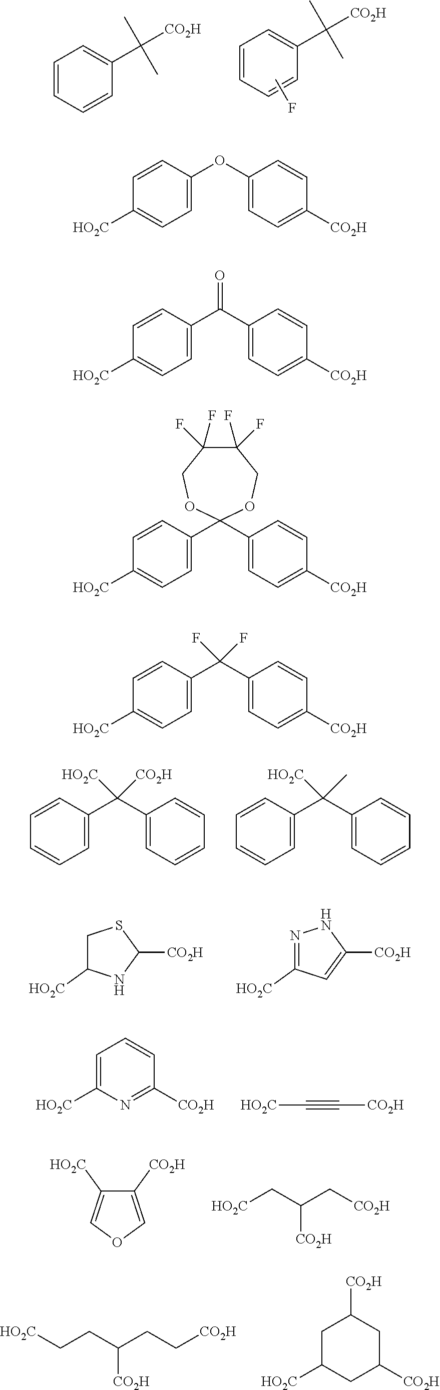

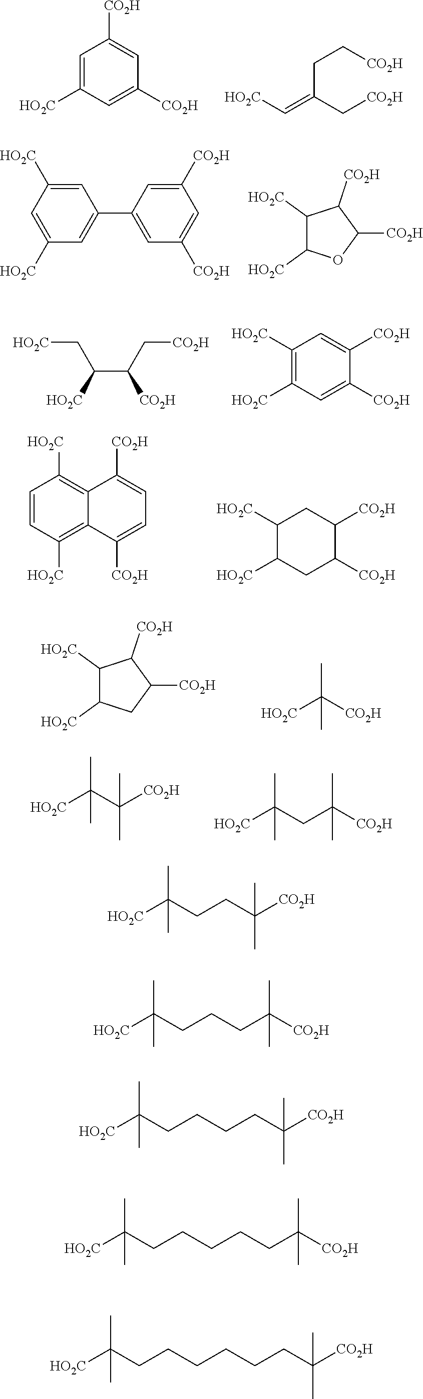

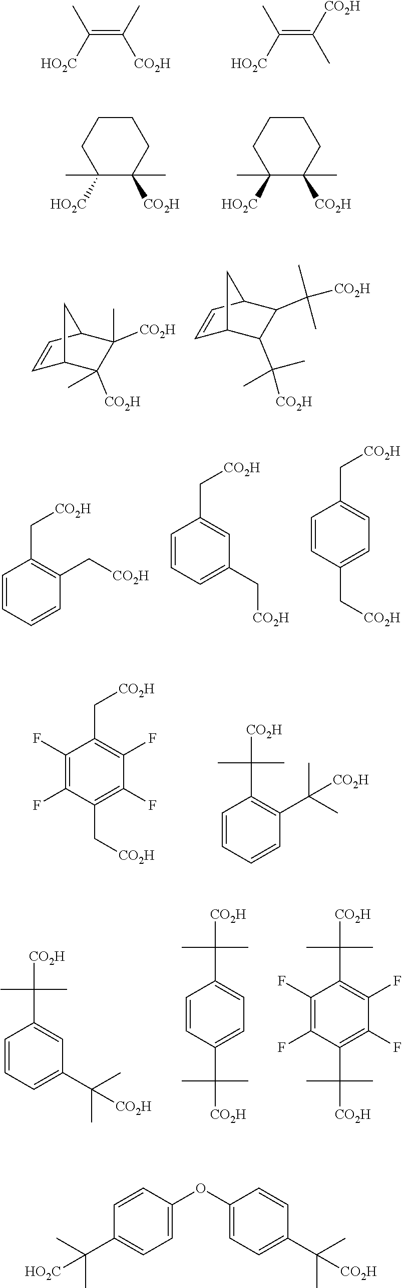

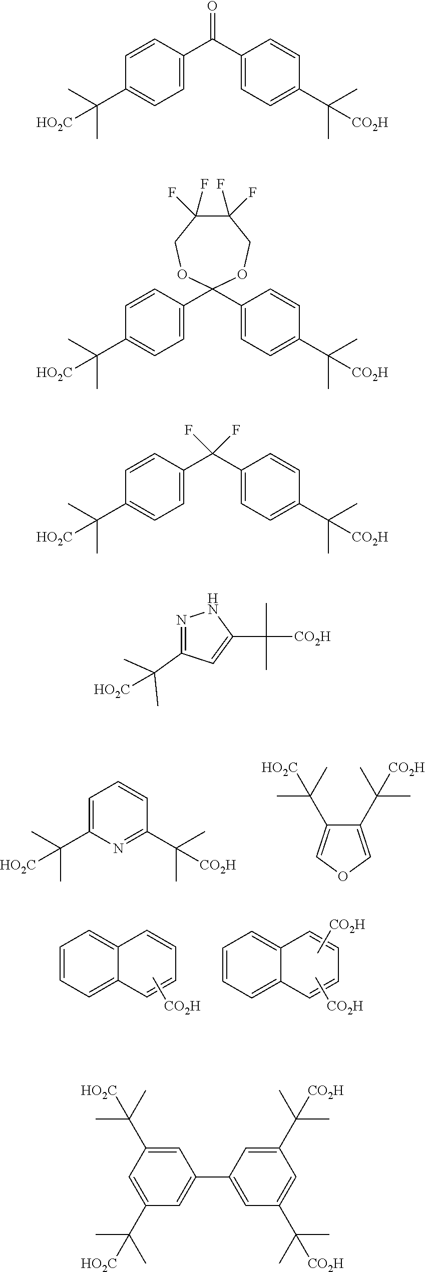

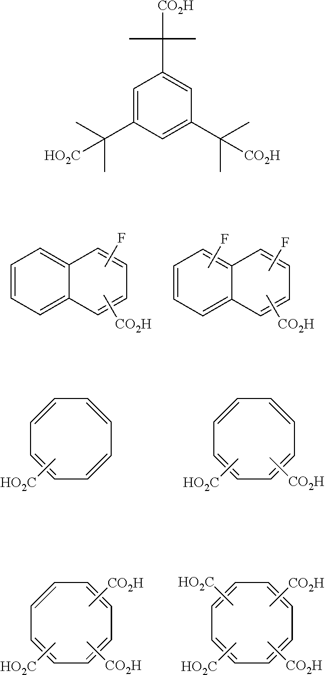

The carboxy group-containing polymer containing a repeat unit having the formula (4) may further contain a repeat unit other than the repeat unit having the formula (4) (hereinafter, also referred to as another repeat unit). Another repeat unit is not particularly limited, and a repeat unit is preferable that is capable of improving the solubility, in a solvent, of an insoluble polymer containing only a repeat unit having a carboxy group. Another repeat unit is preferably a repeat unit having a cyclic structure that is a rigid skeleton and expected to have high etching resistance, or a repeat unit having a styrene skeleton.

Examples of another repeat unit are shown below, but not limited thereto. In the following formula, R^{A} is the same as described above, and X^{B} is each independently —CH₂— or —O—.

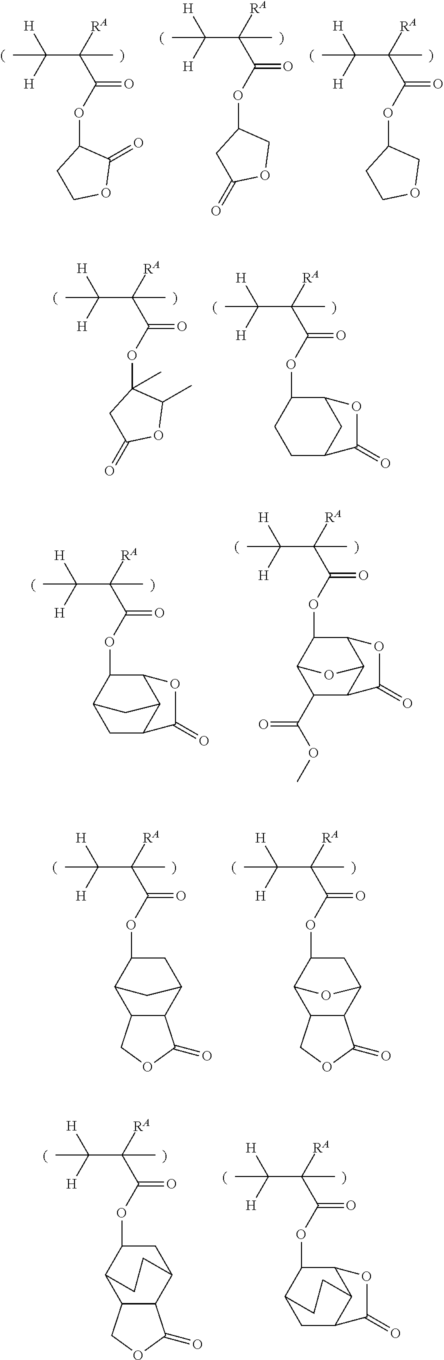

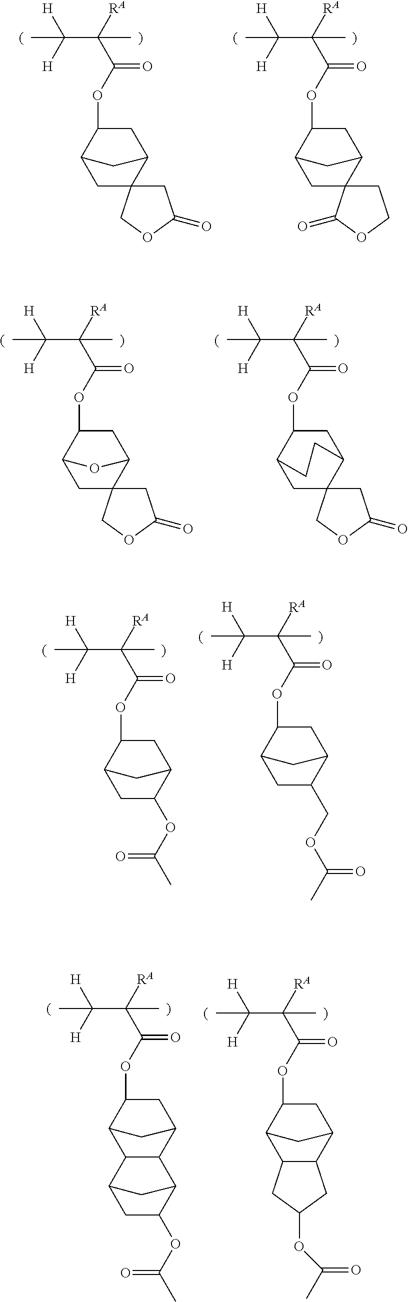

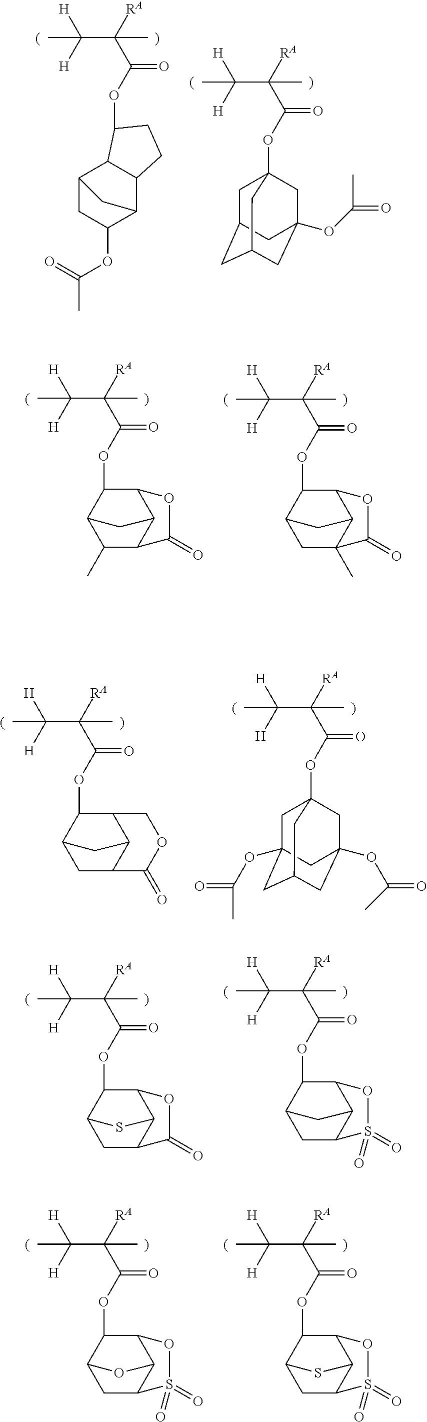

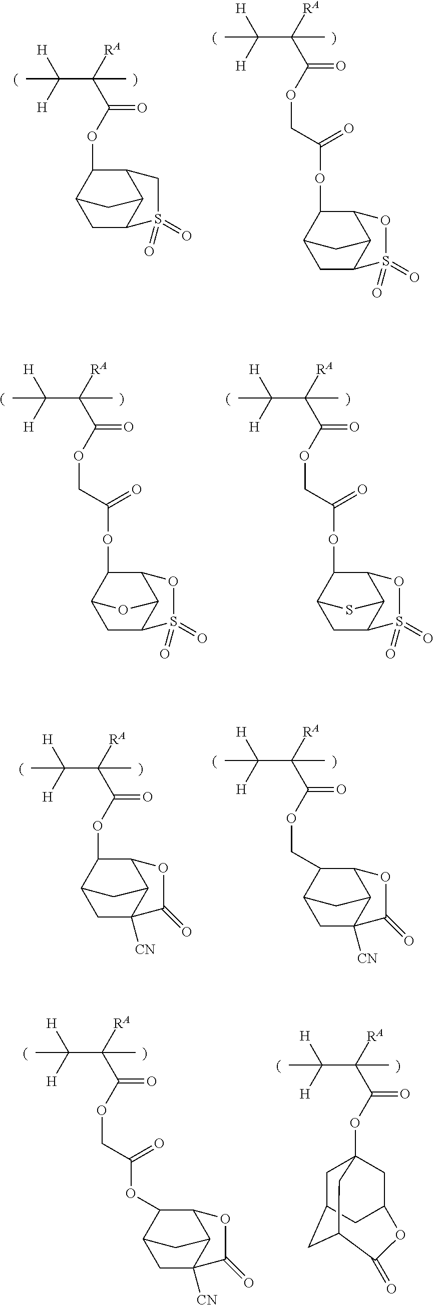

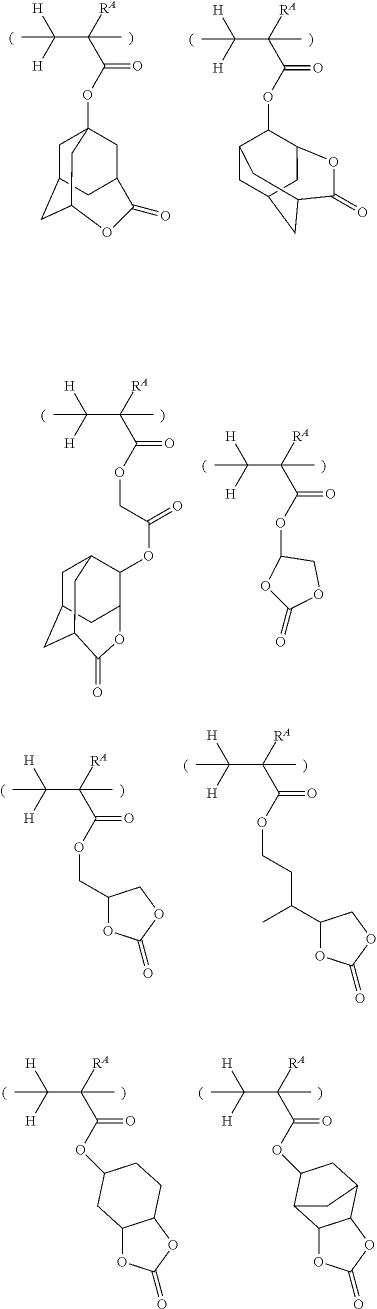

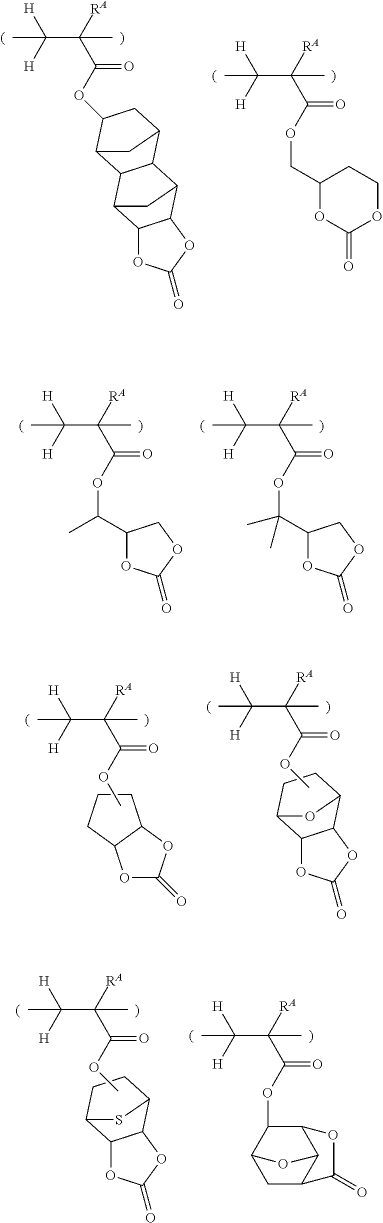

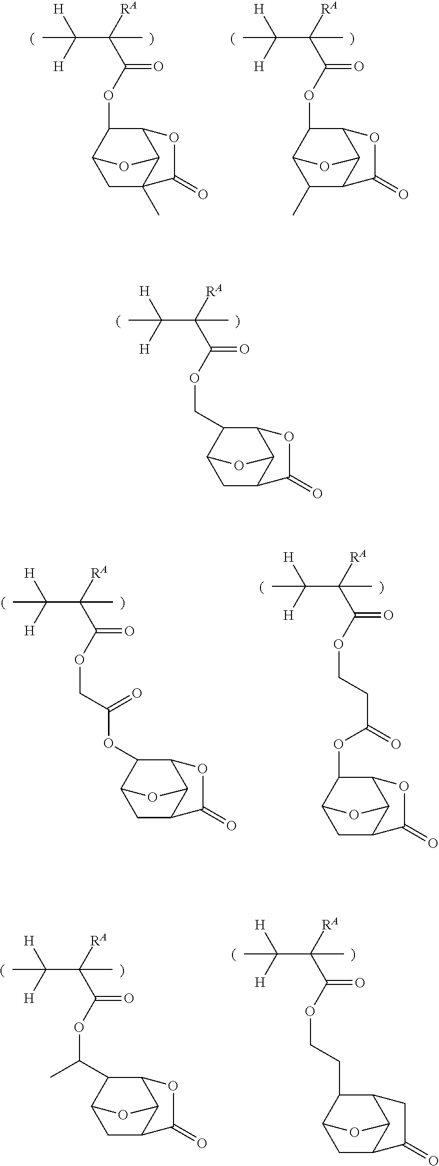

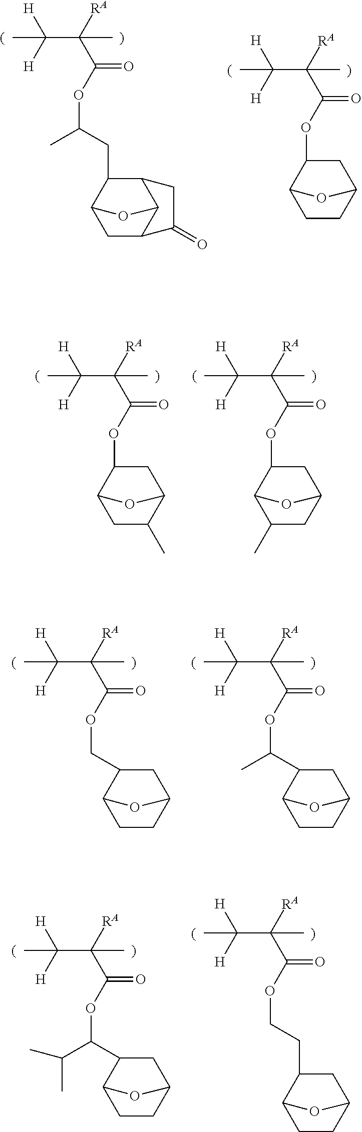

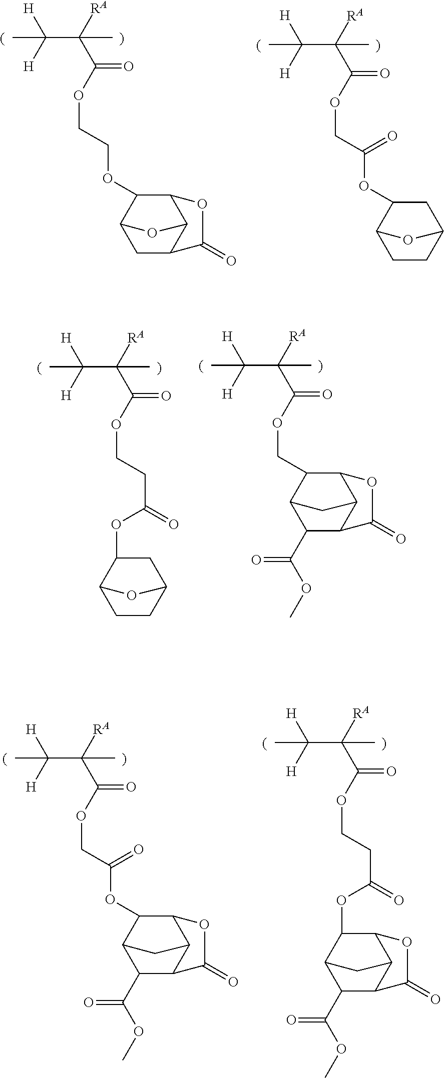

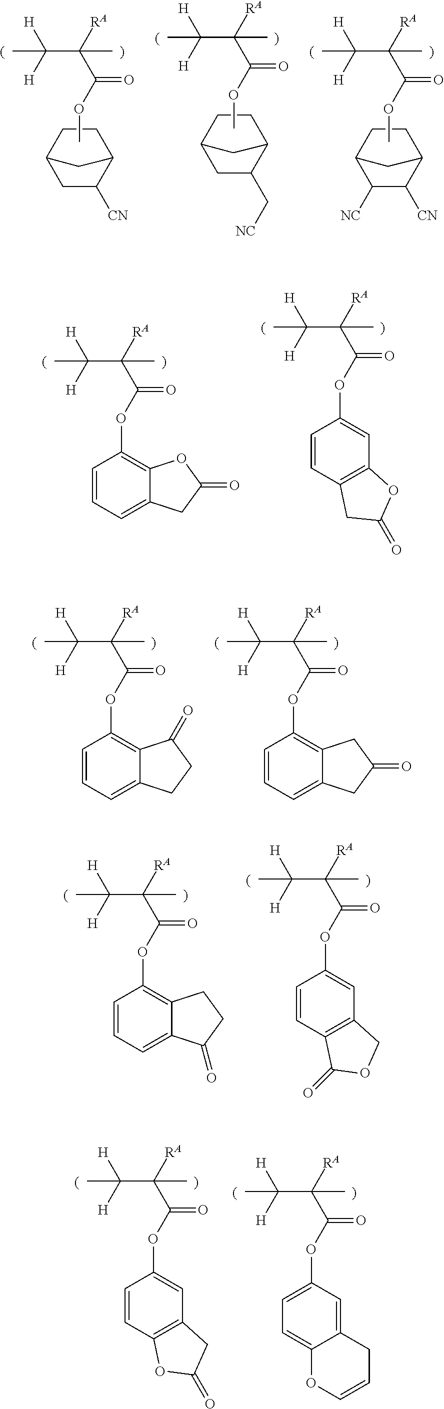

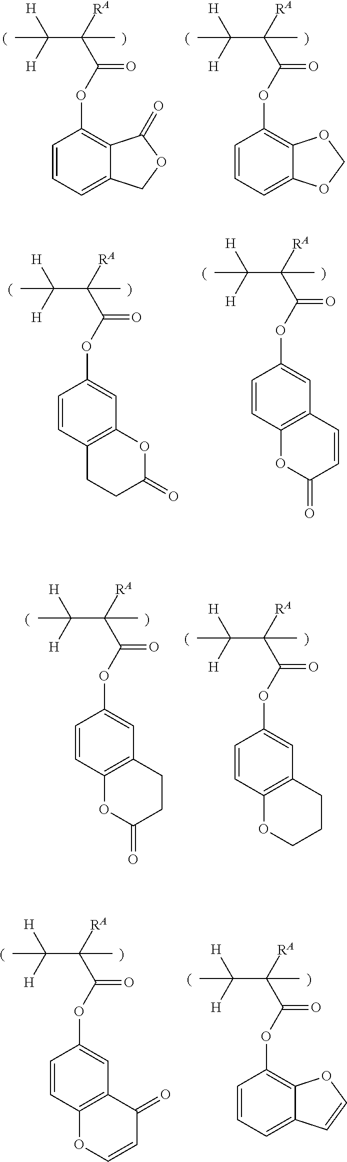

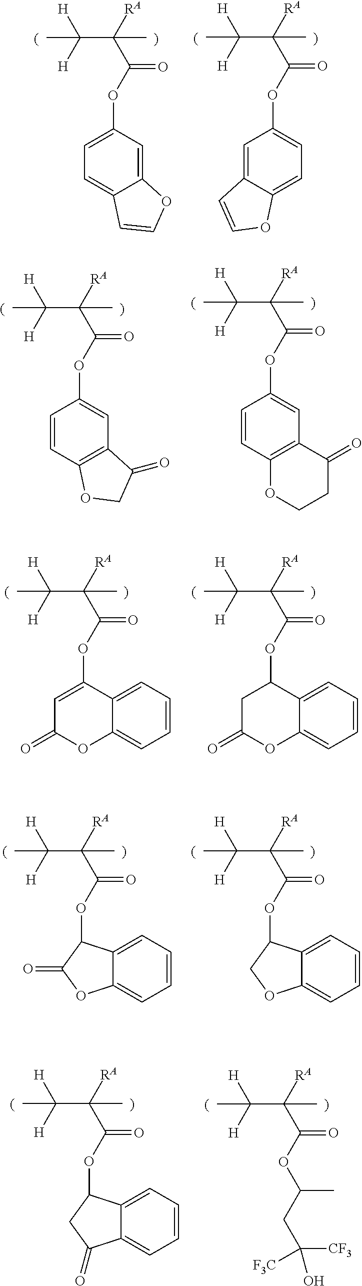

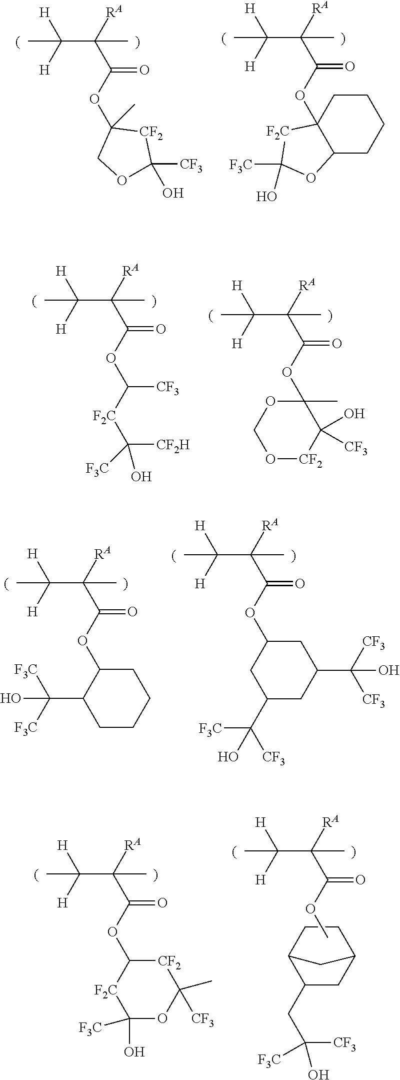

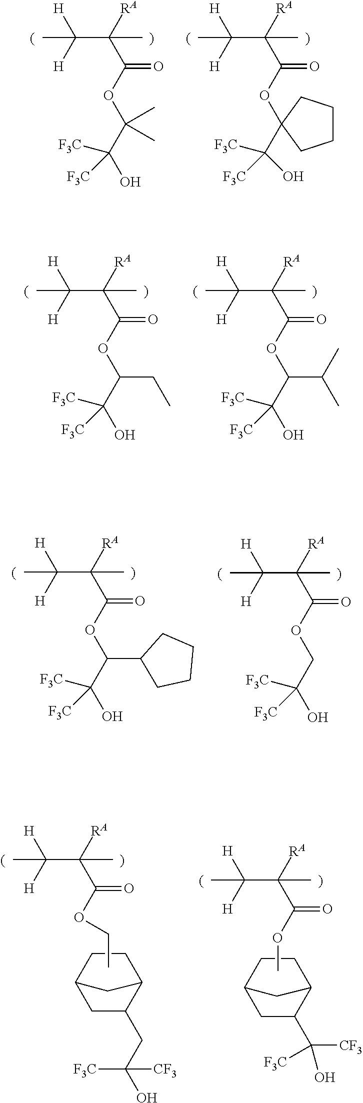

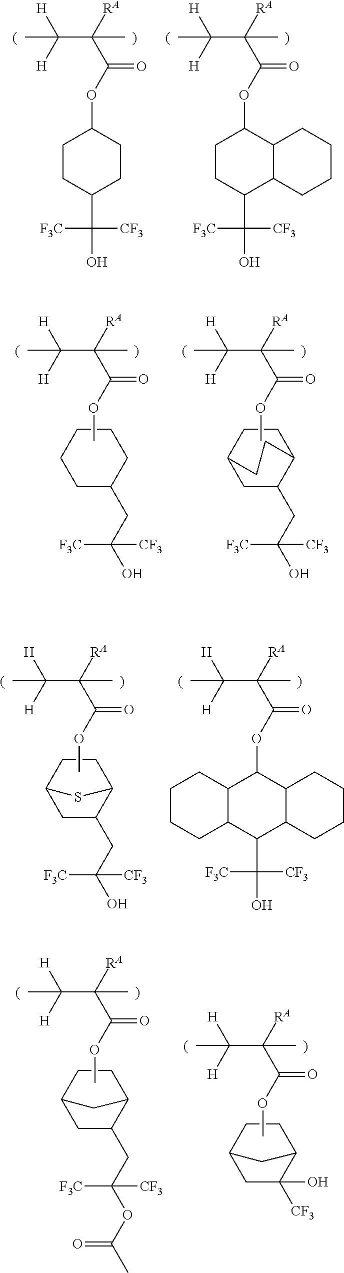

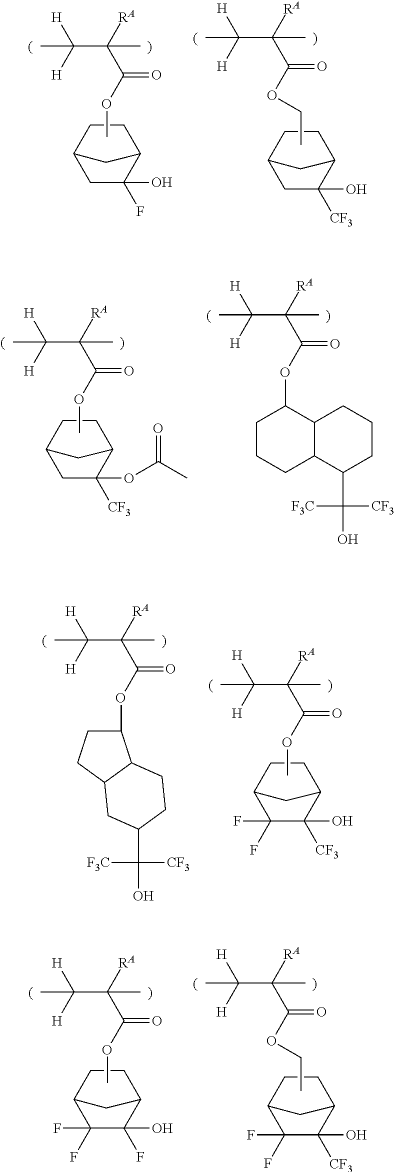

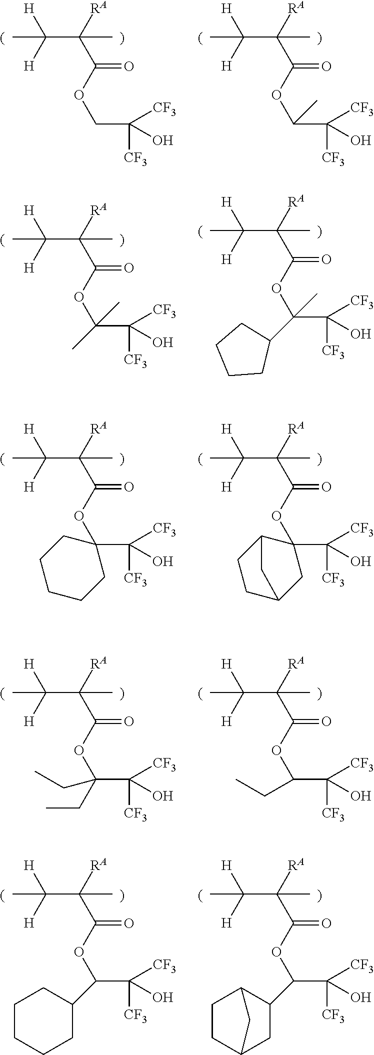

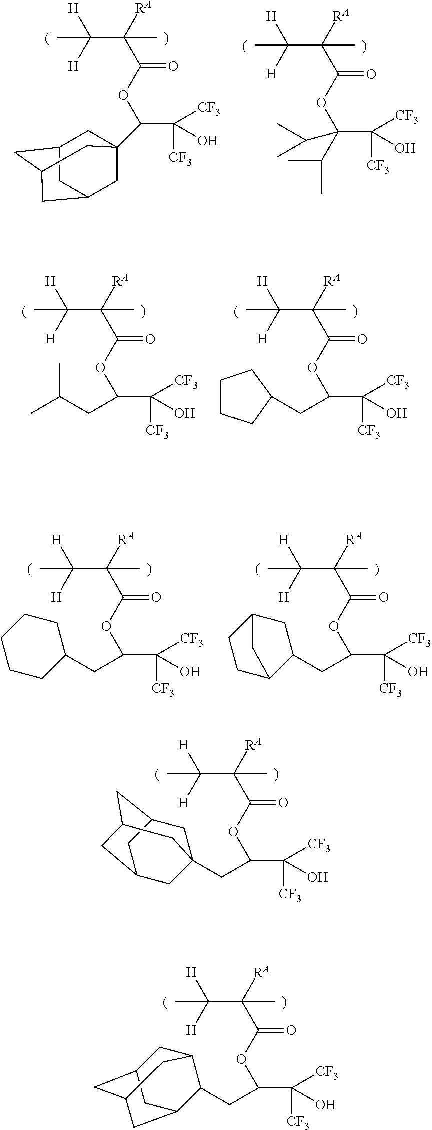

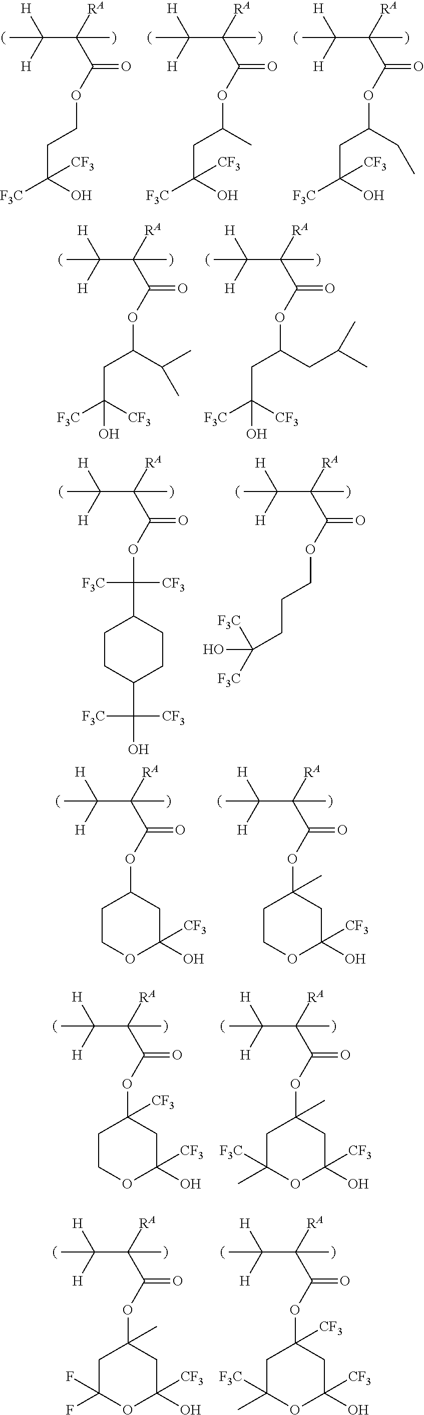

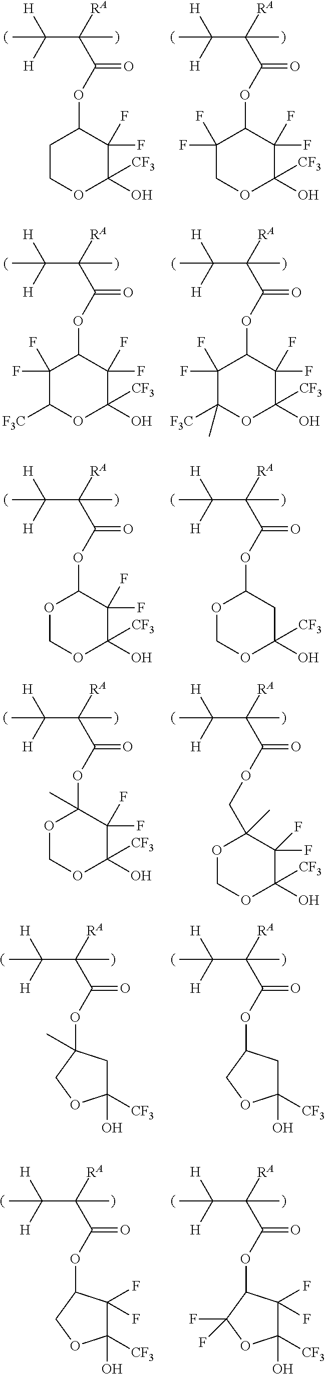

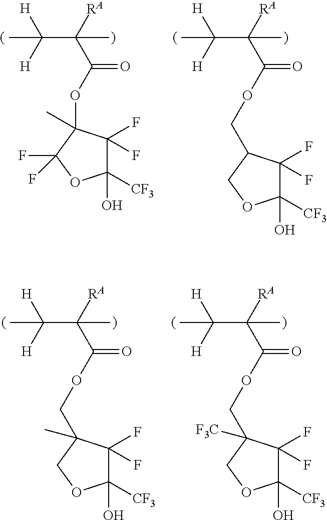

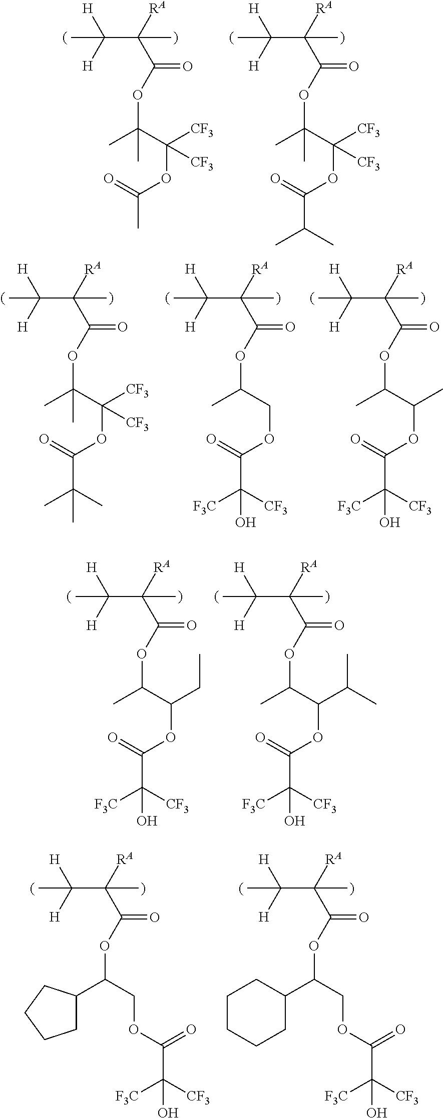

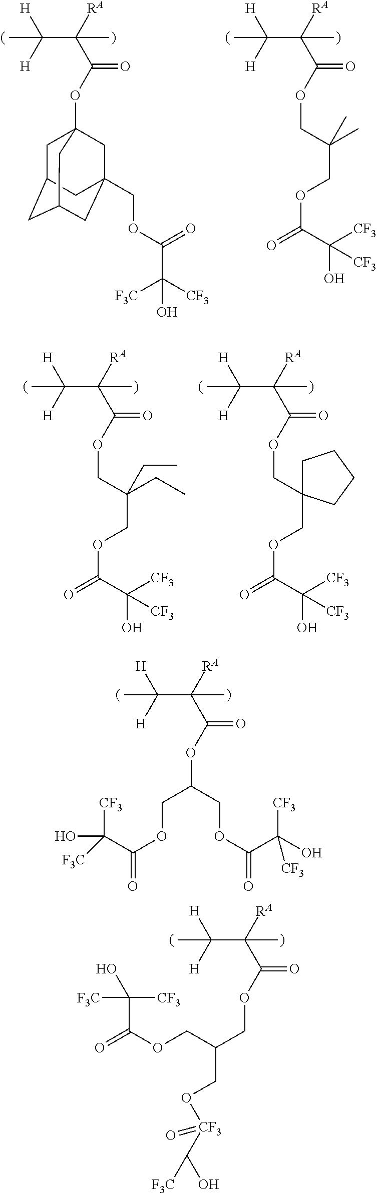

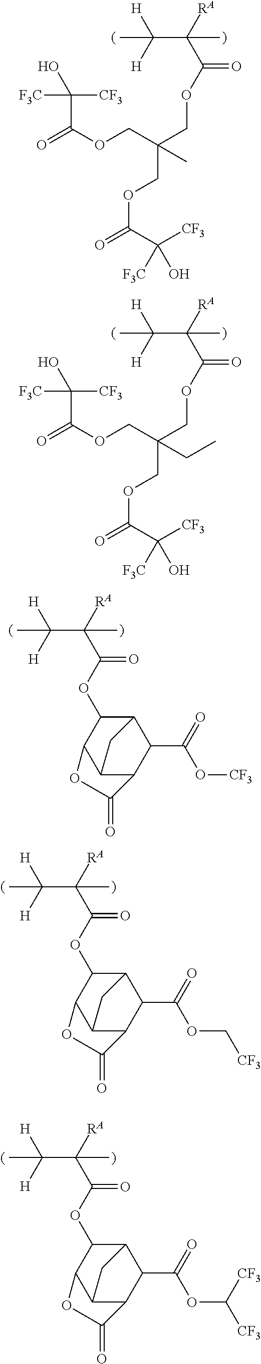

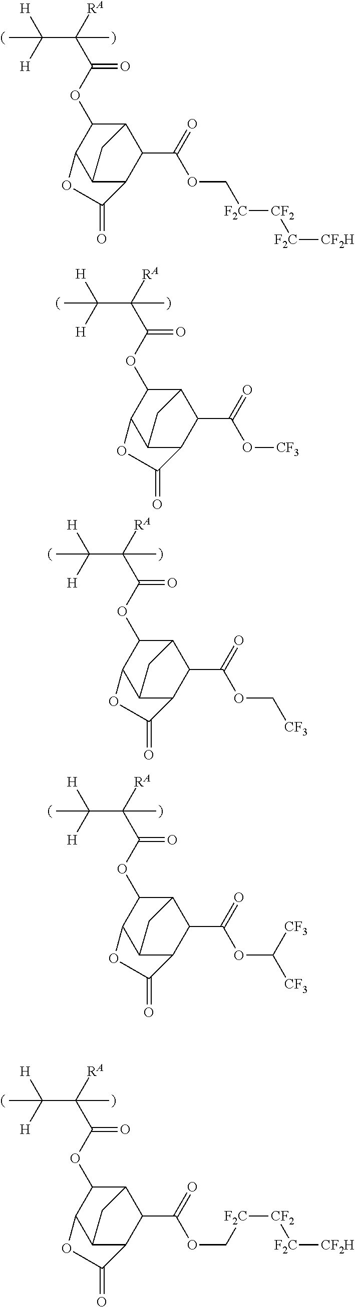

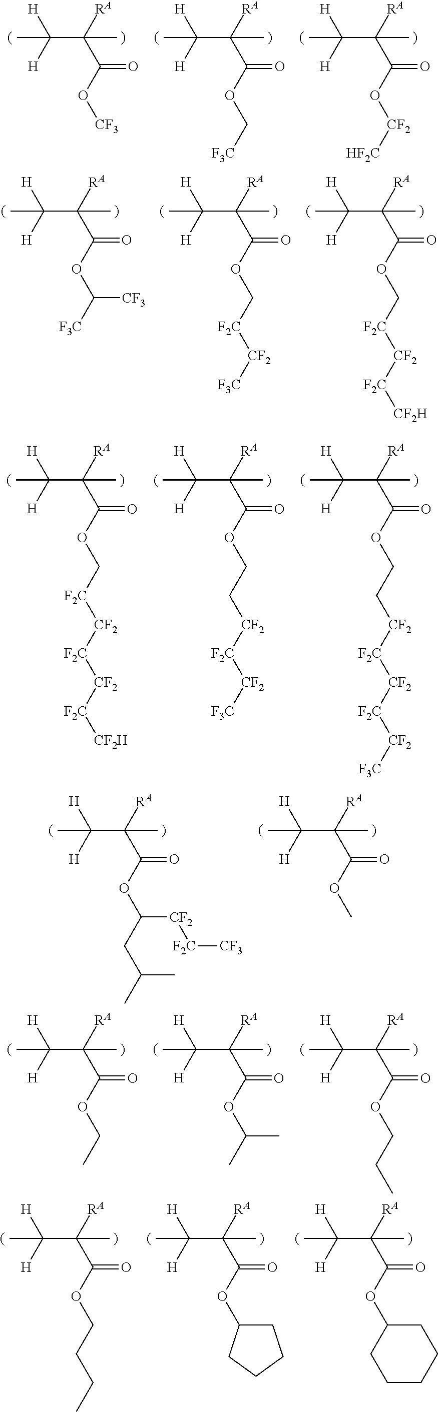

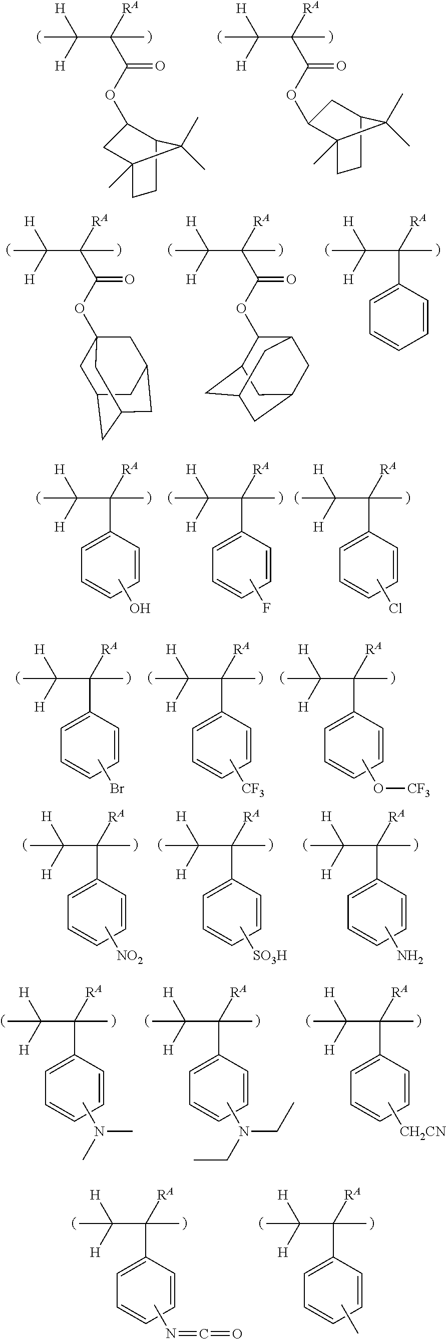

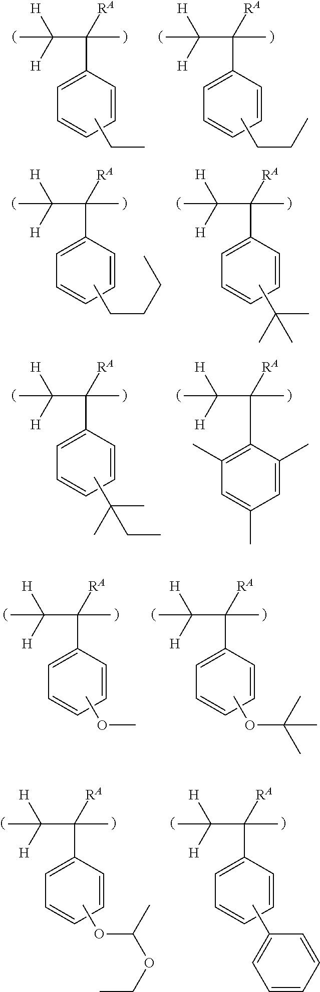

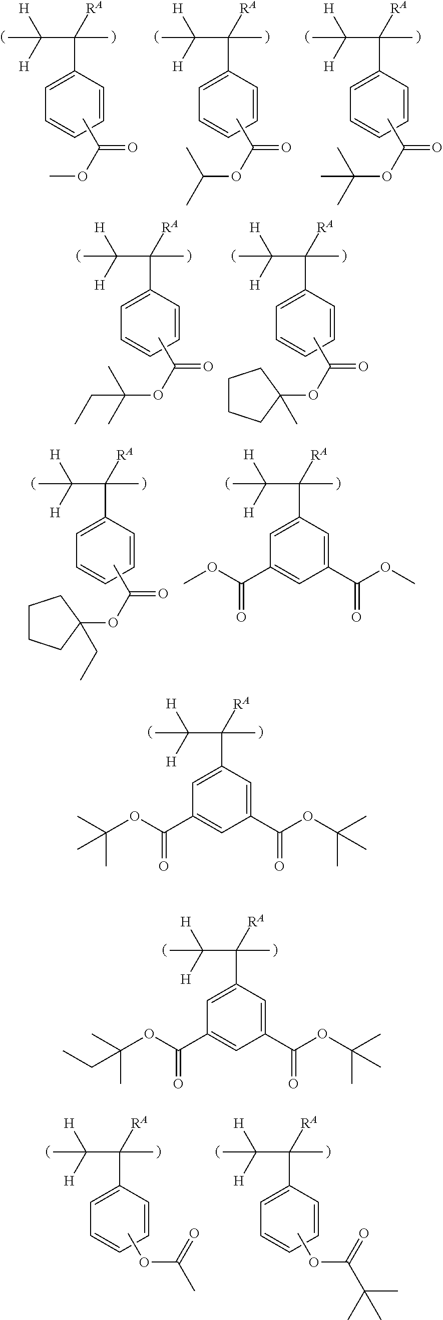

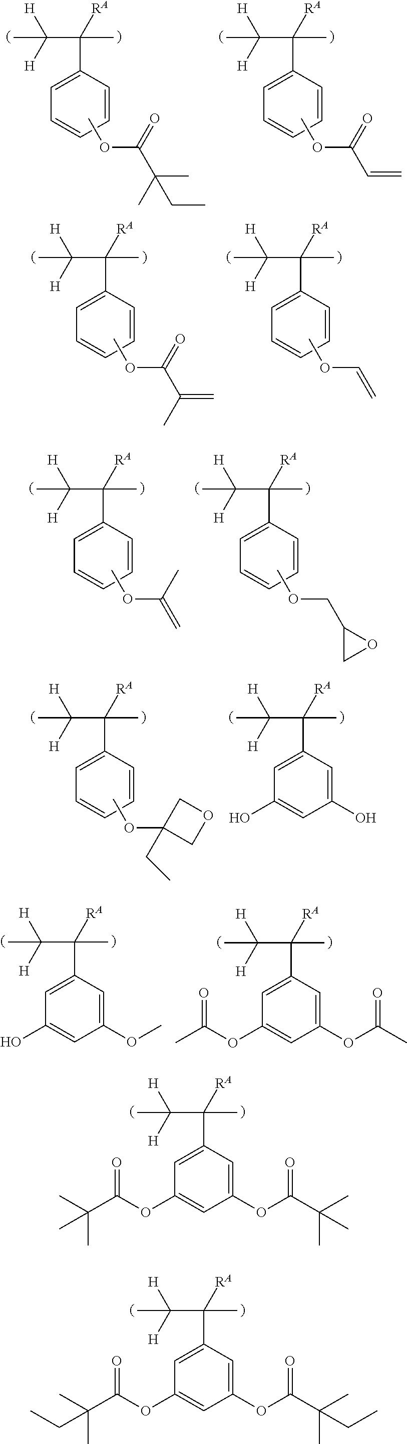

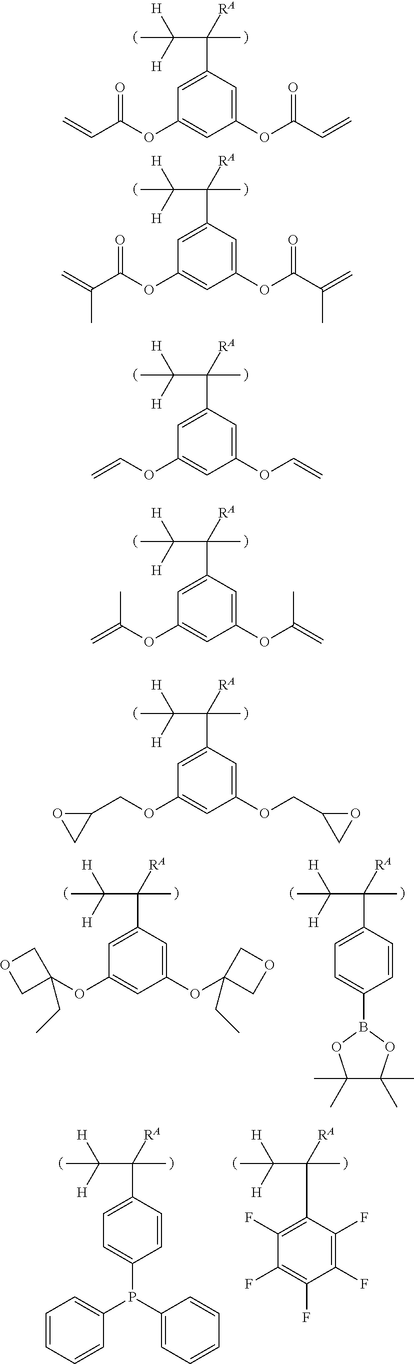

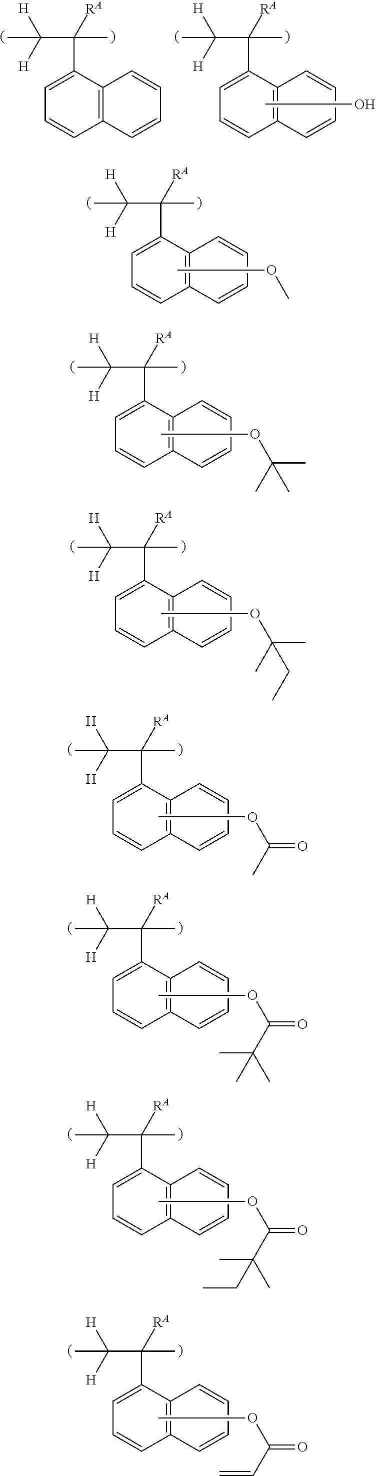

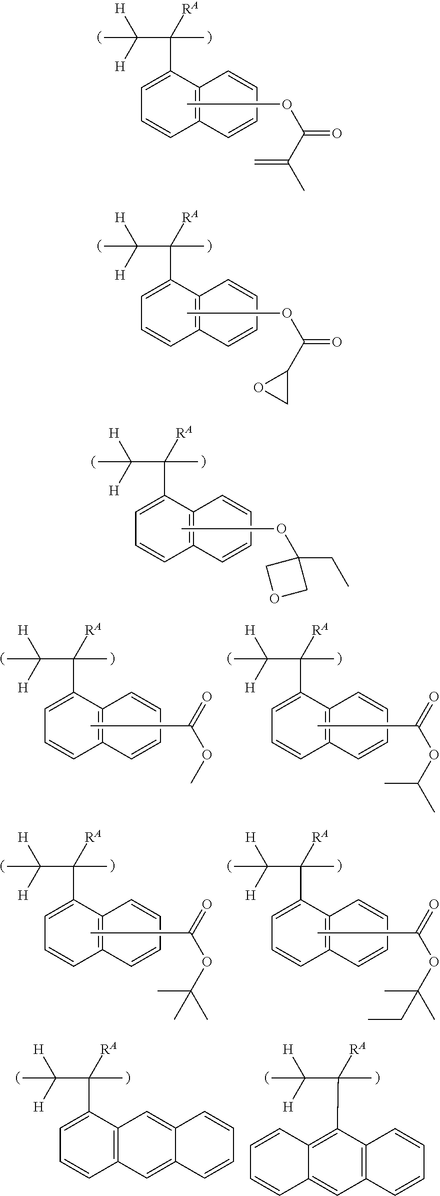

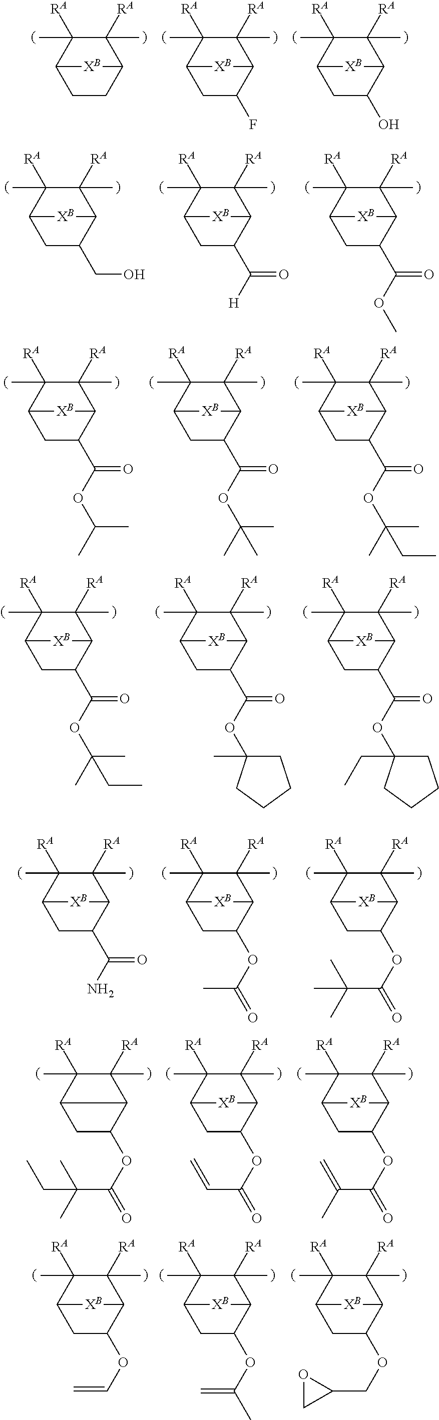

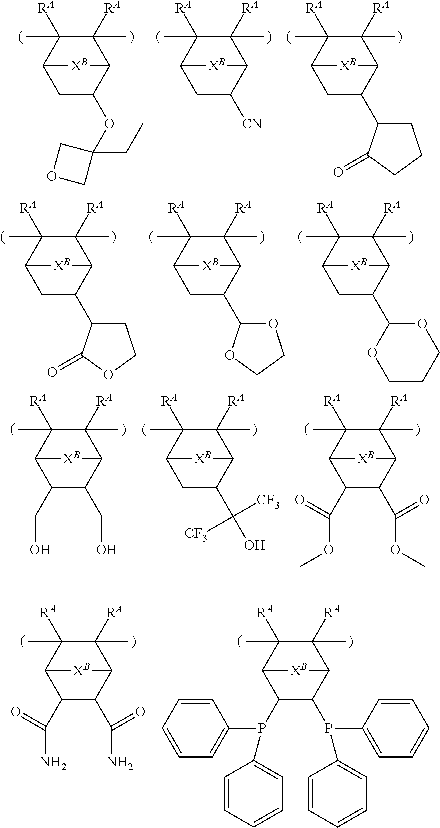

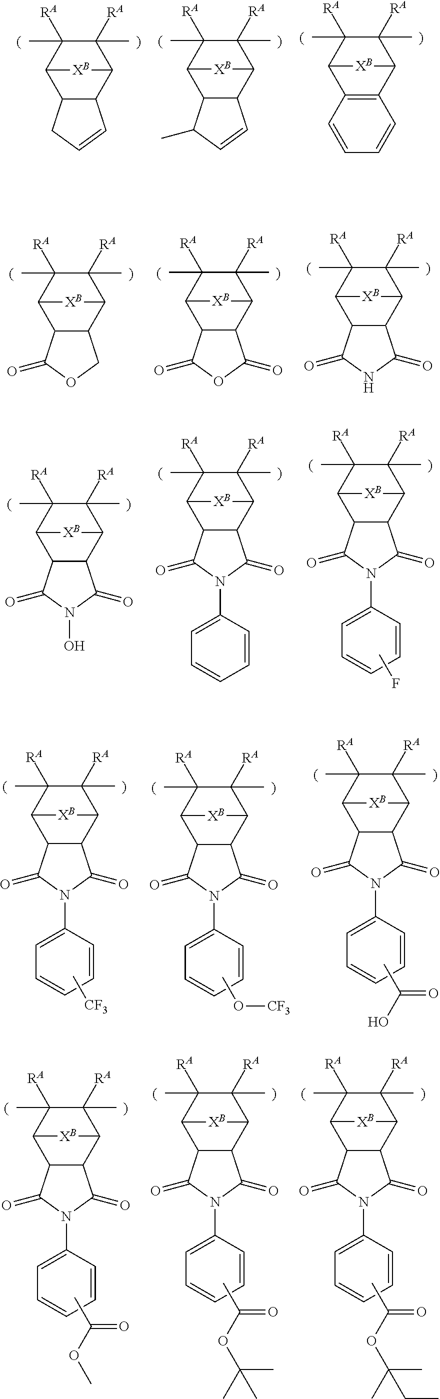

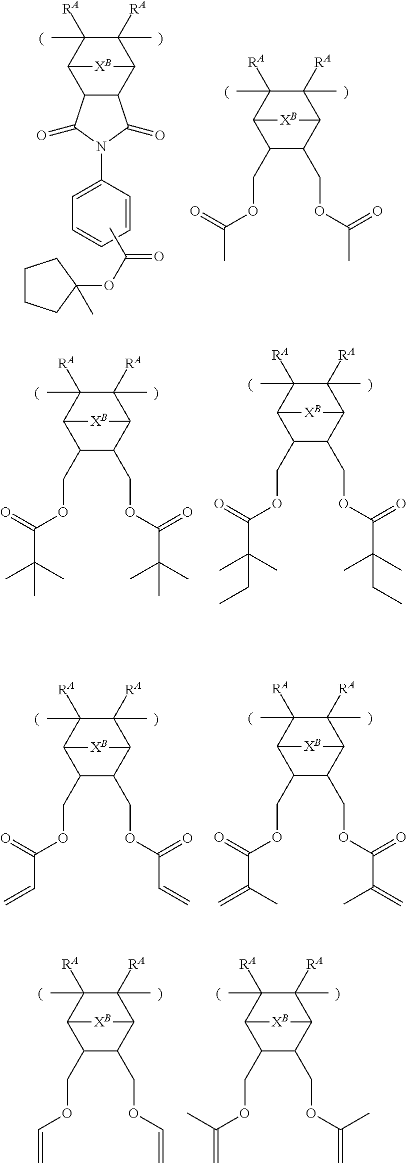

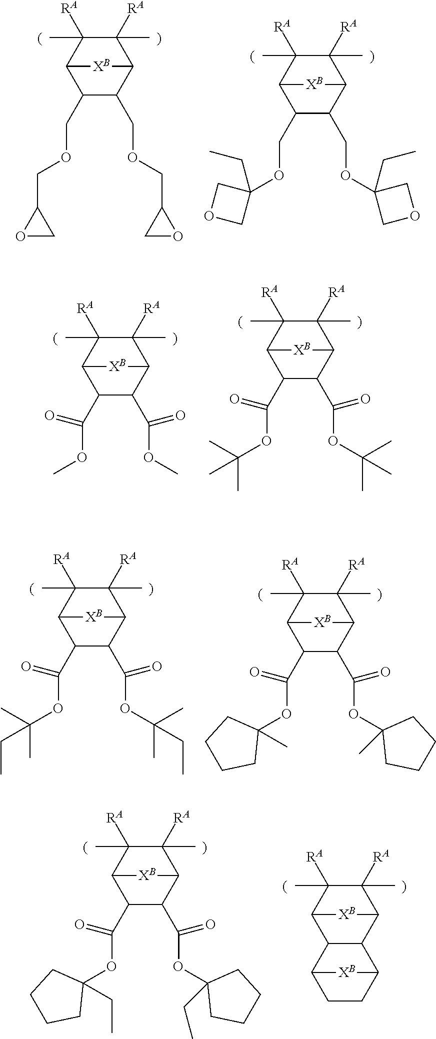

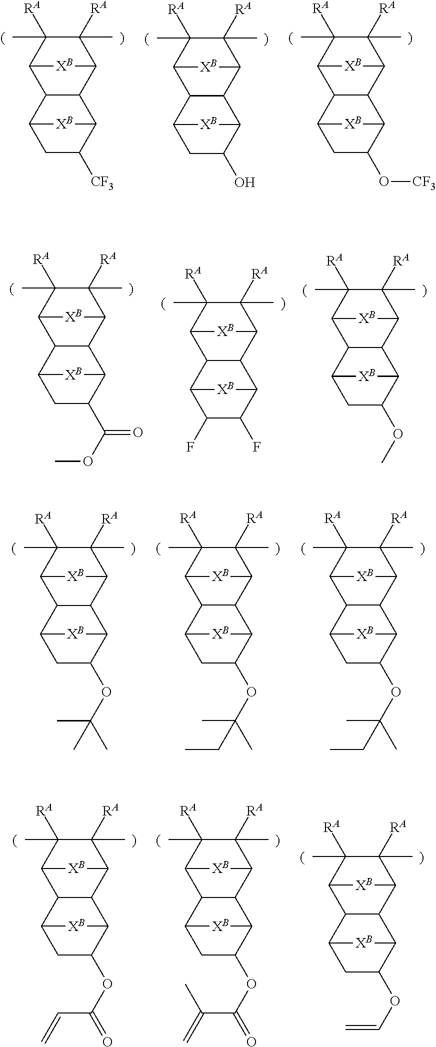

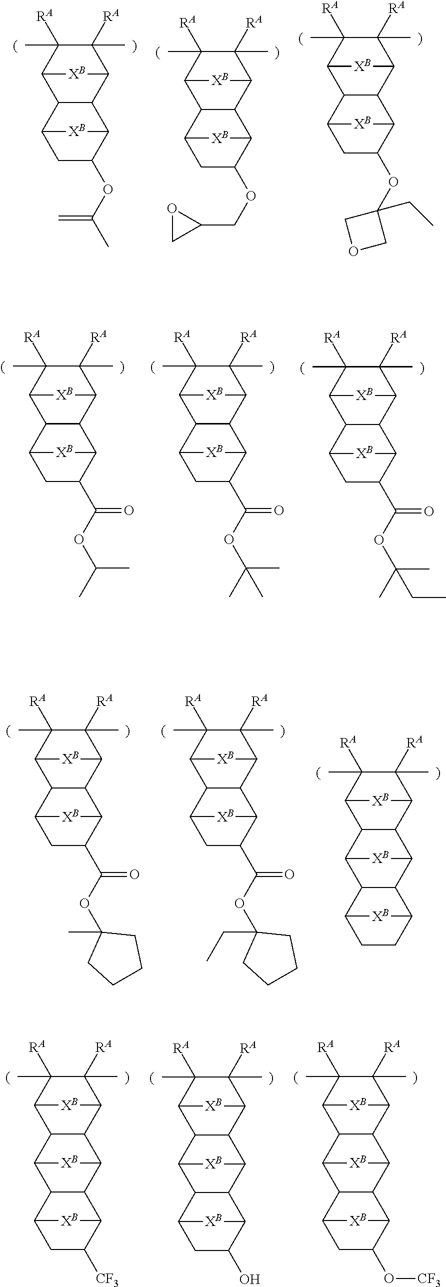

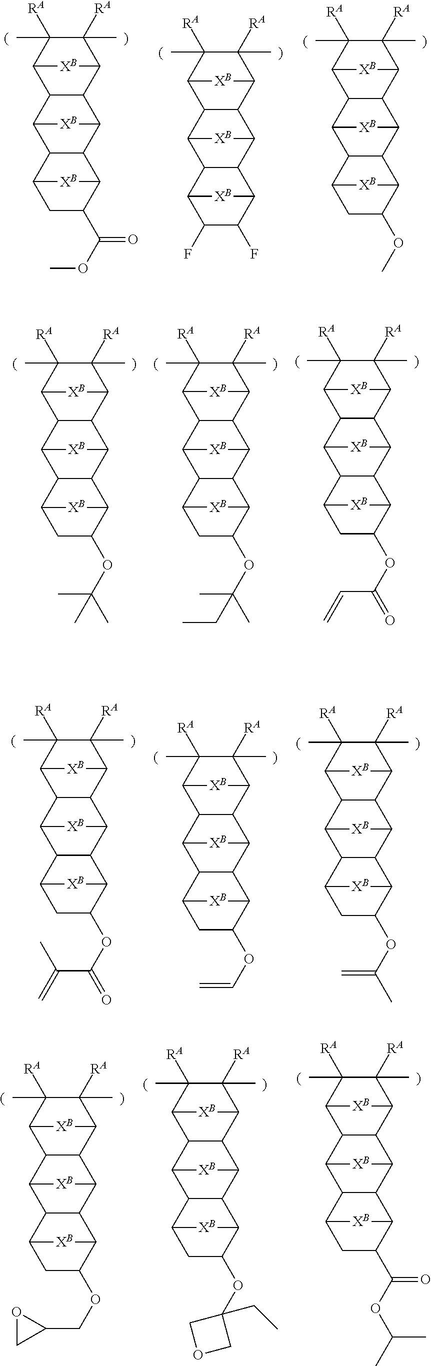

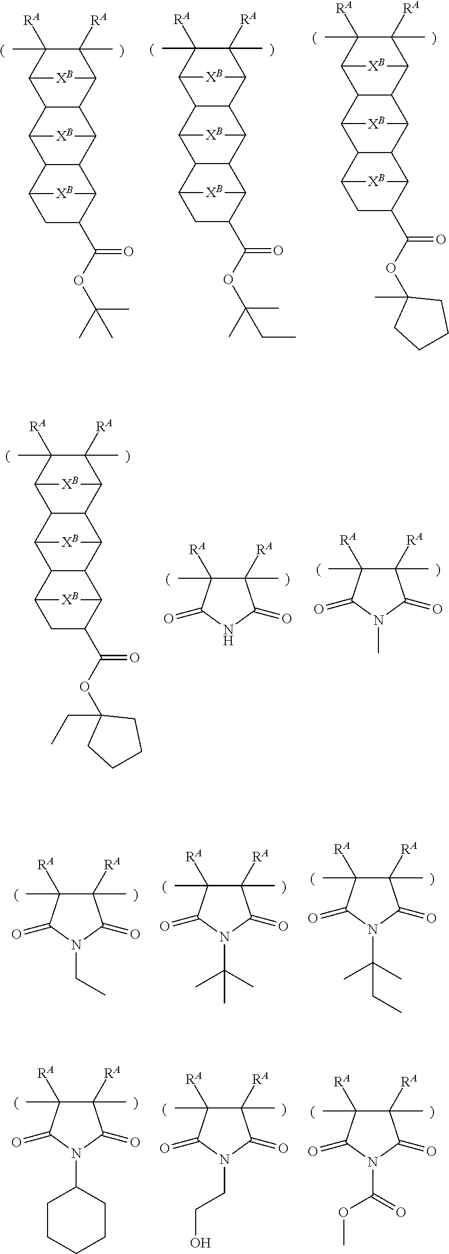

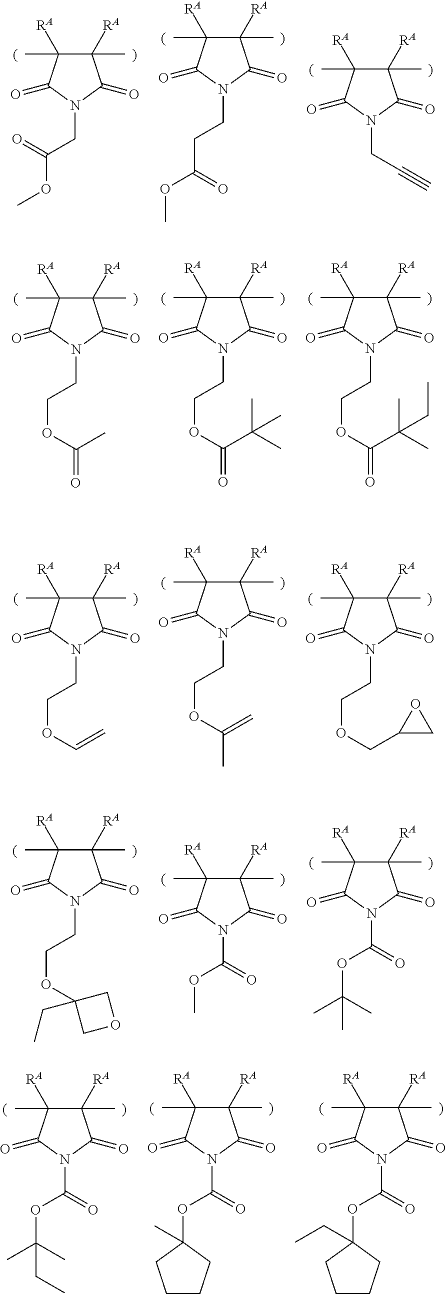

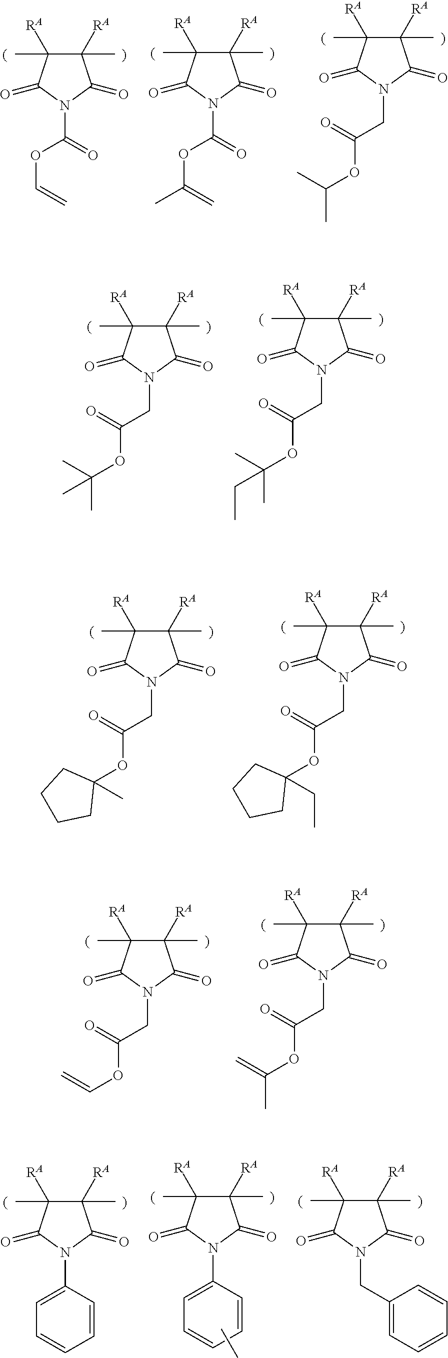

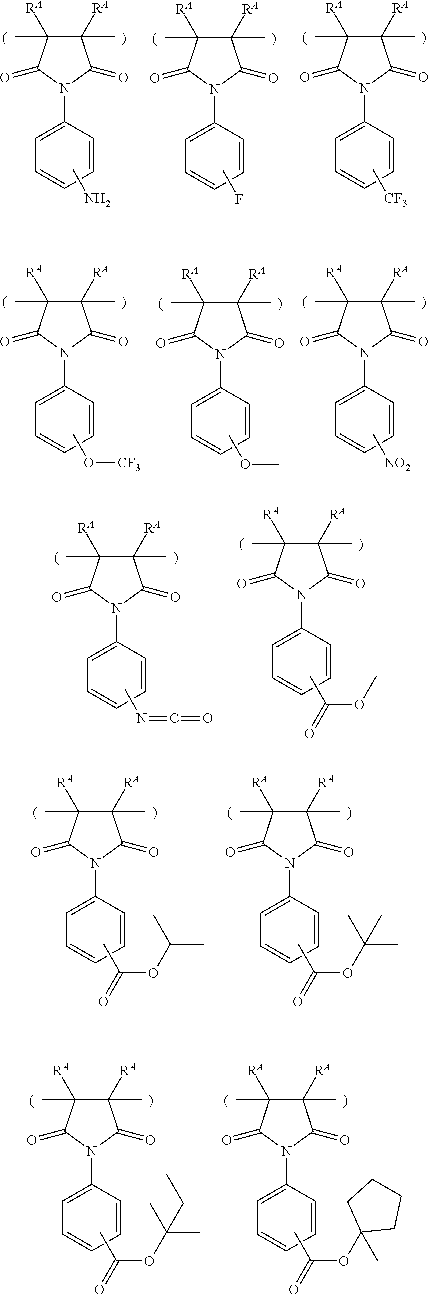

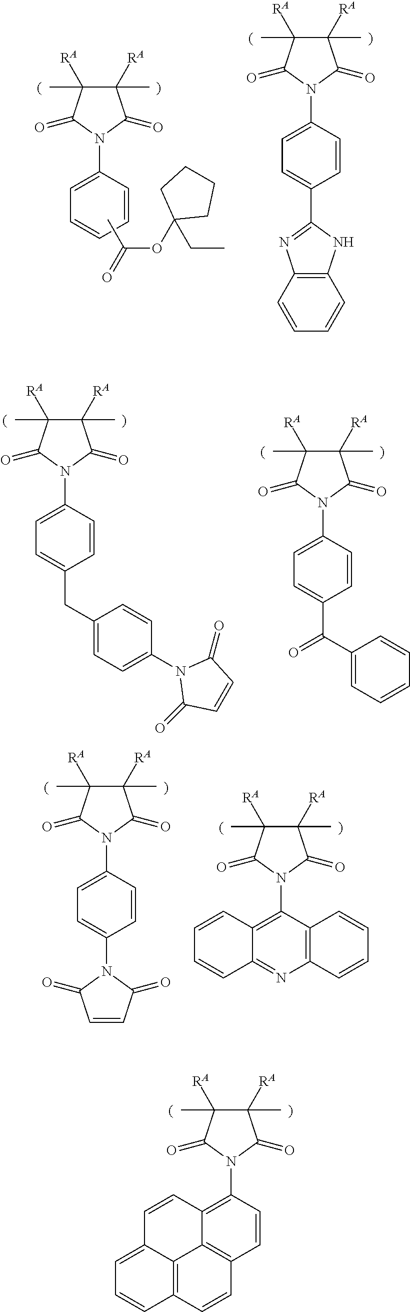

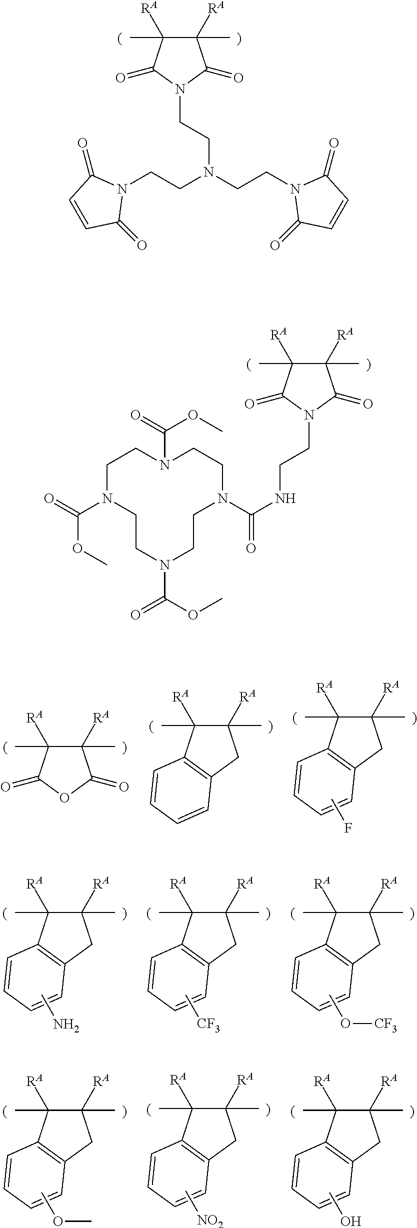

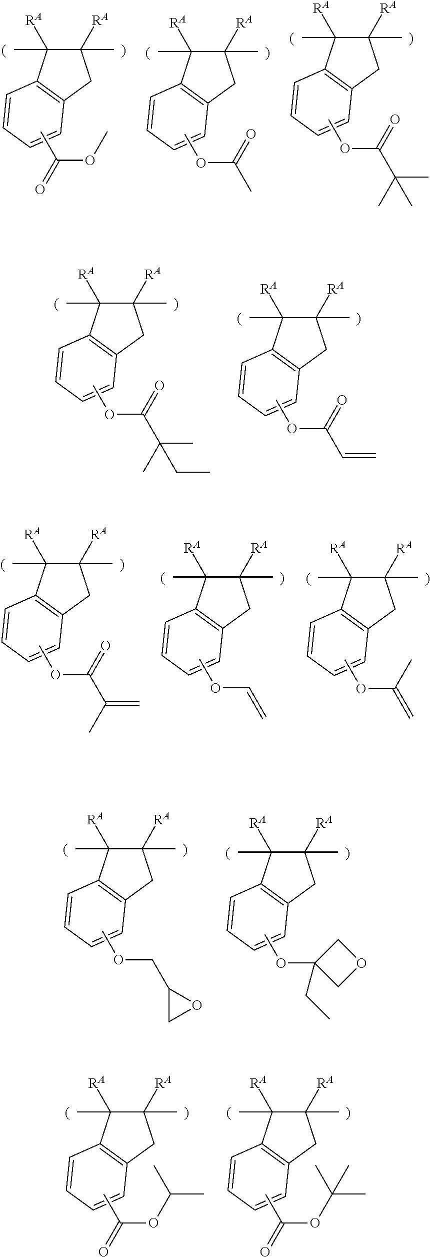

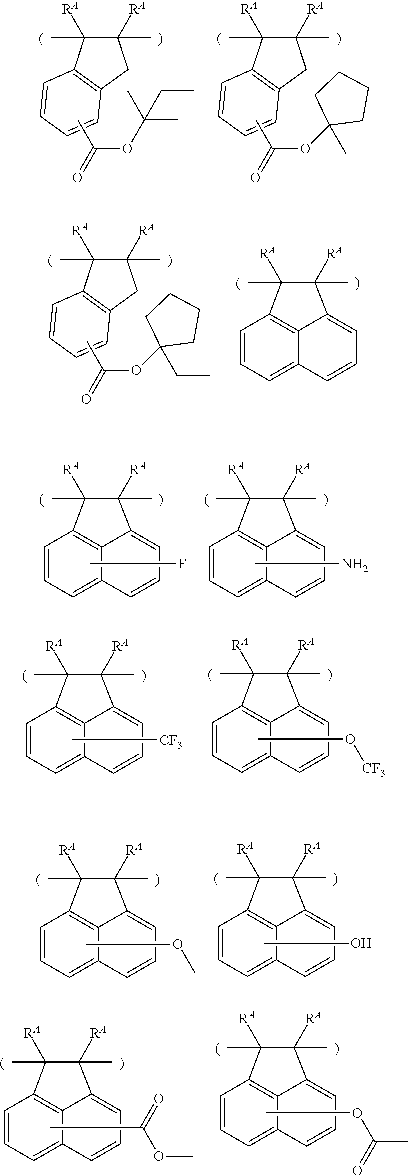

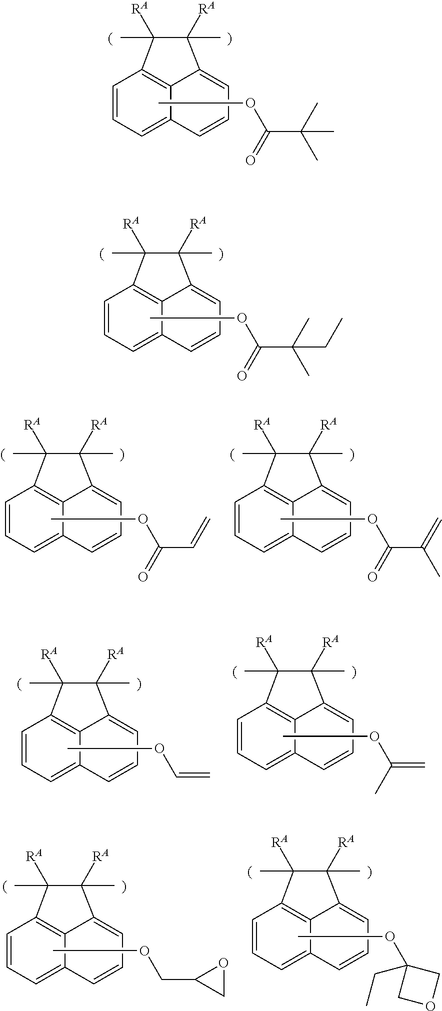

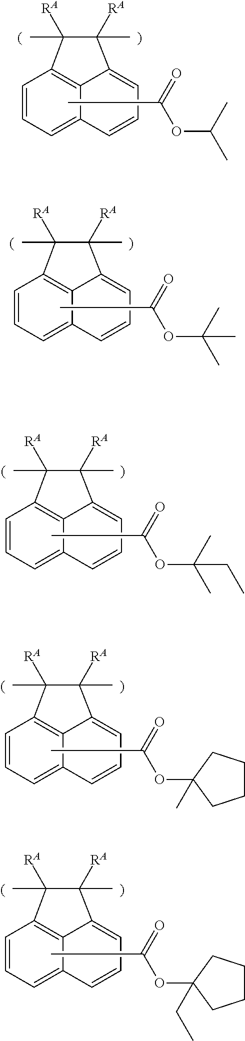

In the resist composition, the content ratio of the hypervalent iodine compound to the carboxy group-containing compound (when the carboxy group-containing compound is a carboxy group-containing polymer, the content ratio of the hypervalent iodine compound to the carboxylic acid-containing repeat unit in the polymer) is, in terms of molar ratio, preferably hypervalent iodine compound:carboxy group-containing compound=10:90 to 90:10, more preferably 20:80 to 80:20, and still more preferably 30:70 to 70:30. The hypervalent iodine compound may be used alone or in admixture of two or more having different composition ratios and different values of Mw and/or Mw/Mn. The carboxy group-containing polymer may be used alone or in admixture of two or more having different composition ratios and different values of Mw and/or Mw/Mn.

In the carboxy group-containing polymer, the carboxy group-containing repeat unit and another repeat unit are preferably present in a content ratio (molar ratio) of carboxy group-containing repeat unit:another repeat unit=10:90 to 90:10, more preferably 15:85 to 85:15, and still more preferably 20:80 to 80:20.

The carboxy group-containing polymer preferably has a weight average molecular weight (Mw) of 1000 to 500000, and more preferably 3000 to 100000. In the invention, Mw represents a value measured by gel permeation chromatography (GPC) versus polystyrene standards using tetrahydrofuran (THF) as a solvent.

If the carboxy group-containing polymer has a wide molecular weight distribution or dispersity (Mw/Mn), which indicates the presence of lower and higher molecular weight polymer fractions, there is a possibility that foreign matter is left on the pattern or the pattern profile is degraded after exposure. The influences of Mw and Mw/Mn become stronger as the pattern rule becomes finer. Therefore, the carboxy group-containing polymer should preferably have a narrow dispersity (Mw/Mn) of 1.0 to 2.0 in order to provide a resist composition suitable for micropatterning to a small feature size.

Examples of the method of synthesizing the carboxy group-containing polymer include a method in which monomers corresponding to the foregoing repeat units are dissolved in an organic solvent, a radical polymerization initiator is added thereto, and the resulting mixture is heated for polymerization.

Examples of the organic solvent used in the polymerization reaction include toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of such a polymerization initiator added is preferably 0.01 to 25 mol % per total amount of monomers to be polymerized. The reaction temperature is preferably 50 to 150° C., and more preferably 60 to 100° C. The reaction time is preferably 2 to 24 hours, and more preferably 2 to 12 hours from the viewpoint of production efficiency.

The polymerization initiator may be added to the monomer solution before supply to a reaction vessel, or an initiator solution may be prepared separately from the monomer solution and each solution may be supplied to a reaction vessel independently. Radicals generated from the initiator during waiting time may promote a polymerization reaction to generate an ultrahigh polymer. Therefore, from the viewpoint of quality control, each of the monomer solution and the initiator solution is preferably prepared and added dropwise independently. Further, a known chain transfer agent such as dodecyl mercaptan or 2-mercaptoethanol may be used in combination for adjusting the molecular weight. In this case, the amount of such a chain transfer agent added is preferably 0.01 to 20 mol % per total amount of monomers to be polymerized.

The amount of each monomer in the monomer solution is to be appropriately set, for example, so as to achieve the foregoing preferred content ratio of the repeat unit.

### [Solvent]

The resist composition contains a solvent. The solvent is not particularly limited as long as the hypervalent iodine compound, the carboxy group-containing compound, and other components described below are dissolvable therein and a film can be formed from the resulting solution. The solvent is preferably an organic solvent, and examples of the organic solvent include ketones such as cyclohexanone, methyl-2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids such as formic acid, acetic acid, and propionic acid, lactones such as γ-butyrolactone, and mixtures thereof.

In the resist composition, the solvent is preferably present in such an amount that the resist composition may have a solids concentration of 0.1 to 20% by weight, more preferably 0.1 to 15% by weight, even more preferably 0.1 to 10% by weight. As used herein, the term solids is a general term for all components in the resist composition excluding the solvent. The solvent may be used alone or in admixture of two or more.

### [Other Components]

The resist composition may further contain a surfactant. The surfactant is preferably a fluorine-based and/or silicone-based surfactant. Exemplary surfactants are described, for example, in US 2008/0248425, paragraph [0276]. Also useful are surfactants other than the fluorine-based and/or silicone-based surfactants, as described, for example, in US 2008/0248425, paragraph [0280].

When contained in the resist composition, the surfactant is preferably present in an amount of 0.0001 to 2% by weight based on the overall solids. The surfactant may be used alone or in admixture of two or more.

The resist composition may further contain a radical scavenger. When added, the radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpyperidine and 2,2,6,6-tetramethylpyperidine-N-oxy radical. Exemplary thiol compounds include dodecanethiol and hexadecanethiol.

When contained in the resist composition, the radical scavenger is preferably present in an amount of 0.01 to 10% by weight based on the overall solids. The radical scavenger may be used alone or in admixture of two or more.

The resist composition may further contain a crosslinking agent. When added, the crosslinking agent promotes the crosslinking reaction during photolithography to improve the glass transition point of the pattern, thereby obtaining a pattern with excellent fine line resolution.

Suitable crosslinking agents include compounds having a carbon-carbon unsaturated bond as a functional group, such as vinyl, (meth) acrylate, allyl, alkynyl, and aromatic ring. Exemplary compounds having a vinyl group include straight, branched, and cyclic alkenes, each of which may have a substituent. Exemplary compounds having a (meth) acrylate group include acrylic acid, methacrylic acid, an acrylic acid ester, and a methacrylic acid ester, each of which may have a substituent. Exemplary compounds having an allyl group include an allyl alcohol, an allyl ether, an allyl ester, an allyl amide, an allylamine, and an allyl group-containing isocyanurate, each of which may have a substituent. Exemplary compounds having an alkynyl group include straight, branched, and cyclic alkynes, an alkynyl alcohol, an alkynyl ether, an alkynyl ester, an alkynyl amide, an alkynyl amine, and an alkynyl group-containing isocyanurate, each of which may have a substituent. Exemplary compounds having an aromatic ring include arenes, heteroarenes, styrene, stilbene, phenylacetylene, acenaphthylene, and chalcone, each of which may have a substituent. The crosslinking agent may have only one of the functional groups described above, or may have a plurality of the functional groups. The number of the functional groups contained in the crosslinking agent is preferably 1 or more and 10 or less, and more preferably 2 or more and 8 or less.

When contained in the resist composition, the crosslinking agent is preferably present in an amount of 0.01 to 50% by weight based on the overall solids. The crosslinking agent may be used alone or in admixture of two or more.

When the resist composition contains the crosslinking agent, the resist composition may further contain a photopolymerization initiator. The photopolymerization initiator can generate radicals by irradiation with high-energy radiation to promote crosslinking of the crosslinking agent.

Exemplary photopolymerization initiators include benzophenone derivatives such as benzophenone, methyl O-benzoylbenzoate, 4-benzoyl-4′-methyl diphenyl ketone, dibenzyl ketone, and fluorenone; acetophenone derivatives such as 2,2′-diethoxyacetophenone, 2-hydroxy-2-methylpropiophenone, 2,2-dimethoxy-1,2-diphenylethane-1-one, 1-hydroxycyclohexyl phenyl ketone, 2-methyl-1-[4-(methylthio)phenyl]-2-morpholinopropane-1-one, 2-hydroxy-1-{4-[4-(2-hydroxy-2-methylpropionyl)-benzyl]-phenyl}-2-methylpropane-1-one, and methyl phenylglyoxylate; thioxanthone derivatives such as thioxanthone, 2-methylthioxanthone, 2-isopropylthioxanthone, 4-isopropylthioxanthone, 2-chlorothioxanthone, and diethylthioxanthone; benzyl derivatives such as benzyl, benzyl dimethyl ketal, and benzyl-β-methoxyethyl acetal; benzoin derivatives such as benzoin, benzoin methyl ether, and 2-hydroxy-2-methyl-1-phenylpropane-1-one; oxime-based compounds such as 1-phenyl-1,2-butanedione-2-(O-methoxycarbonyl) oxime, 1-phenyl-1,2-propanedione-2-(O-methoxycarbonyl) oxime, 1-phenyl-1,2-propanedione-2-(O-ethoxycarbonyl) oxime, 1-phenyl-1,2-propanedione-2-(O-benzoyl) oxime, 1,3-diphenylpropanetrione-2-(O-ethoxycarbonyl) oxime, 1-phenyl-3-ethoxypropanetrione-2-(O-benzoyl) oxime 1,2-octanedione, 1-[4-(phenylthio)-2-(O-benzoyloxime)]ethanone, 1-[9-ethyl-6-(2-methylbenzoyl)-9H-carbazole-3-yl]-1-(O-acetyloxime); α-hydroxyketone compounds such as 2-hydroxy-2-methyl-1-phenylpropane-1-one, 1-[4-(2-hydroxyethoxy)phenyl]-2-hydroxy-2-methyl-1-propane-1-one, and 2-hydroxy-1-{4-[4-(2-hydroxy-2-methylpropionyl)-benzyl]phenyl}-2-methylpropane; α-aminoalkylphenone-based compounds such as 2-benzyl-2-dimethylamino-1-(4-morpholinophenyl)-butanone-1,2-dimethylamino-2-(4-meth ylbenzyl)-1-(4-morpholine-4-yl-phenyl) butane-1-one; phosphine oxide-based compounds such as bis(2,4,6-trimethylbenzoyl)-phenylphosphine oxide, bis(2,6-dimethoxybenzoyl)-2,4,4-trimethyl-pentylphosphine oxide, and 2,4,6-trimethylbenzoyldiphenylphosphine oxide; and titanocene compounds such as bis(η5-2,4-cyclopentadiene-1-yl)-bis(2,6-difluoro-3-(1H-pyrrole-1-yl)phenyl) titanium.

When contained in the resist composition, the photopolymerization initiator is preferably present in an amount of 0.1 to 10% by weight, more preferably 0.1 to 5% by weight, and most preferably 0.1 to 1% by weight, based on the overall solids. When the content is 0.1% by weight or more, the blending effect can be sufficiently obtained.

The resist composition contains the hypervalent iodine compound and the carboxy group-containing compound as main components as described above, but not a polymer containing an acid labile group and a photoacid generator as used in conventional chemically amplified resist compositions. Nevertheless, the resist composition, especially when exposed to EB or EUV, can form a positive pattern, where the exposed region is removed by dry process development, or a negative pattern, where the unexposed region is removed by dry process development. Although its mechanism is not well understood, the following mechanism is presumed.

The hypervalent iodine compound having the formula (1), (2), or (3) is a three-coordinate compound having an aryl group and carboxylate ligands. When such a three-coordinate iodine compound is mixed with a carboxy group-containing compound, replacement of carboxylate ligands takes place as equilibration reaction. If the original carboxylate ligands are removed by any suitable means, a hypervalent iodine compound having new ligands is created. For example, if 1-iodonaphthylene diacetate as a hypervalent iodine compound is mixed with a carboxy group-containing compound, and the resulting low-boiling point acetic acid is removed, then ligand exchange is completed. Here, the carboxy group-containing compound is crosslinked with the hypervalent iodine compound to form a polymer.

The hypervalent iodine compound having a higher molecular weight is generated during film formation. This is because even if synthesized in advance, such a hypervalent iodine compound having a higher molecular weight is insoluble in most organic solvents, so that it is impossible to prepare their solution. This is presumed to be because the hypervalent iodine compound, which is originally low in solvent solubility due to the large polarization, further deteriorates in solubility by using a carboxy group-containing compound that is a high molecular weight compound as a ligand. Therefore, it is desirable that the original low-molecular-weight carboxylic acid is removed during film formation and a subsequent bake step to complete a ligand exchange reaction and form a resist film in the step.

The resist composition can be positive tone or negative tone depending on the selection of the components. The positive resist composition contains a polymer to which the hypervalent iodine compound is bonded during film formation. However, the polymer is decomposed by light to form a monovalent iodine compound. At the same time, the bond between the carboxy group-containing compound and the hypervalent iodine compound is released, and the molecular weight also decreases. As a result, it is presumed that there is a difference in etching rate between the exposed region and the unexposed region, and formed is a positive pattern, where the unexposed film remains after dry process development.

On the other hand, the negative resist composition contains a polymer crosslinked with the hypervalent iodine compound and generated during film formation. The polymer is decomposed by light, undergoes crosslinking or bond replacement, and is converted into chemical species having a lower etching rate than in the unexposed region. As a result, it is presumed that there is a difference in etching rate between the exposed region and the unexposed region, and formed is a negative pattern, where the exposed film remains after dry process development.

The details on how to select components to obtain positive tone or negative tone is not clear. However, this is determined as follows. When a positive resist film is obtained from the resist composition, the exposed region is soluble in an organic solvent. For the negative resist film, the exposed region is insoluble in an aqueous alkali solution.

The hypervalent iodine compound having the formula (1), (2), or (3) has a rigid skeleton with such a large molecular weight that the compound hardly volatilizes even under vacuum conditions during EB or EUV exposure. When the hypervalent iodine compound with a small molecular weight is used, the compound decomposed during exposure volatilizes, the resist film largely shrinks by exposure, and the exposure machine is polluted with volatilized components and the resist pattern shrinks to cause a dimensional change. Therefore, the above-described problem is solved by the hypervalent iodine compound used in the present invention. In addition, by using the hypervalent iodine compound with a large molecular weight and a rigid skeleton, the glass transition point of the pattern is improved, the pattern is prevented from being twisted, the resolution is improved, and the etching resistance is also improved.

The hypervalent iodine compound having the formula (1), (2), or (3) has a plurality of hypervalent iodine bonds in one molecule. With such a skeleton, the positive and negative patterns both have an increased crosslinking density to make it possible to prevent pattern twisting and form a pattern having high etching resistance and excellent resolution.

From the foregoing presumption, the inventive resist composition is regarded as falling in the concept of non-chemically amplified resist composition. The inventive resist composition does not need a polymer containing an acid labile group or a photoacid generator as used in conventional chemically amplified resist compositions. Therefore, a small size pattern can be resolved without adverse effects from acid diffusion (for example, image blur).

The resist composition is quite effective in the EUV lithography. This is because an iodine atom having a high absorptivity to EUV radiation is included. That is, shot noise is reduced, and higher resolution and lower LWR are achievable.

As the EUV lithography resist composition capable of forming a small size pattern, a metal resist composition based on a metal (specifically tin) compound having a high absorptivity to EUV radiation like iodine atom is known, for example, from Patent Document 2. However, the metal resist composition suffers from many problems including a lack of solvent solubility, poor shelf stability, and defects in the form of post-etching residues due to the containment of metal elements, as discussed previously. In contrast, since the resist composition does not use metal elements, it is advantageous in defectiveness over the metal resist and eliminates the problem of solvent solubility. Furthermore, the resist composition, applicable to both positive tone and negative tone, has a wide range of use. For example, in a contact hole forming step, a metal resist that is subjected to negative development requires a reversal processing step after a pillar pattern is formed. However, a positive resist does not need such a step. Therefore, also from the viewpoint of process simplicity, the resist composition is regarded more useful than a metal resist.

JP-A 2015-180928 and JP-A 2018-95853 describe a resist composition comprising a hypervalent iodine compound as an additive and a resist composition comprising a base polymer having a hypervalent iodine compound incorporated in its framework. It is described in these patent documents that these resist compositions are successful only in improving line edge roughness. They refer nowhere to a possibility of photo-decomposition of the hypervalent iodine compound and an ability to function as a material of a non-chemically amplified resist. The hypervalent iodine compound is not a main component, according to the description and specific examples of the content thereof. It is then believed that a material capable of reducing shot noise during the EUV lithography and forming a small size pattern as the non-chemically amplified resist is not conceivable from these patent documents. That is, the present invention provides a definitely novel resist composition and pattern forming process.

### [Resist Pattern Forming Process]

The inventive resist pattern forming process includes the following steps (i) to (iv):
(i) applying the above-described resist composition onto a substrate or onto an underlayer film laminated on a substrate to form a resist film;
(ii) exposing the resist film to high-energy radiation;
(iii) heating the exposed resist film; and
(iv) after the baking, developing the heated resist film by dry etching to form a resist pattern.
   <Step (i)>

The step (i) is a step of applying the above-described resist composition onto a substrate or onto an underlayer film laminated on a substrate to form a resist film. Specifically, the resist composition is applied onto a substrate for integrated circuit fabrication (e.g., Si, SiO₂, SiN, SiON, TiN, WSi, BPSG, SOG, or organic antireflective coating) or onto an underlayer film laminated on the substrate, or onto a substrate for mask circuit fabrication (e.g., Cr, CrO, CrON, MoSi₂, or SiO₂) or onto an underlayer film laminated on the substrate, by any suitable technique such as spin coating, roll coating, flow coating, dip coating, spray coating or doctor coating. The coating is prebaked on a hot plate at a temperature of preferably 60 to 150° C. for 10 seconds to 30 minutes, more preferably at 80 to 120° C. for 30 seconds to 20 minutes to form a resist film having a thickness of 0.01 to 2 μm. The underlayer film means a film formed between the substrate and the resist film in the multilayer resist process. The underlayer film is not particularly limited, and a conventionally known film can be used.

<Step (ii)>

The step (ii) is a step of exposing the resist film to high-energy radiation. Examples of the high-energy radiation include UV, deep UV, EB having an acceleration voltage of 1 to 150 kV, EUV having a wavelength of 3 to 15 nm, X-ray, soft X-ray, excimer laser radiation, g-ray, and synchrotron radiation. On use of UV, deep UV, EUV, X-ray, soft X-ray, excimer laser radiation, g-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 5000 μC/cm², more preferably about 0.5 to 3000 μC/cm². The inventive resist composition is best suited in micropatterning using EB or EUV as the high-energy radiation.

<Step (iii)>

The step (iii) is a step of heating (PEB) the exposed resist film. PEB can be performed not only with a hot plate, but also by infrared irradiation, laser irradiation, hot air blowing, or a method of inserting a wafer into a baking temperature atmosphere. Currently, most of the heating methods use a hot plate. When the substrate on which the resist film is formed is placed on a hot plate, the resist film is heated by heat transfer from the substrate. The temperature at which the resist film is heated is adjusted by controlling the temperature of the hot plate.

The PEB temperature is preferably 30 to 170° C., more preferably 40 to 160° C., and still more preferably 50 to 150° C. The PEB time is preferably 10 seconds to 30 minutes, and more preferably 10 seconds to 20 minutes.

After PEB, a step of exposing the entire surface of the resist film may be included. By exposing the entire surface, crosslinking proceeds in the resist film, and a film having higher etching resistance is obtained. The high-energy radiation described above can be used for the entire surface exposure, and in particular, it is preferable to use UV, deep UV, X-ray, soft X-ray, or the like.

<Step (iv)>

The step (iv) is a step of developing the resist film subjected to PEB by dry etching to form a resist pattern. When a positive resist composition is used, the exposed region is removed to open a space region. When a negative resist composition is used, the unexposed region is removed to open a space region.

Dry etching can be performed by reactive ion etching (RIE) or the like, using a general dry etching apparatus and using a plasma containing a dry etching gas in the chamber. As the dry etching gas, a mixed gas obtained by diluting a gas such as oxygen, hydrogen, ammonia, fluorocarbon, chlorine, or bromine with nitrogen, argon, helium, carbon dioxide, carbon monoxide, sulfur dioxide, or the like can be used. As the gas, a gas containing at least one selected from the group consisting of oxygen and tetrafluoromethane is preferably used. In particular, from the viewpoint of ease of controlling the etching rate, it is preferable to use a mixed gas of oxygen and nitrogen or a mixed gas of tetrafluoromethane and nitrogen.

As dry etching conditions, for example, when a mixed gas of oxygen and nitrogen is used, the pressure in the chamber is preferably 0.01 to 100 Pa, and more preferably 0.1 to 30 Pa. The radio frequency (RF) power is preferably 50 to 1500 W, and more preferably 150 to 1000 W. The bias power is preferably 0 to 300 W, and more preferably 30 to 200 W. The flow rate of oxygen gas is preferably 3 to 300 sccm, and more preferably 5 to 150 sccm. The flow rate of nitrogen gas is preferably 5 to 600 sccm, and more preferably 10 to 500 sccm. The treatment temperature during development is preferably −20 to 30° C., and more preferably −10 to 30° C.

When a mixed gas of tetrafluoromethane and nitrogen is used, the pressure is preferably 0.01 to 100 Pa, and more preferably 0.1 to 30 Pa. The high frequency power is preferably 50 to 1500 W, and more preferably 150 to 1000 W. The bias power is preferably 0 to 300 W, and more preferably 30 to 200 W. The flow rate of tetrafluoromethane gas is preferably 3 to 300 sccm, and more preferably 5 to 150 sccm. The flow rate of nitrogen gas is preferably 5 to 500 sccm, and more preferably 10 to 300 sccm. The treatment temperature during development is preferably-20 to 30° C., and more preferably-10 to 30° C.

The dry etching time can be appropriately set, but is preferably about 30 to 300 seconds, and more preferably about 30 to 120 seconds.

The hole pattern and the trench pattern after development can also be shrunk by thermal flow, RELACS technology, or DSA technology.

### EXAMPLES

Synthesis Examples, Examples and Comparative Examples are given below for illustrating the invention although the invention is not limited thereto.

### [1] Synthesis of Carboxy Group-Containing Polymer

The monomers used for the synthesis of the carboxy group-containing polymer are as follows.

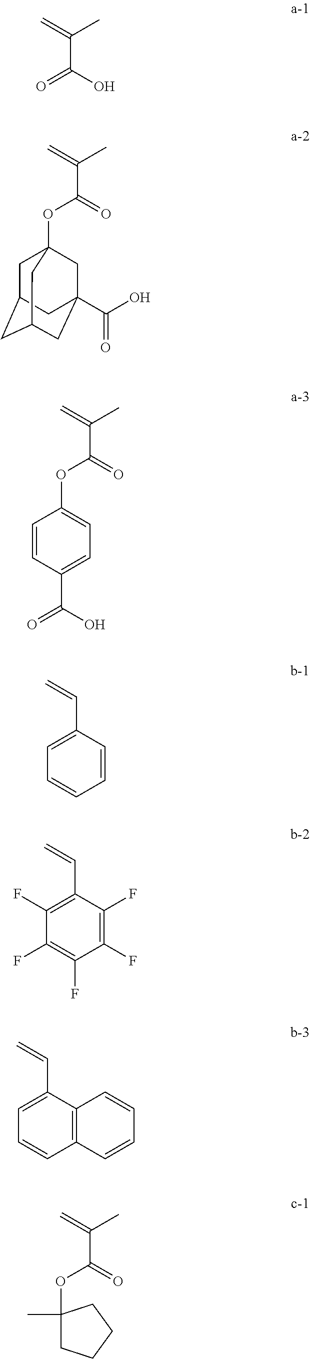

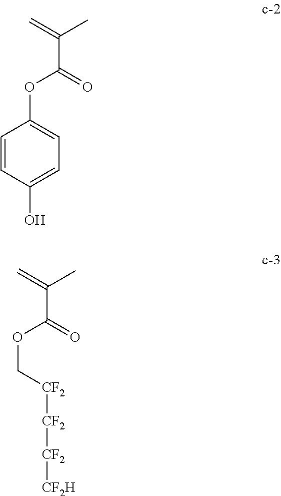 [SMILES: C=C(C)C(=O)Oc1ccc(O)cc1 ; C=C(C)C(=O)OCC(F)(F)C(F)(F)C(F)(F)C(F)F]

### [1] Synthesis of Polymer

### [Synthesis Example 1] Synthesis of Polymer P-1

In a nitrogen atmosphere, a monomer a-1 (56 g), a monomer b-1 (36 g), V-601 (manufactured by FUJIFILM Wako Pure Chemical Corporation) (5.4 g), and MEK (180 g) were put into a flask to prepare a monomer-polymerization initiator solution. In another flask under a nitrogen atmosphere, 55 g of MEK was put and heated to 80° C. while stirred, and then the monomer-polymerization initiator solution was added dropwise over 4 hours. After completion of the dropwise addition, stir of the polymerization liquid was continued for 2 hours while the liquid temperature was maintained at 80° C., and then the polymerization liquid was cooled to room temperature. The obtained polymerization liquid was added dropwise to 4000 g of vigorously stirred hexane, and the precipitated polymer was separated by filtration. The obtained polymer was washed twice with hexane (1200 g), and then vacuum-dried at 50° C. for 20 hours to obtain a polymer P-1 in the form of a white powder (yield: 90 g, yield rate: 98%). The polymer P-1 had a value of Mw of 8000, and a value of Mw/Mn of 1.42. The value of Mw was measured by GPC versus polystyrene standards using THE as a solvent.

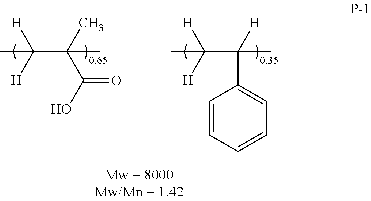

### [Synthesis Examples 2 to 13] Synthesis of Polymer P-2 to P-13

Polymers shown in Table 1 were synthesized in the same manner as in Synthesis Example 1 except that the kind and the compounding ratio of each monomer were changed.

TABLE 1

| | | Incorpo- | | Incorpo- | | |
|---|---|---|---|---|---|---|
| | | ration | | ration | | |
| | | ratio | | ratio | | |
| Polymer | Unit 1 | (mol %) | Unit 2 | (mol %) | Mw | Mw/Mn |
| P-1 | a-1 | 65 | b-1 | 35 | 8,000 | 1.42 |
| P-2 | a-1 | 50 | b-2 | 50 | 8,400 | 1.51 |
| P-3 | a-1 | 60 | b-3 | 40 | 8,100 | 1.42 |
| P-4 | a-1 | 60 | c-3 | 40 | 8,100 | 1.42 |
| P-5 | a-2 | 65 | b-1 | 35 | 8,000 | 1.44 |
| P-6 | a-2 | 50 | b-2 | 50 | 8,600 | 1.41 |
| P-7 | a-2 | 60 | b-3 | 40 | 7,900 | 1.49 |
| P-8 | a-2 | 65 | c-3 | 35 | 9,800 | 1.45 |
| P-9 | a-3 | 65 | b-1 | 35 | 9,400 | 1.40 |
| P-10 | a-3 | 50 | b-2 | 50 | 9,000 | 1.45 |
| P-11 | a-3 | 60 | b-3 | 40 | 7,500 | 1.46 |
| P-12 | a-3 | 65 | c-3 | 35 | 7,000 | 1.48 |
| P-13 | c-1 | 60 | c-2 | 40 | 8,500 | 1.45 |

### [2] Preparation of Resist Composition

### Examples 1-1 to 1-22 and Comparative Examples 1-1 to 1-4

Resist compositions (R-01 to R-22, and CR-01 to CR-02) were prepared by dissolving a hypervalent iodine compound and a carboxy group-containing compound in a solvent containing 0.01% by weight of a surfactant (PF-636, manufactured by OMNOVA Solutions Inc.) in accordance with the recipe shown in Table 2, and filtering the solution through a Teflon® filter having a pore size of 0.2 μm. Separately, resist compositions (CR-03 to CR-04) were prepared by dissolving a polymer, a photoacid generator, and a sensitivity modifier in a solvent containing 0.01% by weight of a surfactant (PF-636, manufactured by OMNOVA Solutions Inc.) in accordance with the recipe shown in Table 3, and filtering the solution through a Teflon® filter having a pore size of 0.2 μm.

TABLE 2

| | | | Hypervalent | Hypervalent | Carboxy- | | |
|---|---|---|---|---|---|---|---|
| | | | iodine | iodine | containing | | |
| | | Resist | compound 1 | compound 2 | compound | Solvent 1 | Solvent 2 |
| | | composition | (pbw) | (pbw) | (pbw) | (pbw) | (pbw) |
| Example | 1-1 | R-01 | I-1 (12) | — | P-1 (9) | PGMEA (800) | AcOH (200) |
| | 1-2 | R-02 | I-2 (10) | — | P-1 (9) | PGMEA (800) | AcOH (200) |
| | 1-3 | R-03 | I-3 (10) | — | P-1 (9) | PGMEA (800) | AcOH (200) |
| | 1-4 | R-04 | I-4 (13) | — | P-1 (9) | PGMEA (800) | AcOH (200) |
| | 1-5 | R-05 | I-1 (6) | I-2 (5) | P-1 (9) | PGMEA (800) | AcOH (200) |
| | 1-6 | R-06 | I-2 (10) | — | P-2 (17) | PGMEA (800) | AcOH (200) |
| | 1-7 | R-07 | I-2 (10) | — | P-3 (11) | PGMEA (800) | AcOH (200) |
| | 1-8 | R-08 | I-2 (10) | — | P-4 (17) | PGMEA (800) | AcOH (200) |
| | 1-9 | R-09 | I-2 (10) | — | P-5 (19) | PGMEA (800) | AcOH (200) |
| | 1-10 | R-10 | I-2 (10) | — | P-6 (28) | PGMEA (800) | AcOH (200) |
| | 1-11 | R-11 | I-2 (10) | — | P-7 (22) | PGMEA (800) | AcOH (200) |
| | 1-12 | R-12 | I-2 (10) | — | P-8 (26) | PGMEA (800) | AcOH (200) |
| | 1-13 | R-13 | I-2 (10) | — | P-9 (12) | PGMEA (800) | AcOH (200) |
| | 1-14 | R-14 | I-2 (10) | — | P-10 (21) | PGMEA (800) | AcOH (200) |
| | 1-15 | R-15 | I-2 (10) | — | P-11 (15) | PGMEA (800) | AcOH (200) |
| | 1-16 | R-16 | I-2 (10) | — | P-12 (19) | PGMEA (800) | AcOH (200) |
| | 1-17 | R-17 | I-2 (10) | — | m-1 (7) | PGMEA (800) | AcOH (200) |
| | 1-18 | R-18 | I-2 (10) | — | m-2 (4) | PGMEA (800) | AcOH (200) |
| | 1-19 | R-19 | I-2 (10) | — | m-3 (7) | PGMEA (800) | AcOH (200) |
| | 1-20 | R-20 | I-2 (10) | — | m-4 (7) | PGMEA (800) | AcOH (200) |
| | 1-21 | R-21 | I-2 (10) | — | m-5 (10) | PGMEA (800) | AcOH (200) |
| | 1-22 | R-22 | I-2 (10) | — | m-6 (8) | PGMEA (800) | AcOH (200) |
| Comparative | 1-1 | RC-01 | I-5 (10) | — | P-1 (9) | PGMEA (800) | AcOH (200) |
| Example | 1-2 | RC-02 | I-5 (10) | — | P-9 (12) | PGMEA (800) | AcOH (200) |

TABLE 3

| | | | | | Sensitivity | | |
|---|---|---|---|---|---|---|---|
| | | Resist | Polymer | PAG | modifier | Solvent 1 | Solvent 2 |
| | | composition | (pbw) | (pbw) | (pbw) | (pbw) | (pbw) |
| Comparative | 1-3 | CR-03 | P-13 (80) | PAG-1 (19) | Q-1 (6) | PGMEA (1890) | GBL (210) |
| Example | 1-4 | CR-04 | P-13 (80) | PAG-1 (19) | I-5 (5) | PGMEA (1890) | GBL (210) |

In Tables 2 and 3, the hypervalent iodine compounds I-1 to I-5, the carboxy group-containing compounds m-1 to m-6, the photoacid generator PAG-1, the sensitivity modifier Q-1, and the solvent are identified below.

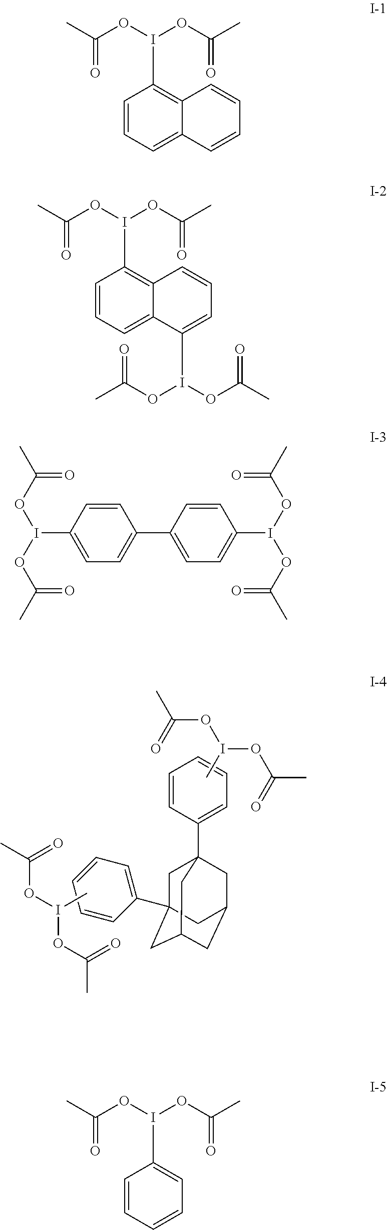

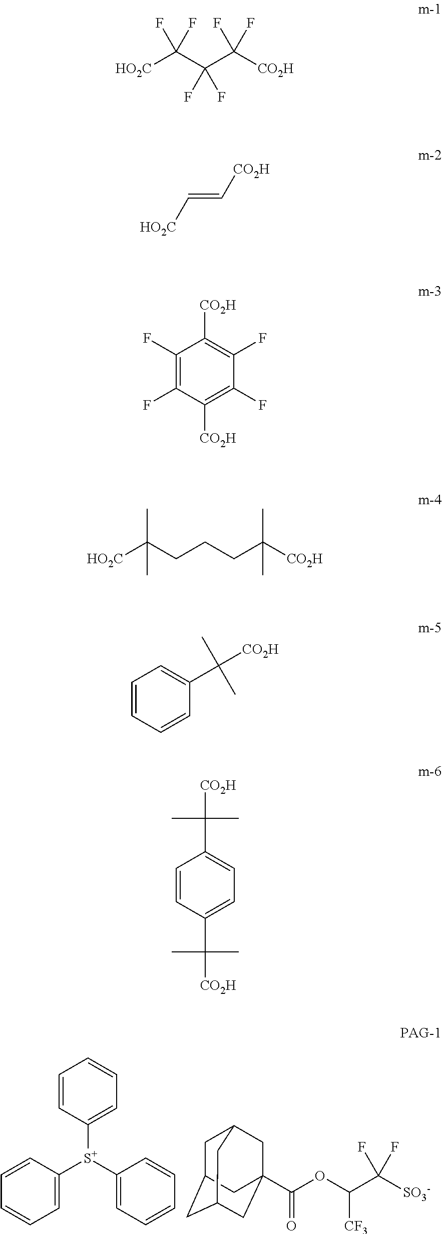

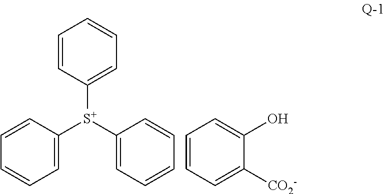

### Solvent:

PGMEA (propylene glycol monomethyl ether acetate)
AcOH (acetic acid)
GBL (γ-butyrolactone)

### [3] EUV Lithography Test

### Examples 2-1 to 2-22 and Comparative Examples 2-1 to 2-4

Each of the resist materials (R-01 to R-29, CR-01 to CR-02) was spin coated on a silicon substrate having a 60-nm antireflective coating DUV-42 (Nissan Chemical Corporation) and prebaked (PAB) on a hotplate at the temperature shown in Table 4 for 60 seconds to form a resist film of 70 nm thick. Using an EUV scanner NXE3400 (ASML, NA 0.33, G 0.9, 90° dipole illumination), the resist film was exposed to EUV through a mask bearing a 40-nm 1:1 line-and-space (LS) pattern. The resist film was baked (PEB) on a hotplate at the temperature shown in Table 4 for 60 seconds.

After PEB, dry etching was performed under the following conditions using a dry etching apparatus Telius manufactured by Tokyo Electron Ltd.
Chamber pressure: 12.0 Pa
RF power: 600 W
Bias power: 50 W
Stage temperature: 25° C.
O₂ gas flow: 20 sccm
N₂ gas flow: 400 sccm
Time: 30 sec

The resist film and the antireflective coating in the exposed region were reduced by dry etching, and dry etching was performed until the silicon substrate surface appeared.

Using a CD-SEM (CG-6300, Hitachi High-Tech Corporation), the exposure dose under which a 40 nm line-and-space of 1:1 was formed was defined as the sensitivity of the resist film. The wafer was cleaved, and the cross-sectional shape and the pattern height of the 40 nm line-and-space pattern were observed with an electron microscope (S-4800, Hitachi High-Tech Corporation). The results are also shown in Table 4.

TABLE 4

| | | | | | | Cross- | Pattern height |
|---|---|---|---|---|---|---|---|
| | | Resist | PAB/PEB | Sensitivity | Pattern | sectional | after etching |
| | | composition | (° C.) | (mJ/cm²) | type | shape | (nm) |
| Example | 2-1 | R-01 | 110/90 | 40 | positive | rectangular | 40 |
| | 2-2 | R-02 | 110/90 | 45 | positive | rectangular | 42 |
| | 2-3 | R-03 | 110/90 | 47 | positive | rectangular | 41 |
| | 2-4 | R-04 | 110/90 | 47 | positive | rectangular | 42 |
| | 2-5 | R-05 | 110/90 | 43 | positive | rectangular | 41 |
| | 2-6 | R-06 | 110/90 | 45 | positive | rectangular | 42 |
| | 2-7 | R-07 | 110/90 | 47 | positive | rectangular | 43 |
| | 2-8 | R-08 | 110/90 | 40 | positive | rectangular | 39 |
| | 2-9 | R-09 | 110/90 | 45 | negative | rectangular | 43 |
| | 2-10 | R-10 | 110/90 | 45 | negative | rectangular | 44 |
| | 2-11 | R-11 | 110/90 | 50 | negative | rectangular | 45 |
| | 2-12 | R-12 | 110/90 | 40 | negative | rectangular | 40 |
| | 2-13 | R-13 | 110/90 | 45 | negative | rectangular | 41 |
| | 2-14 | R-14 | 110/90 | 45 | negative | rectangular | 42 |
| | 2-15 | R-15 | 110/90 | 50 | negative | rectangular | 43 |
| | 2-16 | R-16 | 110/90 | 40 | negative | rectangular | 40 |
| | 2-17 | R-17 | 110/90 | 50 | negative | rectangular | 40 |
| | 2-18 | R-18 | 110/90 | 52 | negative | rectangular | 40 |
| | 2-19 | R-19 | 110/90 | 42 | negative | rectangular | 45 |
| | 2-20 | R-20 | 110/90 | 48 | positive | rectangular | 40 |
| | 2-21 | R-21 | 110/90 | 47 | positive | rectangular | 42 |
| | 2-22 | R-22 | 110/90 | 42 | positive | rectangular | 44 |
| Comparative | 2-1 | CR-01 | 110/90 | 44 | positive | rectangular | 35 |
| Example | 2-2 | CR-02 | 105/90 | 48 | negative | rectangular | 35 |
| | 2-3 | CR-03 | 105/90 | 85 | positive | line pattern | — |
| | | | | | | disappeared | |
| | 2-4 | CR-04 | 105/90 | 85 | positive | line pattern | — |
| | | | | | | disappeared | |

From the results shown in Table 4, it was found that the resist composition based on the hypervalent iodine compound and the carboxy group-containing compound can be used to form a pattern by dry etching development. From the results of Comparative Examples 2-3 and 2-4, it was found that when a chemically amplified positive resist composition was used, the pattern disappeared after dry etching, and there was an insufficient difference in etching rate between the exposed region and the unexposed region. In addition, it was found that the resist composition based on the hypervalent iodine compound and the carboxy group-containing compound can form both positive and negative patterns depending on the selection of the polymer to be used. In addition, from the results of Comparative Examples 2-1 and 2-2, it was found that the hypervalent iodine compound (I-5) having a small molecular weight has lower etching resistance and has a lower pattern height after etching than the hypervalent iodine compound (I-1 to I-4) having a large molecular weight. Dry etching development is capable of forming a pattern with higher aspect ratio and higher resolution because there is no pattern collapse due to stress generated during spin drying in solution development.

Japanese Patent Application No. 2024-093768 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist pattern forming process comprising the steps of:
(i) applying a resist composition containing: a hypervalent iodine compound having the formula (1), (2), or (3); a carboxy group-containing compound; and a solvent onto a substrate or onto an underlayer film laminated on a substrate to form a resist film,
(ii) exposing the resist film to high-energy radiation,
(iii) heating the exposed resist film, and
(iv) developing the heated resist film by dry etching to form a resist pattern: 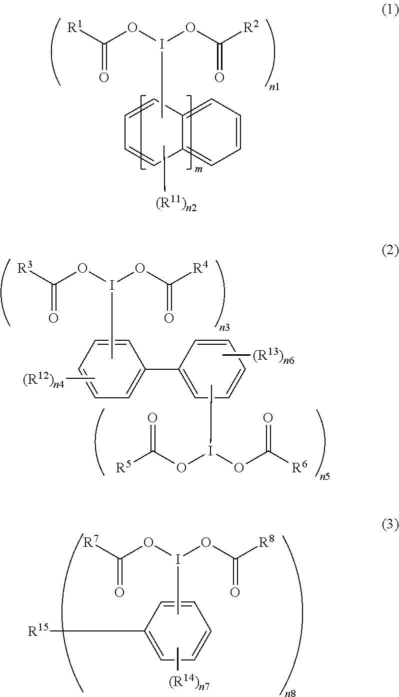
wherein
m is 0, 1, or 2; when m is 0, n1 is 2 or 3, n2 is 0, 1, 2, 3, or 4, and 2≤n1+n2≤6; when m is 1, n1 is 1, 2, or 3, n2 is 0, 1, 2, 3, 4, 5, 6, or 7, and 1≤n1+n2≤8; when m is 2, n1 is 1, 2, or 3, n2 is 0, 1, 2, 3, 4, 5, 6, 7, 8, or 9, and 1≤n1+n2≤10;
n3 is 1 or 2, n4 is 0, 1, 2, 3, or 4, provided that 1≤n3+n4≤5; n5 is 1 or 2, n6 is 0, 1, 2, 3, or 4, provided that 1≤n5+n6≤5; and n7 is 0, 1, 2, 3, or 4, and n8 is 1, 2, 3, or 4;
R¹ to R⁸ are each independently a halogen atom or a C₁-C₁₀ hydrocarbyl group which may contain a heteroatom, R¹ and R², R³ and R⁴, R⁵ and R⁶, or R⁷ and R⁸ may bond together to form a ring with the carbon atoms to which they are attached and the intervenient atoms;
R¹¹ to R¹⁴ are each independently a halogen atom or a C₁-C₄₀ hydrocarbyl group which may contain a heteroatom; when n2 is 2 or more, each R¹¹ may be the same or different from each other, and a plurality of R¹¹s may bond to each other to form a ring with the carbon atoms of the aromatic ring to which they are attached; when n4 is 2 or more, each R¹² may be the same or different from each other, and a plurality of R¹²s may bond to each other to form a ring with the carbon atoms of the aromatic ring to which they are attached; when n6 is 2 or more, each R¹³ may be the same or different from each other, and a plurality of R¹³s may bond to each other to form a ring with the carbon atoms of the aromatic ring to which they are attached; when n7 is 2 or more, each R¹⁴ may be the same or different from each other, and a plurality of R¹⁴s may bond to each other to form a ring with the carbon atoms of the aromatic ring to which they are attached;
R¹⁵ is a C₁-C₄₀ (n8)-valent hydrocarbon group or a C₂-C₄₀ (n8)-valent heterocyclic group; when n8 is 2, R¹⁵ may be an ether bond, a carbonyl group, an azo group, a thioether bond, a carbonate bond, a carbamate bond, a sulfinyl group, a sulfonyl group, or a thioketone bond; some or all of the hydrogen atoms of the (n8)-valent hydrocarbon group or the (n8)-valent heterocyclic group may be substituted with a heteroatom-containing moiety, some of —CH₂— of the (n8)-valent hydrocarbon group may be substituted with a heteroatom-containing moiety, and R¹⁴ and R¹⁵ may bond together to form a ring with the carbon atoms to which they are attached and the intervenient atoms.

2. The resist pattern forming process of claim 1 wherein the carboxy group-containing compound is a polymer having a repeat unit having the formula (4) or a compound having the formula (5): 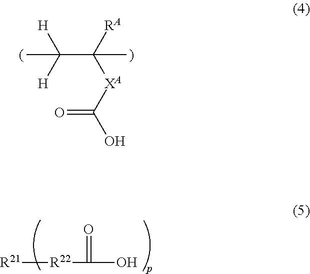
wherein R^{A} is a hydrogen atom, a halogen atom, a methyl group, or a trifluoromethyl group, X^{A} is a single bond, a phenylene group, a naphthylene group, or *—C(═O)—O—X^{A1}— wherein X^{A1} is a C₁-C₁₀ saturated hydrocarbylene group, a phenylene group, or a naphthylene group, the saturated hydrocarbylene group may contain a hydroxy group, an ether bond, an ester bond, or a lactone ring, and * designates a valence bond to a carbon atom in a main chain;
p is 1, 2, 3, or 4,
R²¹ is a C₁-C₄₀ p-valent hydrocarbon group or a C₂-C₄₀ p-valent heterocyclic group, when p is 2, R²¹ may be an ether bond, a carbonyl group, an azo group, a thioether bond, a carbonate bond, a carbamate bond, a sulfinyl group, or a sulfonyl group, and some or all of the hydrogen atoms in the p-valent hydrocarbon group or the p-valent heterocyclic group may be substituted by a heteroatom-containing moiety, and some constituent —CH₂— in the p-valent hydrocarbon group may be replaced by a heteroatom-containing moiety,
R²² is a single bond or a C₁-C₁₀ hydrocarbylene group, and some or all of the hydrogen atoms in the hydrocarbylene group may be substituted by a heteroatom-containing moiety, and some constituent —CH₂— in the hydrocarbylene group may be replaced by a heteroatom-containing moiety, and when p is 2, 3, or 4, each R²² may be the same or different from each other.

3. The resist pattern forming process of claim 1 wherein the high-energy radiation is i-ray, KrF excimer laser beam, ArF excimer laser beam, electron beam, or extreme ultraviolet ray.

4. The resist pattern forming process of claim 1 wherein, in the step (iv), the dry etching is performed by using a gas containing at least one selected from the group consisting of oxygen and tetrafluoromethane.
